(19) United States
(12) Patent Application Publication
(10) Pub. No.: US 2006/0263909 A1
(43) Pub. Date: Nov. 23, 2006

(54) Methods of fabricating thin ferroelectric layers and capacitors having ferroelectric dielectric layers therein

(76) Inventors: Suk-Hun Choi, Gyeonggi-do (KR); Byoung-Jae Bae, Gyeonggi-do (KR); Yoon-Ho Son, Gyeonggi-do (KR); Chang-Ki Hong, Gyeonggi-do (KR); Jeong-Heon Park, Gyeonggi-do (KR)

Correspondence Address: MYERS BIGEL SIBLEY & SAJOVEC, PO BOX 37428, RALEIGH, NC, 27627, US

(21) Appl. No.: 11/326,485

(22) Filed: Jan. 5, 2006

(30) Foreign Application Priority Data
May 18, 2005 (KR) 2005-41568

(51) Int. Cl. H01L 21/00; H01L 21/8242

(52) U.S. Cl. 438/3; 438/240

(57) ABSTRACT

Methods of forming ferroelectric layers include forming a ferroelectric layer on a substrate and chemically-mechanically polishing a surface of the ferroelectric layer by rotating a polishing pad on the surface at a rotation speed in a range from about 5 rpm to about 25 rpm. This polishing step includes pressing the polishing pad onto the surface of the ferroelectric layer at a pressure in a range from about 0.5 psi to about 3 psi. This polishing step may be followed by the step of exposing the polished surface to a rapid thermal anneal. This anneal can be performed in an inert atmosphere containing a gas selected from a group consisting of nitrogen, helium, argon and neon.

### REFERENCE TO PRIORITY APPLICATION

This application claims priority to Korean Application Serial No. 2005-41568, filed May 18, 2005, the disclosure of which is hereby incorporated herein by reference.

### FIELD OF THE INVENTION

The present invention is related to integrated circuit fabrication methods and, more particularly, to methods of forming integrated circuit devices having ferroelectric layers therein.

### BACKGROUND OF THE INVENTION

Semiconductor memory devices are generally divided into volatile semiconductor memory devices such as dynamic random access memory (DRAM) devices or static random access memory (SRAM) devices, and nonvolatile semiconductor memory devices such as erasable programmable read only memory (EPROM) devices, an electrically erasable programmable read only memory (EEPROM) device or a flash memory device. The volatile semiconductor memory device loses data stored therein when power is turned off, whereas the nonvolatile semiconductor memory device can maintain data stored therein even after power is turned off.

In contrast, a ferroelectric random access memory (FRAM) device has a volatile characteristic of a RAM device and also a nonvolatile characteristic of a ROM device. Additionally, the FRAM device may be operated with a voltage lower than that of the EPROM device or the EEPROM device, and data stored in the FRAM device may be maintained for a long storage time.

At present, a ferroelectric material such as PZT [Pb(Zr, Ti)O₃] or SBT (SrBi₂Ta₂O₉) has been developed for the FRAM device. A ferroelectric layer of PZT is formed at a relatively low temperature of below about 650° C. Additionally, the ferroelectric layer of PZT has a large polarization. However, the ferroelectric layer of PZT generally has poor fatigue characteristics and also includes a harmful ingredient such as lead (Pb). A ferroelectric layer of SBT has excellent fatigue characteristics and also has a polarization-voltage (P-V) hysteresis that does not imprint in a specific direction. However, the ferroelectric layer of SBT is formed through a thermal treatment at a high temperature of above about 800° C.

A method of manufacturing an FRAM device including a ferroelectric layer is disclosed in Korean Laid-Open Patent Publication No. 2001-113271, Korean Laid-Open Patent Publication No. 2001-4306, U.S. Pat. No. 6,351,006 issued to Yamakawa et al., and U.S. Pat. No. 6,194,228 issued to Fujiki et al.

When a ferroelectric layer including PZT is formed on a substrate by a metal organic chemical vapor deposition (MOCVD) process, the ferroelectric layer may have a very rough surface so that the FRAM device including the rough ferroelectric layer may have poor electrical and ferroelectric characteristics. In particular, an upper electrode may not be firmly attached to the rough ferroelectric layer, and also the upper electrode may be too easily detached from the rough ferroelectric layer. Additionally, charges may be irregularly distributed on the rough surface of the ferroelectric layer to thereby deteriorate the electrical characteristics of the FRAM device.

To solve the above-mentioned problems, Japanese Laid-Open Patent Publication No. 1997-198729 discloses a method of planarizing a surface of a ferroelectric layer by a chemically and mechanically polishing the surface of the ferroelectric layer. In this method, the surface of the ferroelectric layer is polished using an abrasive that includes colloidal silica dispersed in a strong alkali aqueous solution. However, the above Japanese Laid-Open Patent Publication No. 1997-198729 discloses the colloidal silica dispersed in the strong alkali aqueous solution as the abrasive only. Additionally, the above Japanese Laid-Open Patent Publication No. 1997-198729 is silent about slurry residues and/or polishing residues remaining on the surface of the ferroelectric layer. Furthermore, the above Japanese Laid-Open Patent Publication No. 1997-198729 does not disclose damage to the surface of the ferroelectric layer generated by chemically and mechanically polishing the surface of the ferroelectric layer.

### SUMMARY OF THE INVENTION

Embodiments of the present invention provide methods of manufacturing thin ferroelectric layers having improved ferroelectric and electrical characteristics and methods of manufacturing ferroelectric capacitors including the thin ferroelectric layers.

According to one embodiment of the present invention, there is provided a method of manufacturing a thin ferroelectric layer. In the method of manufacturing the thin ferroelectric layer, a preliminary ferroelectric layer is formed on a substrate. A surface of the preliminary ferroelectric layer is polished to form the thin ferroelectric layer on the substrate. Then, the thin ferroelectric layer is cured. The preliminary ferroelectric layer may be formed on the substrate by a metal organic chemical vapor deposition process, a sol-gel process, a chemical vapor deposition process or an atomic layer deposition process. The preliminary ferroelectric layer may include a ferroelectric material such as PZT [Pb(Zr, Ti)O₃], SBT (SrBi₂Ta₂O₉), BLT [(Bi, La)TiO₃], PLZT [Pb(La, Zr)TiO₃], and BST[(Bi, Sr)TiO₃].

The preliminary ferroelectric layer may have a first root mean square (RMS) value and a first P-V value, and the thin ferroelectric layer may have a second RMS value substantially lower than the first RMS value and a second P-V value substantially lower than the first P-V value. A ratio between the first RMS value and the second RMS value may be in a range of about 1.0:0.025 to about 1.0:0.25, and a ratio between the first P-V value and the second P-V value may be in a range of about 1.0:0.03 to about 1.0:0.3. The first RMS value may be in a range of about 40 Å to about 80 Å, the first P-V value may be in a range of about 200 Å to about 600 Å, the second RMS value may be in a range of about 2 Å to about 10 Å, and the second P-V value may be in a range of about 20 Å to about 60 Å.

The surface of the preliminary ferroelectric layer may be polished through a chemical mechanical polishing process. In particular, the surface of the preliminary ferroelectric layer may be polished using a chemical mechanical polishing apparatus that includes a carrier for mounting the substrate and a polishing pad contacting the surface of the preliminary ferroelectric layer. Here, a pressure pressing the substrate on the polishing pad may be in a range of about 0.5 psi to about 3.0 psi, and a rotation speed of the polishing pad may be in a range of about 5 rpm to about 25 rpm. The surface of the preliminary ferroelectric layer may be polished using a slurry for polishing an oxide. The slurry may include an abrasive. The abrasive may include acidic silica, basic silica, ceria, alumina or titanic The surface of the preliminary ferroelectric layer may be polished for about 10 to about 100 seconds. The thin ferroelectric layer then may be cleaned using a cleaning solution. The cleaning solution may include deionized water, an SMC solution, an SMF solution, an SC1 solution, an ammonia solution or a nitric acid solution.

The thin ferroelectric layer may be cured by thermally treating the thin ferroelectric layer. For example, the thin ferroelectric layer may be cured through a rapid thermal process under an inactive gas atmosphere. Here, the inactive gas may include a nitrogen gas, a helium gas, an argon gas or a neon gas. The thin ferroelectric layer may be cured at a temperature of about 500° C. to about 600° C. for about 30 seconds to about 90 seconds.

According to another embodiment of the present invention, there is provided a method of manufacturing a ferroelectric capacitor. In the method of manufacturing the ferroelectric capacitor, a lower electrode layer is formed on a substrate. A preliminary ferroelectric layer is formed on the lower electrode layer. A thin ferroelectric layer is formed on the lower electrode layer by polishing a surface of the preliminary ferroelectric layer. The thin ferroelectric layer is cured. An upper electrode layer is formed on the thin ferroelectric layer. The lower electrode layer may be formed by forming a first lower electrode film on the substrate, and forming a second lower electrode film on the first lower electrode film. The first lower electrode film may include titanium aluminum nitride, aluminum nitride, titanium nitride, titanium silicon nitride, tungsten nitride or tantalum silicon nitride. These can be used alone or in a mixture thereof. The first lower electrode film and the second lower electrode film may be independently formed by a sputtering process, a chemical vapor deposition process, a pulse laser deposition process or an atomic layer deposition process. The second lower electrode film may include iridium, platinum, ruthenium, palladium or gold. These can be used alone or in a mixture thereof. The upper electrode layer may be formed by forming a first upper electrode film on the thin ferroelectric layer, and forming a second upper electrode film on the first upper electrode film. The first upper electrode film may include strontium ruthenium oxide (SRO), strontium titanium oxide (STO), lanthanum nickel oxide (LNO) or calcium ruthenium oxide (CRO). The first upper electrode film also may be formed using SRO, STO, LNO or CRO doped with copper, lead or bismuth. The first upper electrode film and the second upper electrode film may be independently formed by a sputtering process, a pulse laser deposition process, a chemical vapor deposition process or an atomic layer deposition process.

According to the present invention, a preliminary ferroelectric layer may be polished by a CMP process under properly adjusted process conditions so that a thin ferroelectric layer may have a very level surface and a uniform thin thickness. Thus, the thin ferroelectric layer may have greatly improved ferroelectric and electrical characteristics such as more enhanced polarization or data retention, less leakage current density, etc. Additionally, slurry residues and polishing residues remaining on a surface of the thin ferroelectric layer may be effectively removed using an appropriate cleaning solution. Furthermore, the damage to the thin ferroelectric layer generated in the CMP process may be completely cured by cleaning the thin ferroelectric layer and by thermally treating the thin ferroelectric layer. As a result, a ferroelectric capacitor or a semiconductor device including the thin ferroelectric layer may have greatly improved electrical characteristics. Moreover, because an upper electrode layer is formed on the thin ferroelectric layer having the greatly level surface, the upper electrode layer may not be detached from the thin ferroelectric layer due to an enhanced adhesive strength between the upper electrode layer and the thin ferroelectric layer. Thus, the ferroelectric capacitor may have improved reliabilities.

### BRIEF DESCRIPTION OF THE DRAWINGS

FIG. 1 is a flow chart illustrating a method of manufacturing a thin ferroelectric layer in accordance with an example embodiment of the present invention;

FIGS. 2 to 4 are cross-sectional views illustrating a method of manufacturing a thin ferroelectric layer in accordance with an example embodiment of the present invention;

FIG. 5 is a schematic cross-sectional view illustrating a metal organic chemical vapor deposition apparatus for forming a preliminary ferroelectric layer in accordance with an example embodiment of the present invention;

FIG. 6 is a picture showing a surface of a preliminary ferroelectric layer obtained using an atomic force microscope (AFM) in accordance with an example embodiment of the present invention;

FIG. 7 is a picture showing a surface of a preliminary ferroelectric layer obtained using a scanning electron microscope (SEM) in accordance with an example embodiment of the present invention;

FIG. 8 is a schematic cross-sectional view illustrating a chemical mechanical polishing apparatus for polishing a preliminary ferroelectric layer in accordance with an example embodiment of the present invention;

FIG. 9 is a picture showing a surface of a thin ferroelectric layer obtained using an AFM in accordance with an example embodiment of the present invention;

FIG. 10 is a picture showing a surface of a thin ferroelectric layer obtained using an SEM in accordance with an example embodiment of the present invention;

FIG. 11 is a graph illustrating retention characteristics of polished thin ferroelectric layers and an unpolished thin ferroelectric layer in accordance with example embodiments of the present invention;

FIG. 12 is a graph illustrating leakage current densities of a polished thin ferroelectric layer and an unpolished thin ferroelectric layer in accordance with example embodiments of the present invention;

FIG. 13 is a graph illustrating 2Pr values of polished thin ferroelectric layers and an unpolished thin ferroelectric layer in accordance with example embodiments of the present invention;

FIG. 14 is a graph illustrating 2Pr values of polished thin ferroelectric layers and an unpolished thin ferroelectric layer in accordance with example embodiments of the present invention;

FIG. 15 is a graph illustrating polarization-electric field (P-E) hysteresis loops of polished thin ferroelectric layers and an unpolished thin ferroelectric layer in accordance with example embodiments of the present invention;

FIG. 16 is a graph illustrating retention characteristics of polished thin ferroelectric layers and an unpolished thin ferroelectric layer in accordance with example embodiments of the present invention;

FIG. 17 is a graph illustrating coercive fields of polished thin ferroelectric layers and an unpolished thin ferroelectric layer in accordance with example embodiments of the present invention;

FIG. 18 is a picture showing a surface of a thin ferroelectric layer cleaned using an ammonia solution obtained using an SEM in accordance with an example embodiment of the present invention;

FIG. 19 is an enlarged picture showing the surface of the thin ferroelectric layer in FIG. 18;

FIG. 20 is a picture showing a surface of a thin ferroelectric layer cleaned using deionized water obtained using an SEM in accordance with an example embodiment of the present invention;

FIG. 21 is an enlarged picture showing the surface of the thin ferroelectric layer in FIG. 20;

FIG. 22 is a graph illustrating 2Pr values of thin ferroelectric layers in accordance with Examples 1 and 2 and Comparative Example 1;

FIG. 23 is a graph illustrating 2Pr values of thin ferroelectric layers in accordance with Examples 3 to 7 and Comparative Example 2;

FIG. 24 is a graph illustrating 2Pr values and RMS values of the thin ferroelectric layers in accordance with Examples 3 to 7 and Comparative Example 2;

FIG. 25 is a graph illustrating 2Pr values and thicknesses of thin ferroelectric layers in accordance with Examples 8 to 17 and Comparative Examples 3 and 4;

FIG. 26 is a flow chart illustrating a method of manufacturing a ferroelectric capacitor in accordance with an example embodiment of the present invention;

FIGS. 27 to 30 are cross-sectional views illustrating a method of manufacturing a ferroelectric capacitor in accordance with an example embodiment of the present invention;

FIG. 31 is a picture showing a ferroelectric capacitor having a polished thin ferroelectric layer obtained using an SEM in accordance with an example embodiment of the present invention;

FIG. 32 is a picture showing a ferroelectric capacitor having an unpolished thin ferroelectric layer obtained using an SEM in accordance with an example embodiment of the present invention;

FIG. 33 is a graph illustrating 2Pr values of ferroelectric capacitors and RMS values of thin ferroelectric layers in accordance with Examples 18 to 22 and Comparative Example 5;

FIG. 34 is a graph illustrating leakage current densities of the ferroelectric capacitors in accordance with Examples 18 to 22 and Comparative Example 5;

FIG. 35 is a graph illustrating 2Pr values of ferroelectric capacitors and RMS values of thin ferroelectric layers in accordance with Examples 23 to 27 and Comparative Example 6;

FIG. 36 is a graph illustrating leakage current densities of the ferroelectric capacitors in accordance with Examples 23 to 27 and Comparative Example 6;

FIG. 37 is a graph illustrating 2Pr values of ferroelectric capacitors and RMS values and thicknesses of thin ferroelectric layers in accordance with example embodiments of the present invention;

FIG. 38 is a graph illustrating polishing rates of preliminary ferroelectric layers in accordance with Examples 30 to 35;

FIG. 39 is a picture showing a surface of a thin ferroelectric layer obtained using an SEM in accordance with Comparative Example 7;

FIG. 40 is a picture showing a surface of a thin ferroelectric layer obtained using an SEM in accordance with Example 32;

FIG. 41 is a picture showing a surface of a thin ferroelectric layer obtained using an SEM in accordance with Example 33;

FIG. 42 is a picture showing a surface of a thin ferroelectric layer obtained using an SEM in accordance with Example 34;

FIG. 43 is a picture showing a surface of a thin ferroelectric layer obtained using an SEM in accordance with Example 35;

FIG. 44 is a picture showing a surface of a thin ferroelectric layer obtained using an SEM in accordance with Example 28;

FIG. 45 is a picture showing a surface of a preliminary ferroelectric layer obtained using an AFM in accordance with Example 32;

FIG. 46 is a picture showing the surface of the thin ferroelectric layer obtained using an AFM in accordance with Example 32;

FIG. 47 is a picture showing a surface of a preliminary ferroelectric layer obtained using an AFM in accordance with Example 33;

FIG. 48 is a picture showing the surface of the thin ferroelectric layer obtained using an AFM in accordance with Example 33;

FIG. 49 is a picture showing a surface of a preliminary ferroelectric layer obtained using an AFM in accordance with Example 34;

FIG. 50 is a picture showing the surface of the thin ferroelectric layer obtained using an AFM in accordance with Example 34;

FIG. 51 is a picture showing a surface of a preliminary ferroelectric layer obtained using an AFM in accordance with Example 35;

FIG. 52 is a picture showing the surface of the thin ferroelectric layer obtained using an AFM in accordance with Example 35;

FIG. 53 is a picture showing a ferroelectric capacitor obtained using an SEM in accordance with Example 29;

FIG. 54 is a picture showing a ferroelectric capacitor obtained using an SEM in accordance with Example 31;

FIG. 55 is a picture showing a ferroelectric capacitor obtained using an SEM in accordance with Example 32;

FIG. 56 is a picture showing a ferroelectric capacitor obtained using an SEM in accordance with Example 33;

FIG. 57 is a picture showing a ferroelectric capacitor obtained using an SEM in accordance with Example 34;

FIG. 58 is a picture showing a ferroelectric capacitor obtained using an SEM in accordance with Example 35;

FIG. 59 is a picture showing a ferroelectric capacitor obtained using an SEM in accordance with Comparative Example 7;

FIG. 60 is a graph illustrating polarization-voltage (P-V) hysteresis loops of the ferroelectric capacitors in accordance with Examples 29 and 31 and Comparative Example 7;

FIG. 61 is a graph illustrating P-V hysteresis loops of the ferroelectric capacitors in accordance with Examples 32 and 33 and Comparative Example 7;

FIG. 62 is a graph illustrating P-V hysteresis loops of the ferroelectric capacitors in accordance with Examples 34 and 35 and Comparative Example 7;

FIG. 63 is a graph illustrating 2Pr values of the ferroelectric capacitors in accordance with Examples 29 and 31 and Comparative Example 7;

FIG. 64 is a graph illustrating leakage current densities of the ferroelectric capacitors in accordance with Examples 29 and 31 and Comparative Example 7;

FIG. 65 is a graph illustrating 2Pr values of the ferroelectric capacitors in accordance with Examples 32 and 33 and Comparative Example 7;

FIG. 66 is a graph illustrating leakage current densities of the ferroelectric capacitors in accordance with Examples 32 and 33 and Comparative Example 7;

FIG. 67 is a graph illustrating 2Pr values of the ferroelectric capacitors in accordance with Examples 34 and 35 and Comparative Example 7;

FIG. 68 is a graph illustrating leakage current densities of the ferroelectric capacitors in accordance with Examples 34 and 35 and Comparative Example 7;

FIG. 69 is a graph illustrating retention characteristics of the ferroelectric capacitors in accordance with Examples 29 and 31 and Comparative Example 7;

FIG. 70 is a graph illustrating retention characteristics of the ferroelectric capacitors in accordance with Examples 32 and 33 and Comparative Example 7;

FIG. 71 is a graph illustrating retention characteristics of the ferroelectric capacitors in accordance with Examples 34 and 35 and Comparative Example 7;

FIG. 72 is a graph illustrating etch rates of thin ferroelectric layers relative to cleaning solutions in accordance with example embodiments of the present invention;

FIG. 73 is a picture showing a surface of a thin ferroelectric layer obtained using an SEM in accordance with Comparative Example 9;

FIG. 74 is an enlarged picture showing the surface of the thin ferroelectric layer in FIG. 73;

FIG. 75 is a picture showing a surface of a thin ferroelectric layer obtained using an SEM in accordance with Example 39;

FIG. 76 is an enlarged picture showing the surface of the thin ferroelectric layer in FIG. 75;

FIG. 77 is a picture showing a surface of a thin ferroelectric layer obtained using an SEM in accordance with Example 40;

FIG. 78 is an enlarged picture showing the surface of the thin ferroelectric layer in FIG. 77;

FIG. 79 is a picture showing a surface of a thin ferroelectric layer obtained using an SEM in accordance with Example 43;

FIG. 80 is an enlarged picture showing the surface of the thin ferroelectric layer in FIG. 79;

FIG. 81 is a picture showing a surface of a thin ferroelectric layer obtained using an SEM in accordance with Example 46;

FIG. 82 is an enlarged picture showing the surface of the thin ferroelectric layer in FIG. 81;

FIG. 83 is a picture showing a surface of a thin ferroelectric layer obtained using an SEM in accordance with Example 49;

FIG. 84 is an enlarged picture showing the surface of the thin ferroelectric layer in FIG. 83;

FIG. 85 is a picture showing a surface of a thin ferroelectric layer obtained using an SEM in accordance with Comparative Example 10;

FIG. 86 is an enlarged picture showing the surface of the thin ferroelectric layer in FIG. 85;

FIG. 87 is a picture showing a surface of a thin ferroelectric layer obtained using an SEM in accordance with Example 44;

FIG. 88 is an enlarged picture showing the surface of the thin ferroelectric layer in FIG. 87;

FIG. 89 is a picture showing a surface of a thin ferroelectric layer obtained using an SEM in accordance with Example 50;

FIG. 90 is an enlarged picture showing the surface of the thin ferroelectric layer in FIG. 89;

FIG. 91 is a picture showing a cross-section of a thin ferroelectric layer obtained using an SEM in accordance with Comparative Example 8;

FIG. 92 is a picture showing a surface of the thin ferroelectric layer in FIG. 91;

FIG. 93 is a picture showing a cross-section of a thin ferroelectric layer obtained using an SEM in accordance with Example 36;

FIG. 94 is a picture showing a surface of the thin ferroelectric layer in FIG. 93;

FIG. 95 is a picture showing a cross-section of a thin ferroelectric layer obtained using an SEM in accordance with Example 39;

FIG. 96 is a picture showing a surface of the thin ferroelectric layer in FIG. 95;

FIG. 97 is a picture showing a cross-section of a thin ferroelectric layer obtained using an SEM in accordance with Example 42;

FIG. 98 is a picture showing a surface of the thin ferroelectric layer in FIG. 97;

FIG. 99 is a picture showing a cross-section of a thin ferroelectric layer obtained using an SEM in accordance with Example 45;

FIG. 100 is a picture showing a surface of the thin ferroelectric layer in FIG. 99;

FIG. 101 is a picture showing a cross-section of a thin ferroelectric layer obtained using an SEM in accordance with Example 48;

FIG. 102 is a picture showing a surface of the thin ferroelectric layer in FIG. 101;

FIG. 103 is a graph illustrating a P-V hysteresis loop of a ferroelectric capacitor in accordance with Comparative Example 9;

FIG. 104 is a graph illustrating a P-V hysteresis loop of a ferroelectric capacitor in accordance with Comparative Example 10;

FIG. 105 is a graph illustrating a P-V hysteresis loop of a ferroelectric capacitor in accordance with Example 36;

FIG. 106 is a graph illustrating a P-V hysteresis loop of a ferroelectric capacitor in accordance with Example 38;

FIG. 107 is a graph illustrating a P-V hysteresis loop of a ferroelectric capacitor in accordance with Example 40;

FIG. 108 is a graph illustrating a P-V hysteresis loop of a ferroelectric capacitor in accordance with Example 41;

FIG. 109 is a graph illustrating a P-V hysteresis loop of a ferroelectric capacitor in accordance with Example 43;

FIG. 110 is a graph illustrating a P-V hysteresis loop of a ferroelectric capacitor in accordance with Example 44;

FIG. 111 is a graph illustrating a P-V hysteresis loop of a ferroelectric capacitor in accordance with Example 46;

FIG. 112 is a graph illustrating a P-V hysteresis loop of a ferroelectric capacitor in accordance with Example 47;

FIG. 113 is a graph illustrating a P-V hysteresis loop of a ferroelectric capacitor in accordance with Example 49;

FIG. 114 is a graph illustrating a P-V hysteresis loop of a ferroelectric capacitor in accordance with Example 50;

FIG. 115 is a graph illustrating a polarization of the ferroelectric capacitor in accordance with Comparative Example 9;

FIG. 116 is a graph illustrating a polarization of the ferroelectric capacitor in accordance with Comparative Example 10;

FIG. 117 is a graph illustrating a polarization of the ferroelectric capacitor in accordance with Example 37;

FIG. 118 is a graph illustrating a polarization of the ferroelectric capacitor in accordance with Example 38;

FIG. 119 is a graph illustrating a polarization of the ferroelectric capacitor in accordance with Example 40;

FIG. 120 is a graph illustrating a polarization of the ferroelectric capacitor in accordance with Example 41;

FIG. 121 is a graph illustrating a polarization of the ferroelectric capacitor in accordance with Example 43;

FIG. 122 is a graph illustrating a polarization of the ferroelectric capacitor in accordance with Example 44;

FIG. 123 is a graph illustrating a polarization of the ferroelectric capacitor in accordance with Example 46;

FIG. 124 is a graph illustrating a polarization of the ferroelectric capacitor in accordance with Example 47;

FIG. 125 is a graph illustrating a polarization of the ferroelectric capacitor in accordance with Example 49;

FIG. 126 is a graph illustrating a polarization of the ferroelectric capacitor in accordance with Example 50;

FIG. 127 is a graph illustrating P-V hysteresis loops of the ferroelectric capacitors in accordance with Comparative Example 10 and Examples 38, 44, 47 and 50;

FIG. 128 is a graph illustrating P-V hysteresis loops of the ferroelectric capacitors in accordance with Examples 37 and 38;

FIG. 129 is a graph illustrating P-V hysteresis loops of the ferroelectric capacitors in accordance with Examples 46 and 47;

FIG. 130 is a graph illustrating polarizations of the ferroelectric capacitors in accordance with Comparative Example 10 and Examples 38, 41, 44, 47 and 50;

FIG. 131 is a graph illustrating contents of ingredients in the thin ferroelectric layers in accordance with Comparative Example 10 and Examples 38, 41, 44, 47 and 50; and

FIGS. 132 through 136 are cross-sectional views illustrating a method of manufacturing a semiconductor device having a thin ferroelectric layer in accordance with an example embodiment of the present invention.

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Method of Manufacturing a Thin Ferroelectric Layer

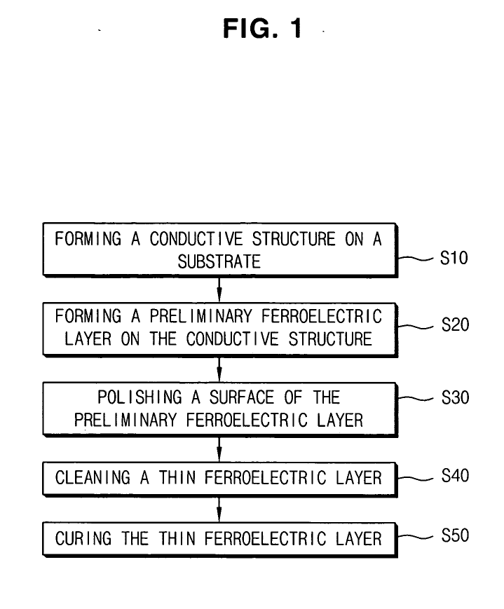

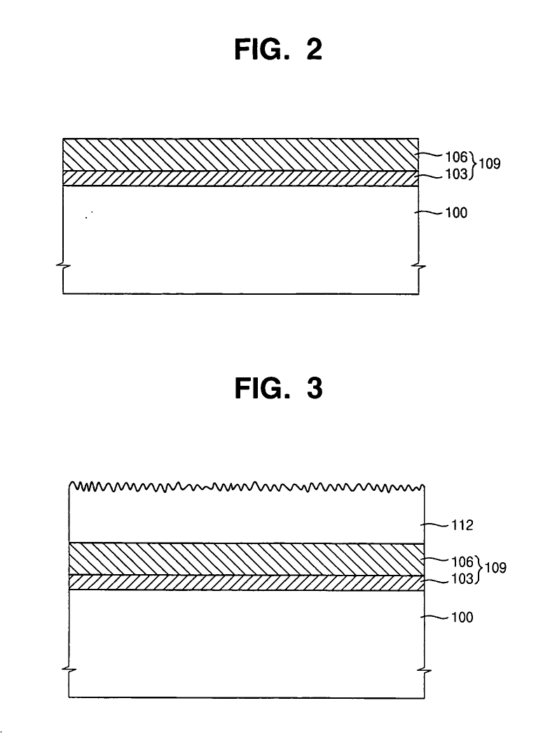

FIG. 1 is a flow chart illustrating a method of manufacturing a thin ferroelectric layer in accordance with an example embodiment of the present invention, and FIGS. 2 to 4 are cross-sectional views illustrating a method of manufacturing a thin ferroelectric layer in accordance with an example embodiment of the present invention.

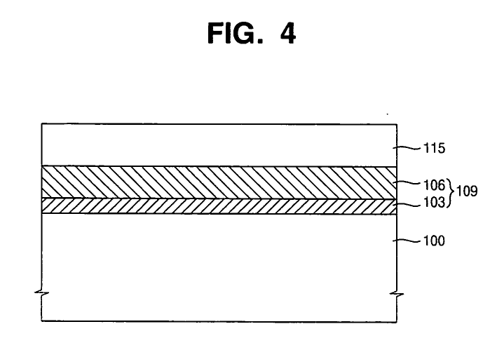

Referring to FIGS. 1 and 2, a conductive structure 109 is formed on a substrate 100 in step S10. A contact region, a pad, a plug, a conductive wiring, a conductive pattern, a transistor, etc. may be formed between the substrate 100 and the conductive structure 109. In one example embodiment of the present invention, the substrate 100 may include a semiconductor substrate such as a silicon wafer or a silicon on insulator (SOI) substrate in order to form a thin ferroelectric layer 115 (see FIG. 4). In another example embodiment of the present invention, the substrate 100 may include a single crystalline metal oxide substrate. For example, the substrate 100 includes a single crystalline aluminum oxide (Al₂O₃) substrate, a single crystalline strontium titanium oxide (SrTiO₃) substrate, or a single crystalline magnesium oxide (MgO) substrate. When the substrate 100 includes the single crystalline metal oxide substrate, the thin ferroelectric layer 115 may be directly formed on the substrate 100 without a formation of the conductive structure 109.

The conductive structure 109 includes a first conductive layer 103 and a second conductive layer 106 sequentially formed on the substrate 100. The first conductive layer 103 may serve as a barrier layer that prevents oxygen included in the thin ferroelectric layer 115 from diffusing to the conductive structure 109 and the substrate 100. The second conductive layer 106 may enhance a crystallization of ingredients contained in the thin ferroelectric layer 115.

The first conductive layer 103 may be formed using a metal nitride. For example, the first conductive layer 103 is formed using titanium aluminum nitride (TiAlN), aluminum nitride (AlN), titanium nitride (TiN), titanium silicon nitride (TiSiN), tantalum nitride (TaN), tantalum silicon nitride (TaSiN), tungsten nitride (WN), etc. The first conductive layer 103 may be formed on the substrate 100 by a sputtering process, a chemical vapor deposition (CVD) process or an atomic layer deposition (ALD) process, etc. For example, the first conductive layer 103 is formed using titanium aluminum nitride by the sputtering process. The first conductive layer 103 may have a thickness of about 50 to about 500 Å measured from an upper face of the substrate 100.

The second conductive layer 106 may be formed on the first conductive layer 103 by a sputtering process, a CVD process, a pulse laser deposition (PLD) process or an ALD process. The second conductive layer 106 may be formed using a metal such as iridium (Ir), platinum (Pt), ruthenium (Ru), palladium (Pd), gold (Au), etc. For example, the second conductive layer 106 is formed using iridium by the sputtering process. The second conductive layer 106 may have a thickness of about 500 Å to about 1,500 Å measured from an upper face of the first conductive layer 103. As a result, the conductive structure 109 is completed on the substrate 100.

In one example embodiment of the present invention, an insulation layer (not shown) may be formed on the substrate 100 before forming the conductive structure 109. The insulation layer may be formed using an oxide such as boro-phosphor silicate glass (BPSG), phosphor silicate glass (PSG), undoped silicate glass (USG), spin on glass (SOG), flowable oxide (FOx), plasma-enhanced tetraethylorthosilicate (PE-TEOS), high density plasma chemical vapor deposition (HDP-CVD) oxide, etc. The insulation layer may be formed between the substrate 100 and the conductive structure 109 by a CVD process, a plasma enhanced chemical vapor deposition (PECVD) process, an ALD process, an HDP-CVD process, etc.

In another example embodiment of the present invention, an adhesion layer (not shown) may be formed between the insulation layer and the conductive structure 109. The adhesion layer may improve an adhesive strength between the insulation layer and the first conductive layer 103. The adhesion layer may be formed using a metal or a conductive metal nitride. For example, the adhesion layer is formed using titanium (Ti), titanium nitride (TiN), tantalum (Ta), tantalum nitride (TaN), aluminum (Al), aluminum nitride (AlN), tungsten (W), tungsten nitride (WN), etc. The adhesion layer may be formed on the insulation layer by a sputtering process, a CVD process, a PLD process, an ALD process, etc.

In another example embodiment of the present invention, the adhesion layer may be formed on the substrate 100 even when the insulation layer is not formed on the substrate 100. Here, the adhesion layer may improve an adhesive strength between the substrate 100 and the first conductive layer 103.

In still another example embodiment of the present invention, the first conductive layer 103 may increase an adhesion strength between the substrate 100 and the second conductive layer 106 when the adhesion layer is not formed between the substrate 100 and the first conductive layer 103 or between the insulation layer and the first conductive layer 103. That is, the first conductive layer 103 may simultaneously serve as the adhesion layer and the barrier layer.

Referring to FIGS. 1 and 3, a preliminary ferroelectric layer 112 is formed on the conductive structure 109 in step S20. The preliminary ferroelectric layer 112 may have a thickness of about 200 to about 1,500 Å measured from an upper face of the second conductive layer 106. The preliminary ferroelectric layer 112 may include a ferroelectric material such as PZT [Pb(Zr, Ti)O₃], SBT (SrBi₂Ta₂O₉), BLT [(Bi, La)TiO₃], PLZT [Pb(La, Zr)TiO₃], BST [(Bi, Sr)TiO₃], etc. The preliminary ferroelectric layer 112 also may include the ferroelectric material doped with a metal such as calcium (Ca), lanthanum (La), manganese (Mn) or bismuth (Bi). For example, the preliminary ferroelectric layer 112 may include PZT, SBT, BLT, PLZT or BST doped with calcium, lanthanum, manganese or bismuth. Alternatively, the preliminary ferroelectric layer 112 may include a metal oxide such as titanium oxide (TiO₂), tantalum oxide (TaO₂), aluminum oxide (Al₂O₃), zinc oxide (ZnO₂), hafnium oxide (HfO₂), etc.

The preliminary ferroelectric layer 112 may be formed on the conductive layer 106 by a metal organic chemical vapor deposition (MOCVD) process, a sol-gel process or an ALD process. For example, the preliminary ferroelectric layer 112 may be formed using PZT by the metal organic chemical vapor deposition process. The step S20 of forming the preliminary ferroelectric layer 112 will be described in detail as follows.

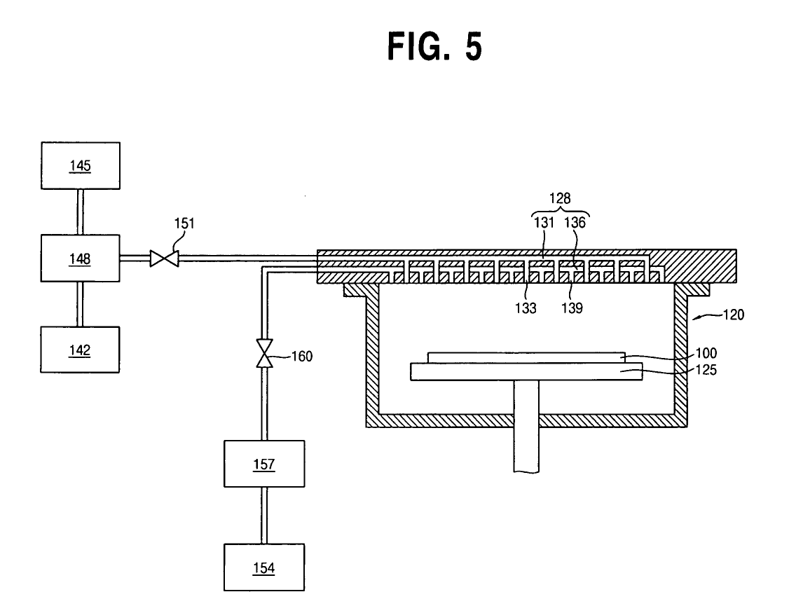

FIG. 5 is a schematic cross-sectional view illustrating a metal organic chemical vapor deposition apparatus for forming the preliminary ferroelectric layer 112 in accordance with an example embodiment of the present invention. Referring to FIGS. 1, 3 and 5, the substrate 100 having the conductive structure 109 is loaded on a susceptor 125 installed in a reaction chamber 120. In the step S20 of forming the preliminary ferroelectric layer 112, the substrate 100 is maintained at a temperature of about 350° C. to about 650° C., and the reaction chamber 120 is maintained at a pressure of about 1 Torr to about 10 Torr.

A showerhead 128 having a first spraying port 131 and a second spraying port 136 is disposed at an upper portion of the process chamber 120. The first spraying port 131 includes a plurality of first nozzles 133, and the second spraying port 136 has a plurality of second nozzles 139. The first and the second nozzles 133 and 139 may be alternately disposed over the susceptor 125.

After a metal organic precursor is provided from a metal organic precursor source 142 into a vaporizer 148, the metal organic precursor is heated in the vaporizer 148. A carrier gas is provided from a carrier gas source 145 into the vaporizer 148, and then the carrier gas is also heated in the vaporizer 148. The metal organic precursor may include a first compound containing lead, a second compound containing zirconium, and a third compound containing titanium. Alternatively, the metal organic precursor may include a compound containing lead, zirconium and titanium. The carrier gas may include a nitrogen (N₂) gas, a helium (He) gas or an argon (Ar) gas. The heated metal organic precursor and the heated carrier gas are provided onto the substrate 100 through the first nozzles 133 of the first spraying port 131.

In the meantime, an oxidant is provided from an oxidant source 154 into a heater 157, and then the oxidant is heated in the heater 157. The heated oxidant is provided onto the substrate 100 through the second nozzles 139 of the second spraying port 136. The oxidant may include oxygen (O₂), ozone (O₃), nitrogen dioxide (NO₂) or nitrous oxide (N₂O). The heated oxidant may have a temperature substantially identical to that of the heated metal organic precursor.

In the step 20 of forming the preliminary ferroelectric layer 112 on the second conductive layer 106 by reacting the heated metal organic precursor with the heated oxidant, flow rates of the heated metal organic precursor and the heated oxidant may be controlled using a first valve 151 and a second valve 160. For example, the heated oxidant has a flow rate of about 1,000 sccm to about 1,500 sccm. Therefore, the preliminary ferroelectric layer 112 is formed on the second conductive layer 106. Here, the preliminary ferroelectric layer 112 includes PZT formed by the MOCVD process.

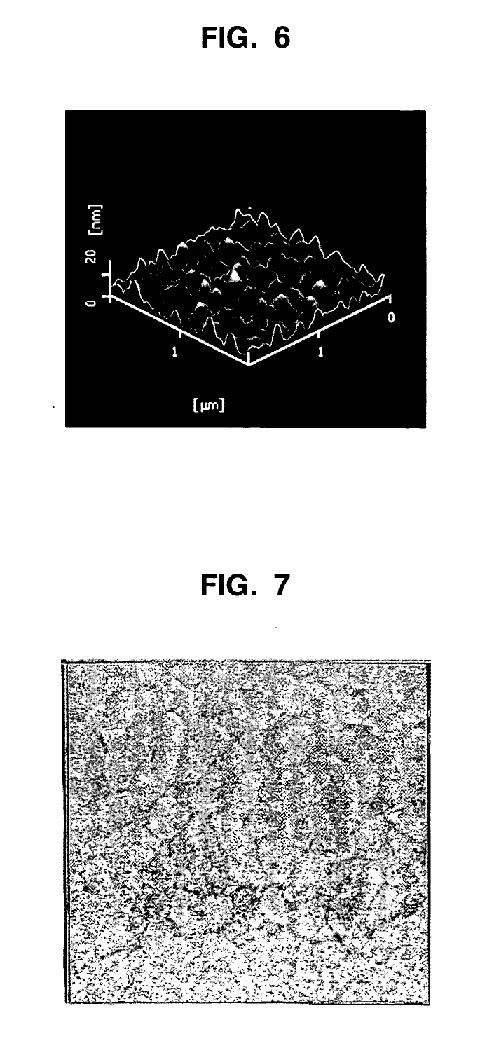

FIG. 6 is a picture showing a surface of the preliminary ferroelectric layer 112 obtained using an atomic force microscope (AFM), and FIG. 7 is a picture showing the surface of the preliminary ferroelectric layer 112 obtained using a scanning electron microscope (SEM). Referring FIGS. 6 and 7, the surface of the preliminary ferroelectric layer 112 has a first root mean square (RMS) value of about 40 Å to about 80 Å when the preliminary ferroelectric layer 112 is formed using PZT by the MOCVD process. In addition, the surface of the preliminary ferroelectric layer 112 has a first peak-to-valley value (referred to as P-V value) of about 200 Å to about 600 Å. That is, the surface conditions of the preliminary ferroelectric layer 112 are relatively poor. When the preliminary ferroelectric layer 112 has the relatively large first RMS value and first P-V value, the thin ferroelectric layer 115 may have reduced data retention or decreased polarization retention. Additionally, leakage current from the ferroelectric layer 115 may increase when the preliminary ferroelectric layer 112 has poor surface conditions. Thus, the surface of the preliminary ferroelectric layer 112 is polished to thereby improve surface conditions of the ferroelectric layer 115.

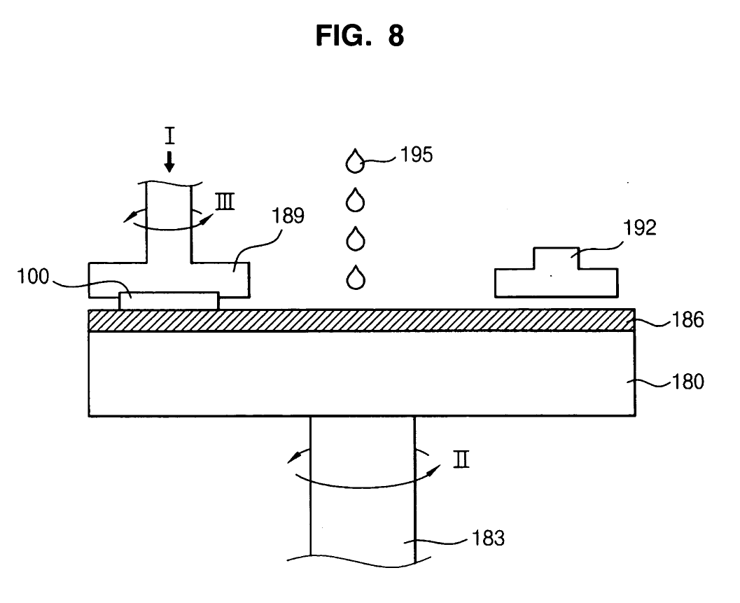

Referring to FIGS. 1 and 4, the surface of the preliminary ferroelectric layer 112 is polished by a chemical mechanical polishing (CMP) process in step S30. This polishing step will be described in detail as follows. FIG. 8 is a cross-sectional view illustrating a chemical mechanical polishing apparatus for polishing the preliminary ferroelectric layer 112. Referring to FIGS. 1, 4 and 8, the chemical mechanical polishing apparatus includes a rotation table 180 having a polishing pad 186, a rotation axis 183 for revolving the rotation table 180, a carrier 189 for receiving the substrate 100, and a conditioning pad 192 for improving surface conditions of the polishing pad 186. The carrier 189 is disposed over a first portion of the polishing pad 186, and the conditioning pad 192 is positioned over a second portion of the polishing pad 186. The substrate 100 including the preliminary ferroelectric layer 112 is received in the carrier 189 so that the preliminary ferroelectric layer 112 faces the polishing pad 186. That is, the preliminary ferroelectric layer 112 makes contact with the polishing pad 186. The carrier 189 receiving the substrate 100 rotates in a direction substantially identical to a rotation direction of the polishing pad 186, whereas the carrier 189 has a rotation speed substantially different from that of the polishing pad 186.

Slurry 195 is provided onto a central portion of the polishing pad 186 through a supply nozzle (not shown) disposed over the rotation table 180. Since the rotation table 180 rotates by a predetermined rotation speed, the slurry 195 is transferred between the polishing pad 186 and the preliminary ferroelectric layer 112 due to a centrifugal force generated by the rotation of the rotation table 180. The slurry 195 may polish an oxide layer because the preliminary ferroelectric layer 112 includes oxide.

In one example embodiment of the present invention, the slurry 195 for polishing the preliminary ferroelectric layer 112 may include an abrasive containing an oxide. For example, the abrasive includes acidic silica (SiO₂), basic silica or ceria (CeO₂). Here, the acidic silica may have a pH of about 2 to about 3, and the basic silica may have a pH of about 10 to 12. The ceria has a pH of about 7 to 8. Alternatively, the slurry 195 may include an abrasive containing a metal oxide. For example, the abrasive may include alumina (Al₂O₃) or titania (TiO₂).

In the step S30 for polishing the surface of the preliminary ferroelectric layer 112 by the CMP process, main process parameters are a downward pressure I and a rotation speed II of the polishing pad 186. The rotation speed III of the carrier 189 may be constantly maintained in the CMP process. The downward pressure I indicates a pressure between the substrate 100 and the polishing pad 186. Namely, the downward pressure I means a pressure of the carrier 189 that presses the polishing pad 186. The rotation speed II of the polishing pad 186 is substantially identical to the rotation speed of the rotation table 180.

Generally, as a thickness of a thin ferroelectric layer, for example, a thickness of a thin PZT layer, is reduced, a dead layer effect may be caused at a surface portion of the ferroelectric layer so that the ferroelectric layer may have poor ferroelectric characteristics. When the thin ferroelectric layer has the reduced thickness, a 2Pr value of the ferroelectric layer may decrease, whereas a coercive voltage of the ferroelectric layer may increase. However, according to example embodiments of the present invention, the surface of the preliminary ferroelectric layer 112 is polished by the above-described process so that the thin ferroelectric layer 115 has a very flat surface, and the thin ferroelectric layer 115 has a considerably thin thickness. Accordingly, the thin ferroelectric layer 115 has greatly improved ferroelectric characteristics by reducing the dead layer effect of the thin ferroelectric layer 115.

The downward pressure I between the substrate 100 and the polishing pad 186 may be in a range of about 0.5 psi to about 3.0 psi, which is relatively low compared to a conventional CMP process. Additionally, the rotation speed II of the polishing pad 186 may be in a range of about 5 rpm to about 25 rpm, which is considerably slower than that of the conventional CMP process. That is, the preliminary ferroelectric layer 112 is polished at the relatively low downward pressure I and the relatively slow rotation speed II. As a result, the thin ferroelectric layer 115 may have the improved ferroelectric characteristics by preventing a stress from generating in the thin ferroelectric layer 115 in the CMP process. Furthermore, when the preliminary ferroelectric layer 112 is polished at the relatively low downward pressure I and the relatively slow rotation speed II, a process margin of the CMP process may be sufficiently ensured because a polishing rate of the preliminary ferroelectric layer 112 may be easily controlled.

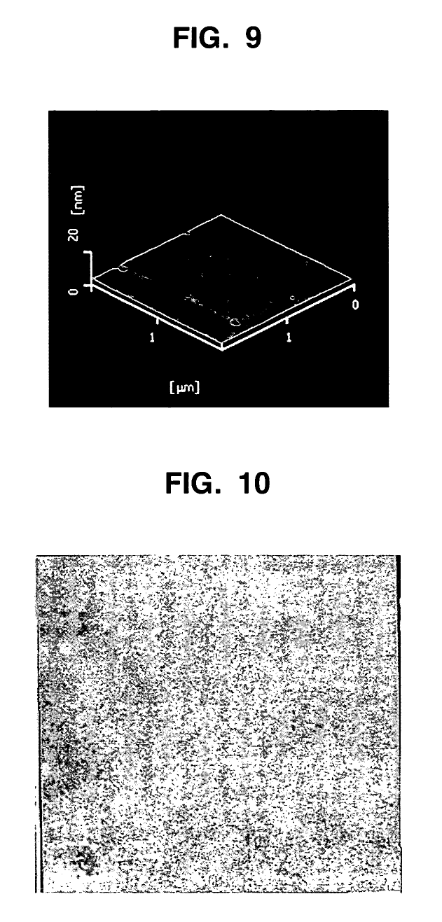

FIG. 9 is a picture showing the surface of the thin ferroelectric layer 115 obtained using an AFM, and FIG. 10 is a picture showing the surface of the thin ferroelectric layer 115 obtained using an SEM. Referring to FIGS. 9 and 10, after the surface of the preliminary ferroelectric layer 112 is polished, the thin ferroelectric layer 115 may have a second RMS value of about 2 Å to about 10 Å, and a second P-V value of about 20 Å to about 60 Å. Hence, a ratio between the first RMS value and the second RMS value may be in a range of about 1.0:0.025 to about 1.0:0.25. In addition, a ratio between the first P-V value and the second P-V value may be in a range of about 1.0:0.03 to about 1.0:0.3. Accordingly, the surface of the thin ferroelectric layer 115 has greatly improved roughness so that the thin ferroelectric layer 115 may have considerably enhanced ferroelectric characteristics.

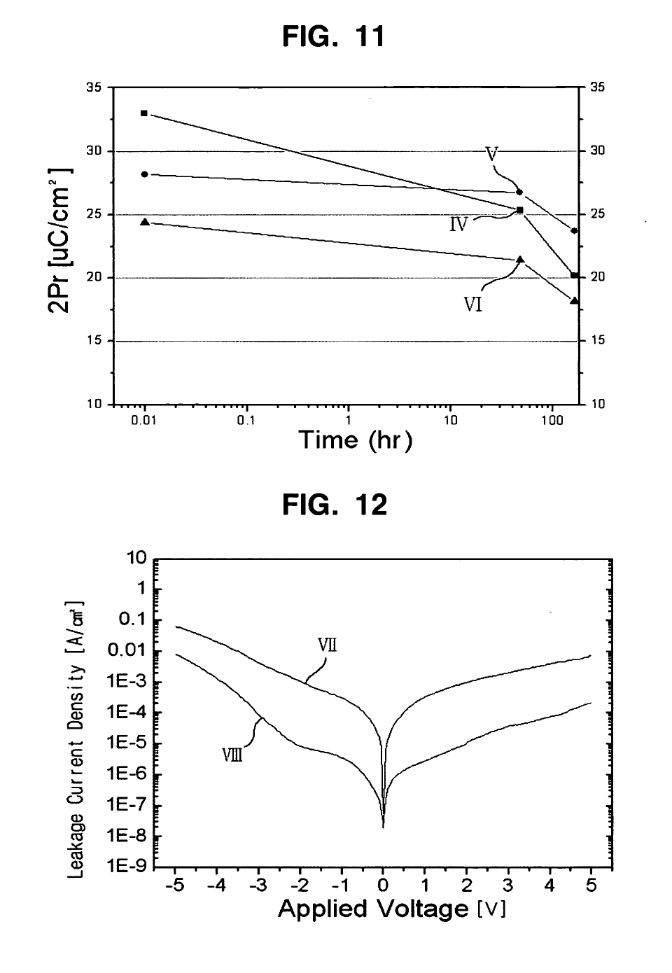

FIG. 11 is a graph illustrating retention characteristics of the polished thin ferroelectric layers and an unpolished ferroelectric layer in accordance with example embodiments of the present invention. In FIG. 11, “IV” indicates a reduction rate of a 2Pr value of the unpolished thin ferroelectric layer relative to time, and “V” and “VI” represent reduction rates of 2Pr values of first and second polished thin ferroelectric layers relative to time, respectively. The first thin ferroelectric layer V is formed by performing the polishing process for about 30 seconds, and the second thin ferroelectric layer VI is obtained by executing the polishing process for about 60 seconds.

Referring to FIG. 11, the first polished thin ferroelectric layer V has an initial 2Pr value of about 27.6 μC/cm². After about 100 hours at a temperature of about 150° C., the first polished thin ferroelectric layer V has a 2Pr value of about 24.8 μC/cm². Thus, the reduction rate of the 2Pr value of the first polished thin ferroelectric layer V is about 10%. The second polished thin ferroelectric layer VI has an initial 2Pr value of about 24.5° C./cm², and then the second polished thin ferroelectric layer VI has a 2Pr value of about 18.4 μLC/cm² after about 100 hours at a temperature of about 150° C. Hence, the reduction rate of the 2Pr value of the second polished thin ferroelectric layer VI is about 25%. However, the unpolished thin ferroelectric layer IV has an initial 2Pr value of about 33.4 μC/cm² and has a 2Pr value of about 20.1 μC/cm² after about 100 hours at a temperature of about 150° C. Therefore, the unpolished thin ferroelectric layer IV has a reduction rate of the 2Pr value of about 40%.

As shown in FIG. 11, the unpolished thin ferroelectric layer W has a large reduction rate of the 2Pr value. That is, the retention characteristic of the unpolished thin ferroelectric layer IV is greatly reduced as time goes by. However, the first and the second polished thin ferroelectric layers V and VI have relatively low reduction rates of the 2Pr values. Thus, the retention characteristics of the first and the second polished thin ferroelectric layers V and VI are not rapidly decreased with respect to time. As a result, the surface polishing process may improve the polarization and retention characteristics of the first and the second thin ferroelectric layers V and VI, and may prevent a deterioration of the data retention characteristics of the first and the second thin ferroelectric layers V and VI. In particular, the first polished thin ferroelectric layer V has the reduction rate of the 2Pr value relatively smaller than that of the second polished thin ferroelectric layer VI. Therefore, a thin polished ferroelectric layer may have slightly deteriorated retention characteristics when a surface polishing process is excessively carried out.

FIG. 12 is a graph illustrating leakage current densities of a polished thin ferroelectric layer and an unpolished thin ferroelectric layer in accordance with example embodiments of the present invention. In FIG. 12, “VII” indicates the leakage current density of the unpolished thin ferroelectric layer relative to an applied voltage, and “VIII” represents the leakage current density of the polished thin ferroelectric layer relative to the applied voltage. The polished thin ferroelectric layer VIII is formed by performing the surface polishing process for about 30 seconds.

Referring to FIG. 12, when the applied voltage is in a range of about −5 V to about +5 V, the unpolished ferroelectric layer VII has a maximum leakage current density of about 0.1 A/cm², whereas the polished thin ferroelectric layer VIII has a maximum leakage current density of about 0.01 A/cm². Therefore, the polished thin ferroelectric layer VIII has the leakage current density considerably smaller than that of the unpolished ferroelectric layer VII. As a result, the polished thin ferroelectric layer VIII may have improved electrical characteristics.

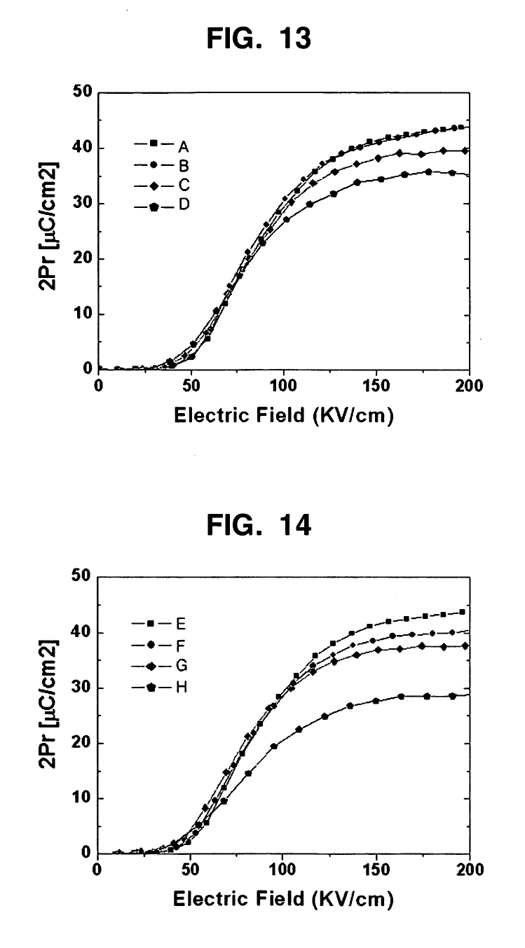

FIG. 13 is a graph illustrating 2Pr values of polished thin ferroelectric layers and an unpolished thin ferroelectric layer in accordance with example embodiments of the present invention. In FIG. 13, the 2Pr values relative to electric fields are obtained under a relatively low downward pressure of about 1.0 psi in the surface polishing process. In FIG. 13, “A” represents the 2Pr value of the unpolished thin ferroelectric layer, and “B” indicates the 2Pr value of the polished thin ferroelectric layer for about 30 seconds. Additionally, “C” indicates the 2Pr value of the polished thin ferroelectric layer for about 60 seconds, and “D” represents the 2Pr value of the polished thin ferroelectric layer for about 90 seconds.

As shown in FIG. 13, under the relatively low downward pressure of about 1.0 psi and the applied electric field of about 200 kV/cm, the unpolished thin ferroelectric layer A has a maximum 2Pr value of about 44.2 μC/cm², and the polished thin ferroelectric layer B has a maximum 2Pr value of about 44.1 μC/cm². When the surface polishing process is carried out for about 30 seconds, the polished thin ferroelectric layer B has the maximum 2Pr value substantially identical to that of the unpolished thin ferroelectric layer A. The polished thin ferroelectric layer C has a maximum 2Pr value of about 39.7 μC/cm², and the polished thin ferroelectric layer D has a maximum 2Pr value of about 35.2 μC/cm². When the time of the surface polishing process increases under the downward pressure of about 1.0 psi, the polished thin ferroelectric layers C and D have slightly reduced maximum 2Pr values.

FIG. 14 is a graph illustrating 2Pr values of polished thin ferroelectric layers and an unpolished thin ferroelectric layer in accordance with example embodiments of the present invention. In FIG. 14, the 2Pr values relative to electric fields are obtained under a relatively low downward pressure of about 2.5 psi in the surface polishing process. In FIG. 14, “E” represents the 2Pr value of the unpolished thin ferroelectric layer, and “F” indicates the 2Pr value of the polished thin ferroelectric layer for about 30 seconds. In addition, “G” indicates the 2Pr value of the polished thin ferroelectric layer for about 60 seconds, and “H” represents the 2Pr value of the polished thin ferroelectric layer for about 90 seconds.

Referring to FIG. 14, under the relatively low downward pressure of about 2.5 psi and the applied electric field of about 200 kV/cm, the unpolished thin ferroelectric layer E has a maximum 2Pr value of about 44.2 μC/cm², and the polished thin ferroelectric layer F has a maximum 2Pr value of about 40.1 μC/cm². When the surface polishing process is carried out at the downward pressure of about 2.5 psi for about 30 seconds, the polished thin ferroelectric layer F has the maximum 2Pr value slightly smaller than that of the unpolished ferroelectric layer E. The polished thin ferroelectric layer G has a maximum 2Pr value of about 37.6 μC/cm², and the polished thin ferroelectric layer H for about 90 seconds has a maximum 2Pr value of about 28.4 μC/cm². When the time of the surface polishing process increases under the downward pressure of about 2.5 psi, the polished thin ferroelectric layers G and H have somewhat reduced maximum 2Pr values.

Referring to FIGS. 13 and 14, as the downward pressure increases, the polarization deterioration of the thin ferroelectric layers also increase because more significant stresses are generated in the surfaces of the thin ferroelectric layers. Therefore, the preliminary ferroelectric layers are advantageously polished under the low downward pressure to thereby obtain the thin ferroelectric layers having improved ferroelectric characteristics.

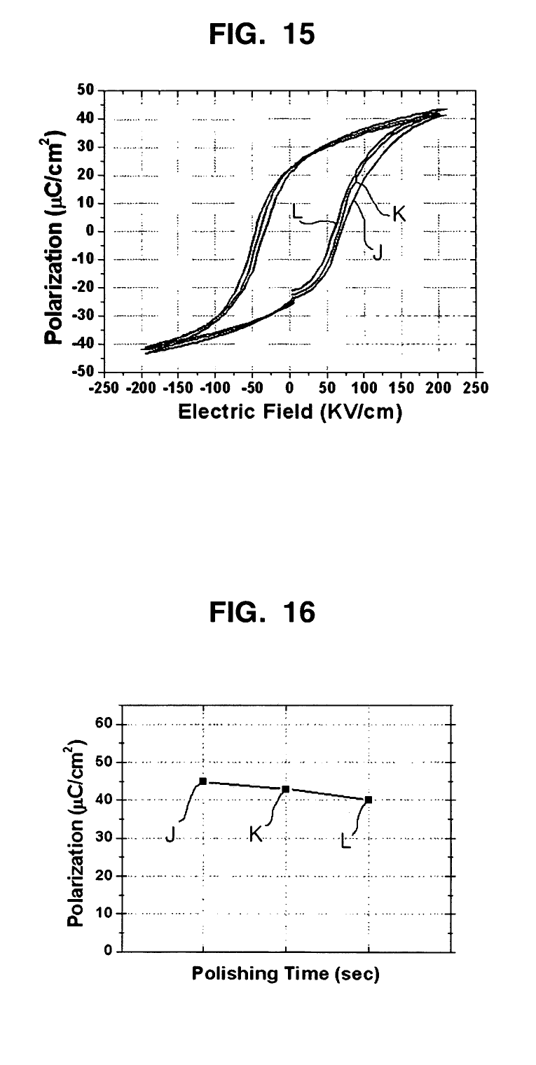

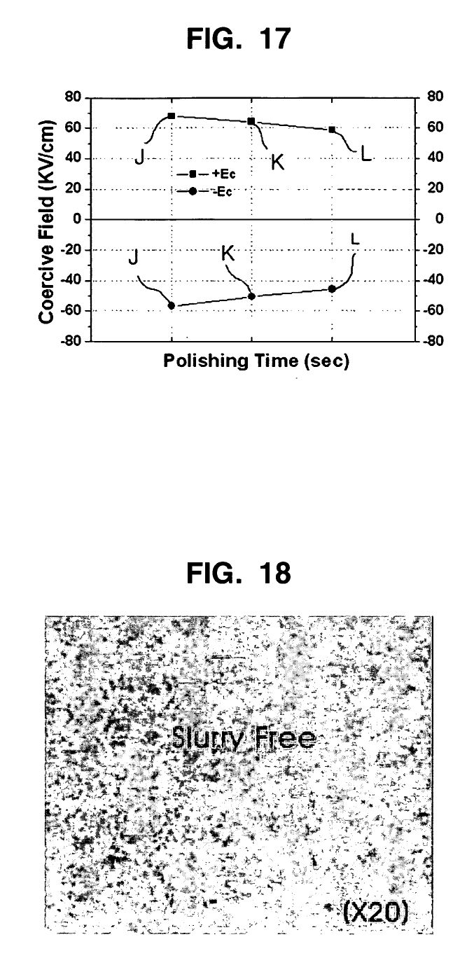

FIG. 15 is a graph illustrating polarization-electric field (P-E) hysteresis loops of an unpolished thin ferroelectric layer and polished thin ferroelectric layers in accordance with example embodiments of the present invention. FIG. 16 is a graph illustrating polarizations of an unpolished thin ferroelectric layer and polished thin ferroelectric layers relative to polishing time in accordance with example embodiments of the present invention. FIG. 17 is a graph illustrating coercive fields of an unpolished thin ferroelectric layer and polished thin ferroelectric layers relative to polishing time in accordance with example embodiments of the present invention. In FIGS. 15 to 17, the polished thin ferroelectric layers are formed through polishing processes under process conditions including a low downward pressure of about 1.0 psi and a slow rotation speed of about 10 rpm. In FIGS. 15 to 17, “J” indicates the unpolished thin ferroelectric layer, “K” represents the polished thin ferroelectric layer for about 30 seconds, and “L” means the polished thin ferroelectric layer for about 60 seconds.

When a ferroelectric layer is formed on a conductive layer, the dead layer effect may be caused at an interface between the ferroelectric layer and the conductive layer. As a thickness of the ferroelectric layer decreases, the ferroelectric layer may have a reduced polarization and an increased coercive field so that the ferroelectric layer may have poor ferroelectric characteristics. However, as shown in FIGS. 15 to 17, when a thin ferroelectric layer is formed through the polishing process under the proper downward pressure and rotation speed, the polished ferroelectric layers K and L have the coercive fields lower than that of the unpolished thin ferroelectric layer J, whereas the polarizations and the P-E hysteresis loops of the polished ferroelectric layers K and L may not be substantially deteriorated. As a result, the polished thin ferroelectric layers may have improved ferroelectric characteristics.

Referring now to FIGS. 1 and 4, the thin ferroelectric layer 115 having the greatly improved surface conditions is cleaned in step S40. After the polishing process, slurry residues and/or polishing residues may remain on the surface of the thin ferroelectric layer 115. Additionally, damage may be generated at the surface of the thin ferroelectric layer 115 in the polishing process. Hence, the thin ferroelectric layer 115 is cleaned to remove the slurry residues and/or polishing residues from the surface of the thin ferroelectric layer 115, and also to somewhat cure the damage to the surface of the thin ferroelectric layer 115. The cleaning process may be performed for about 30 to about 90 seconds.

In one example embodiment of the present invention, the thin ferroelectric layer 115 may be cleaned using a cleaning solution that includes an ammonia solution or a nitric acid solution. In another example embodiment of the present invention, the thin ferroelectric layer 115 may be cleaned using a cleaning solution that includes an SMC solution, an SMF solution or an SC1 solution. In still another example embodiment of the present invention, the thin ferroelectric layer 115 may be cleaned using a cleaning solution that includes deionized water.

When the thin ferroelectric layer 115 is cleaned using the ammonia solution, the thin ferroelectric layer 115 may be slightly etched by an etch rate of about 1 Å/minute to about 5 Å/minute. Therefore, the slurry residues and/or the polishing residues are removed from the surface of the thin ferroelectric layer 115, and also the damage to the surface of the thin ferroelectric layer 115 is primarily cured. When the thin ferroelectric layer 115 is cleaned using the SMF solution, the time for cleaning the thin ferroelectric layer 115 may be advantageously reduced because the SMF solution may etch the thin ferroelectric layer 115 by an etch rate of about 55 Å/minute to about 60 Å/minute. When the thin ferroelectric layer 115 is cleaned using the SMC solution or the SC1 solution, the time for cleaning the thin ferroelectric layer 115 may be substantially identical to that of the ammonia solution because the SMC solution and the SC1 solution may remove the thin ferroelectric layer 115 by etch rates of about 2 Å/minute to about 6 Å/minute, respectively. When the thin ferroelectric layer 115 is cleaned using the nitric acid solution, the time for cleaning the thin ferroelectric layer 115 may be advantageously reduced because the nitric solution may etch the thin ferroelectric layer 115 by an etch rate of about 20 Å/minute to about 25 Å/minute.

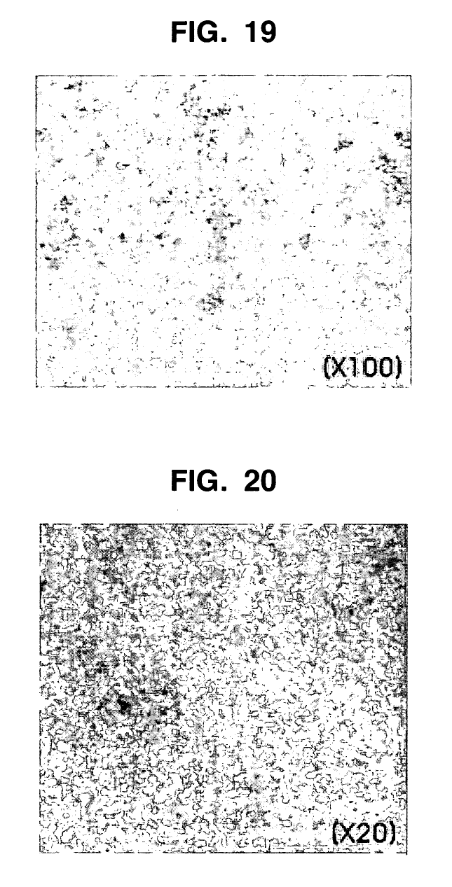

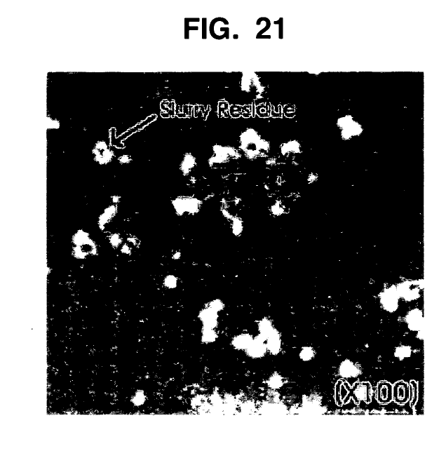

FIG. 18 is a picture showing a surface of a thin ferroelectric layer cleaned using an ammonia solution obtained using an SEM in accordance with an example embodiment of the present invention, and FIG. 19 is an enlarged picture showing the surface of the thin ferroelectric layer in FIG. 18. FIG. 20 is a picture showing a surface of a thin ferroelectric layer cleaned using deionized water obtained using an SEM in accordance with an example embodiment of the present invention, and FIG. 21 is an enlarged picture showing the surface of the thin ferroelectric layer in FIG. 20. In FIGS. 18 and 20, the surfaces of the thin ferroelectric layers are magnified by a ratio of about 20. In FIGS. 19 and 21, the surfaces of the thin ferroelectric layers are magnified by a ratio of about 100.

Referring to FIGS. 20 and 21, when the thin ferroelectric layer is cleaned using the deionized water, the slurry residues and the polishing residues remain on the surface of the thin ferroelectric layer. On the other hand, as shown in FIGS. 18 and 19, the slurry residues and the polishing residues are completely removed from the surface of the thin ferroelectric layer when the thin ferroelectric layer is cleaned using the ammonia solution. Therefore, the ammonia solution may effectively remove the slurry residues and the polishing residues from the surface of the thin ferroelectric layer.

Referring now to FIGS. 1 and 4, in step S50, the thin ferroelectric layer 115 is cured to completely remove the damage to the surface of the thin ferroelectric layer 115 generated in the above-described polishing process. The thin ferroelectric layer 115 may be cured by thermally treating the surface of the thin ferroelectric layer 115 at a temperature of about 500° C. to about 600° C. for about 30 to about 90 seconds. For example, the thin ferroelectric layer 115 is cured by a rapid thermal process (RTP). When the curing process is performed on the thin ferroelectric layer 115, the damage to the thin ferroelectric layer 115 generated in the polishing process may be completely cured. The curing process may be carried out under an inactive gas atmosphere. The inactive gas may include a nitrogen gas, a helium gas, an argon gas, a xenon gas, etc.

Measurements of Characteristics of Thin Ferroelectric Layers Relative to Process Conditions of Polishing Processes

The characteristics of thin ferroelectric layers of various Examples and Comparative Examples were measured to identify variations of ferroelectric and electrical characteristics relative to the process conditions of the polishing processes.

### EXAMPLE 1

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first conductive layer had an average thickness of about 300 Å, and the second conductive layer had an average thickness of about 1,200 Å. The preliminary ferroelectric layer had an average thickness of about 1,000 Å.

A surface of the preliminary ferroelectric layer was polished using a slurry by a CMP process to thereby form a thin ferroelectric layer. The slurry included an abrasive that contains acidic silica having a pH of about 2.5. The preliminary ferroelectric layer was polished for about 30 seconds. In the CMP process, a downward pressure was about 8.5 psi, and a rotation speed of a polishing pad was about 40 rpm. That is, the downward pressure and the rotation speed of the polishing pad were relatively high.

### EXAMPLE 2

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first conductive layer had an average thickness of about 300 Å, and the second conductive layer had an average thickness of about 1,200 Å. The preliminary ferroelectric layer had an average thickness of about 1,000 Å.

A surface of the preliminary ferroelectric layer was polished using a slurry by a CMP process so that a thin ferroelectric layer was formed on the second conductive layer. The slurry included an abrasive that contains acidic silica having a pH of about 2.1. The preliminary ferroelectric layer was polished for about 60 seconds. In the CMP process, a downward pressure was about 8.5 psi, and a rotation speed of a polishing pad was about 40 rpm. The downward pressure and the rotation speed of the polishing pad were relatively high.

### EXAMPLE 3

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers had average thicknesses substantially identical to those of the first and the second conductive layers in Example 1. In addition, the preliminary ferroelectric layer had an average thickness substantially identical to that of the preliminary ferroelectric layer in Example 1.

A surface of the preliminary ferroelectric layer was polished using a slurry by a CMP process to form a thin ferroelectric layer on the second conductive layer. The slurry included an abrasive that contains acidic silica having a pH of about 2.1. The preliminary ferroelectric layer was polished for about 60 seconds. In the CMP process, a downward pressure was about 8.5 psi, and a rotation speed of a polishing pad was about 40 rpm. The downward pressure and the rotation speed of the polishing pad were relatively high.

### COMPARATIVE EXAMPLE 1

After a first conductive layer and a second conductive layer were sequentially formed on a substrate, a thin ferroelectric layer was formed on the second conductive layer without a CMP process. The first and the second conductive layers were formed using titanium aluminum nitride and iridium, respectively. The thin ferroelectric layer was formed using PZT by an MOCVD process. The first and the second conductive layers had average thicknesses substantially identical to those of the first and the second conductive layers in Example 1. The thin ferroelectric layer had an average thickness of about 1,100 Å.

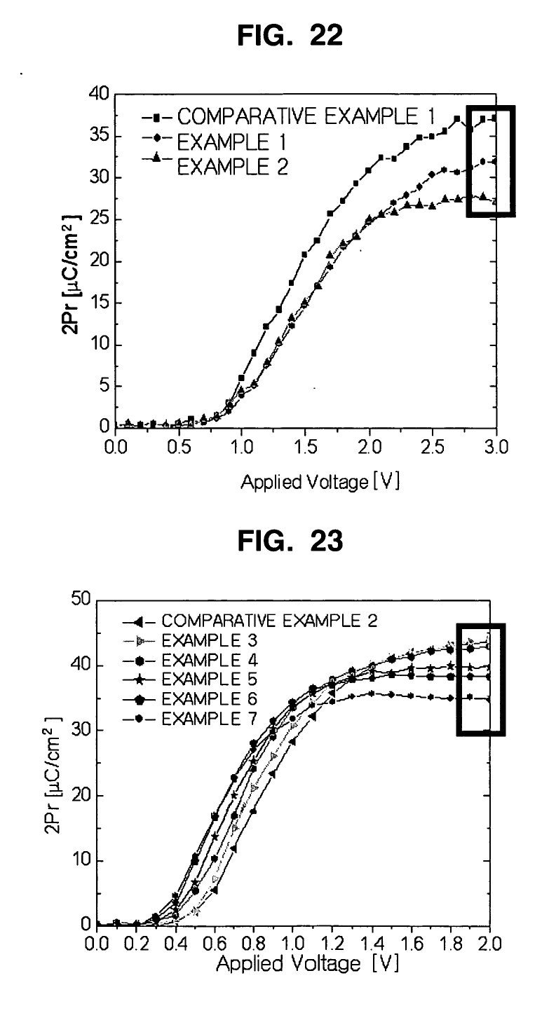

FIG. 22 is a graph illustrating 2Pr values of the thin ferroelectric layers in accordance with Comparative Example 1 and Examples 1 and 2.

Referring to FIG. 22, the thin ferroelectric layer of Comparative Example 1 had the 2Pr value of about 37.3 μC/cm². The thin ferroelectric layers of Examples 1 and 2 had the 2Pr value of about 33.1 μC/cm² and 27.0 μC/cm², respectively. When the preliminary ferroelectric layers were polished under the high downward pressure of about 8.5 psi and the rotation speed of about 40 rpm, the thin ferroelectric layers had relatively low 2Pr values because stress might be generated at the surfaces of the thin ferroelectric layers in the polishing process. That is, when the polishing process was performed under process conditions such as the high downward pressure and the rapid rotation speed, the 2Pr values of the thin ferroelectric layers were gradually reduced as the polishing time became longer. Therefore, the thin ferroelectric layers had poor ferroelectric characteristics under the high downward pressure and the rapid rotation speed.

### EXAMPLE 3

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers had average thicknesses substantially identical to those of the first and the second conductive layers in Example 1. The preliminary ferroelectric layer had an average thickness of about 1,100 Å.

A surface of the preliminary ferroelectric layer was polished using a slurry by a CMP process to thereby form a thin ferroelectric layer on the second conductive layer. The slurry included an abrasive that contains acidic silica having a pH of about 2.1. The preliminary ferroelectric layer was polished for about 15 seconds. In the CMP process, a downward pressure was about 1.0 psi, and a rotation speed of a polishing pad was about 10 rpm. Namely, the downward pressure and the rotation speed of the polishing pad were relatively low.

After the CMP process, the thin ferroelectric layer had an average thickness of about 920 Å.

### EXAMPLE 4

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers had average thicknesses substantially identical to those of the first and the second conductive layers in Example 1. The preliminary ferroelectric layer had an average thickness substantially identical to that of the preliminary ferroelectric layer in Example 3.

A surface of the preliminary ferroelectric layer was polished using a slurry by a CMP process so that a thin ferroelectric layer was formed on the second conductive layer. The slurry included an abrasive that contains acidic silica having a pH of about 2.5. The preliminary ferroelectric layer was polished for about 30 seconds. In the CMP process, a downward pressure was about 1.0 psi, and a rotation speed of a polishing pad was about 10 rpm. The downward pressure and the rotation speed of the polishing pad were relatively low.

After the CMP process, the thin ferroelectric layer had an average thickness of about 863 Å.

### EXAMPLE 5

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers had average thicknesses substantially identical to those of the first and the second conductive layers in Example 1. The preliminary ferroelectric layer had an average thickness substantially identical to that of the preliminary ferroelectric layer in Example 3.

A surface of the preliminary ferroelectric layer was polished using a slurry by a CMP process so that a thin ferroelectric layer was formed on the second conductive layer. The slurry included an abrasive that contains basic silica having a pH of about 10.9. The preliminary ferroelectric layer was polished for about 45 seconds. In the CMP process, a downward pressure was about 1.0 psi, and a rotation speed of a polishing pad was about 10 rpm. The downward pressure and the rotation speed of the polishing pad were relatively low.

After the CMP process, the thin ferroelectric layer had an average thickness of about 829 Å.

### EXAMPLE 6

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers had average thicknesses substantially identical to those of the first and the second conductive layers in Example 1. The preliminary ferroelectric layer had an average thickness substantially identical to that of the preliminary ferroelectric layer in Example 3.

A surface of the preliminary ferroelectric layer was polished using a slurry by a CMP process so that a thin ferroelectric layer was formed on the second conductive layer. The slurry included an abrasive that contains basic silica having a pH of about 11.2. The preliminary ferroelectric layer was polished for about 60 seconds. In the CMP process, a downward pressure was about 1.0 psi, and a rotation speed of a polishing pad was about 10 rpm. The downward pressure and the rotation speed of the polishing pad were relatively low.

After the CMP process, the thin ferroelectric layer had an average thickness of about 792 Å.

### EXAMPLE 7

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers had average thicknesses substantially identical to those of the first and the second conductive layers in Example 1. The preliminary ferroelectric layer had an average thickness substantially identical to that of the preliminary ferroelectric layer in Example 3.

A surface of the preliminary ferroelectric layer was polished using a slurry by a CMP process so that a thin ferroelectric layer was formed on the second conductive layer. The slurry included an abrasive that contains acidic silica having a pH of about 2.1. The preliminary ferroelectric layer was polished for about 90 seconds. In the CMP process, a downward pressure was about 1.0 psi, and a rotation speed of a polishing pad was about 10 rpm. The downward pressure and the rotation speed of the polishing pad were relatively low.

After the CMP process, the thin ferroelectric layer had an average thickness of about 685 Å.

### COMPARATIVE EXAMPLE 2

After a first conductive layer and a second conductive layer were sequentially formed on a substrate, a thin ferroelectric layer was formed on the second conductive layer without a CMP process. The first and the second conductive layers were formed using titanium aluminum nitride and iridium, respectively. The thin ferroelectric layer was formed using PZT by an MOCVD process. The first and the second conductive layers had average thicknesses substantially identical to those of the first and the second conductive layers in Example 1. The thin ferroelectric layer had an average thickness of about 1,100 Å.

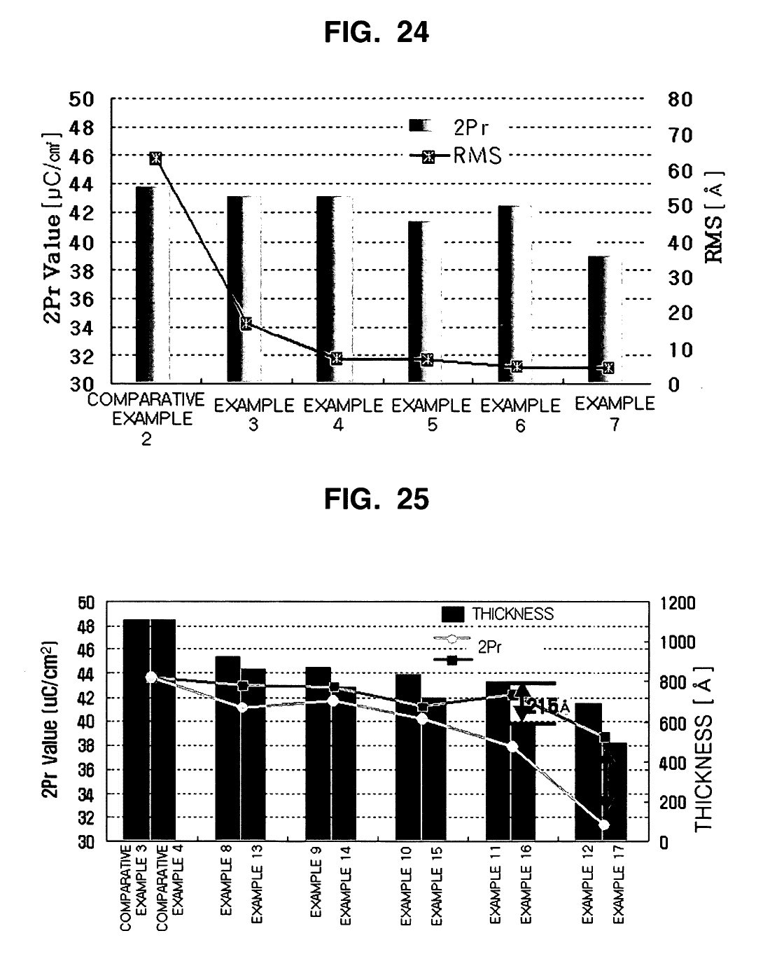

FIG. 23 is a graph illustrating 2Pr values of the thin ferroelectric layers in accordance with Comparative Example 2 and Examples 3 to 7, and FIG. 24 is a graph illustrating the 2Pr values and RMS values of the thin ferroelectric layers in accordance with Comparative Example 2 and Examples 3 to 7.

Referring to FIGS. 23 and 24, the thin ferroelectric layer of Comparative Example 2 had the 2Pr value of about 43.8 μC/cm² and the RMS value of about 45.9 Å. The thin ferroelectric layer of Example 3 had the 2Pr value of about 43.2 μC/cm² and the RMS value of about 14.7 Å, and the thin ferroelectric layer of Example 4 had the 2Pr value of about 43.1 μC/cm² and the RMS value of about 9.9 Å. The thin ferroelectric layer of Example 5 had the 2Pr value of about 41.6 μC/cm² and the RMS value of about 9.7 Å, and the thin ferroelectric layer of Example 6 had the 2Pr value of about 42.4 μC/cm² and the RMS value of about 5.5 Å. In addition, the thin ferroelectric layer of Example 7 had the 2Pr value of about 38.0 μC/cm² and the RMS value of about 5.2 Å

As shown in FIGS. 23 and 24, when the preliminary ferroelectric layers were polished under the low downward pressure of about 1.0 psi and the rotation speed of about 10 rpm, the thin ferroelectric layers had slightly low 2Pr values as the polishing time became longer, whereas the RMS values of the thin ferroelectric layers were greatly reduced relative to the polishing time. However, when the polishing process was performed for above about 60 seconds, the thin ferroelectric layer had a low 2Pr value although the surface roughness of the thin ferroelectric layer was improved so that the thin ferroelectric layer had poor retention characteristics.

### EXAMPLE 8

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers had average thicknesses of about 300 Å and about 1,200 Å, respectively. The preliminary ferroelectric layer had an average thickness of about 1,151 Å.

A surface of the preliminary ferroelectric layer was polished using a slurry by a CMP process so that a thin ferroelectric layer was formed on the second conductive layer. The slurry included an abrasive that contains basic silica having a pH of about 10.2. The preliminary ferroelectric layer was polished for about 15 seconds. In the CMP process, a downward pressure was about 1.0 psi, and a rotation speed of a polishing pad was about 10 rpm. The downward pressure and the rotation speed of the polishing pad were relatively low. After the CMP process, the thin ferroelectric layer had an average thickness of about 942 Å.

### EXAMPLE 9

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers and the preliminary ferroelectric layer had average thicknesses substantially identical to those of the first and the second conductive layers and the preliminary ferroelectric layer in Example 8.

A surface of the preliminary ferroelectric layer was polished using a slurry by a CMP process so that a thin ferroelectric layer was formed on the second conductive layer. The slurry included an abrasive that contains basic silica having a pH of about 10.35. The preliminary ferroelectric layer was polished for about 30 seconds. In the CMP process, a downward pressure was about 1.0 psi, and a rotation speed of a polishing pad was about 10 rpm. The downward pressure and the rotation speed of the polishing pad were relatively low. After the CMP process, the thin ferroelectric layer had an average thickness of about 864 Å.

### EXAMPLE 10

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers and the preliminary ferroelectric layer had average thicknesses substantially identical to those of the first and the second conductive layers and the preliminary ferroelectric layer in Example 8.

A surface of the preliminary ferroelectric layer was polished using a slurry by a CMP process so that a thin ferroelectric layer was formed on the second conductive layer. The slurry included an abrasive that contains acidic silica having a pH of about 2.3. The preliminary ferroelectric layer was polished for about 45 seconds. In the CMP process, a downward pressure was about 1.0 psi, and a rotation speed of a polishing pad was about 10 rpm. The downward pressure and the rotation speed of the polishing pad were relatively low. After the CMP process, the thin ferroelectric layer had an average thickness of about 821 Å.

### EXAMPLE 11

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers and the preliminary ferroelectric layer had average thicknesses substantially identical to those of the first and the second conductive layers and the preliminary ferroelectric layer in Example 8.

A surface of the preliminary ferroelectric layer was polished using a slurry by a CMP process so that a thin ferroelectric layer was formed on the second conductive layer. The slurry included an abrasive that contains acidic silica having a pH of about 2.5. The preliminary ferroelectric layer was polished for about 60 seconds. In the CMP process, a downward pressure was about 1.0 psi, and a rotation speed of a polishing pad was about 10 rpm. The downward pressure and the rotation speed of the polishing pad were relatively low. After the CMP process, the thin ferroelectric layer had an average thickness of about 796 Å.

### EXAMPLE 12

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers and the preliminary ferroelectric layer had average thicknesses substantially identical to those of the first and the second conductive layers and the preliminary ferroelectric layer in Example 8.

A surface of the preliminary ferroelectric layer was polished using a slurry by a CMP process so that a thin ferroelectric layer was formed on the second conductive layer. The slurry included an abrasive that contains acidic silica having a pH of about 2.1. The preliminary ferroelectric layer was polished for about 90 seconds. In the CMP process, a downward pressure was about 1.0 psi, and a rotation speed of a polishing pad was about 10 rpm. The downward pressure and the rotation speed of the polishing pad were relatively low. After the CMP process, the thin ferroelectric layer had an average thickness of about 693 Å.

### EXAMPLE 13

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers and the preliminary ferroelectric layer had average thicknesses substantially identical to those of the first and the second conductive layers and the preliminary ferroelectric layer in Example 8.

A surface of the preliminary ferroelectric layer was polished using a slurry by a CMP process so that a thin ferroelectric layer was formed on the second conductive layer. The slurry included an abrasive that contains acidic silica having a pH of about 2.4. The preliminary ferroelectric layer was polished for about 15 seconds. In the CMP process, a downward pressure was about 2.5 psi, and a rotation speed of a polishing pad was about 10 rpm. The downward pressure and the rotation speed of the polishing pad were relatively low. After the CMP process, the thin ferroelectric layer had an average thickness of about 846 Å.

### EXAMPLE 14

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers and the preliminary ferroelectric layer had average thicknesses substantially identical to those of the first and the second conductive layers and the preliminary ferroelectric layer in Example 8.

A surface of the preliminary ferroelectric layer was polished using a slurry by a CMP process so that a thin ferroelectric layer was formed on the second conductive layer. The slurry included an abrasive that contains acidic silica having a pH of about 2.5. The preliminary ferroelectric layer was polished for about 30 seconds. In the CMP process, a downward pressure was about 2.5 psi, and a rotation speed of a polishing pad was about 10 rpm. The downward pressure and the rotation speed of the polishing pad were relatively low. After the CMP process, the thin ferroelectric layer had an average thickness of about 783 Å.

### EXAMPLE 15

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers and the preliminary ferroelectric layer had average thicknesses substantially identical to those of the first and the second conductive layers and the preliminary ferroelectric layer in Example 8.

A surface of the preliminary ferroelectric layer was polished using a slurry by a CMP process so that a thin ferroelectric layer was formed on the second conductive layer. The slurry included an abrasive that contains basic silica having a pH of about 11.3. The preliminary ferroelectric layer was polished for about 45 seconds. In the CMP process, a downward pressure was about 2.5 psi, and a rotation speed of a polishing pad was about 10 rpm. The downward pressure and the rotation speed of the polishing pad were relatively low. After the CMP process, the thin ferroelectric layer had an average thickness of about 725 Å.

### EXAMPLE 16

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers and the preliminary ferroelectric layer had average thicknesses substantially identical to those of the first and the second conductive layers and the preliminary ferroelectric layer in Example 8.

A surface of the preliminary ferroelectric layer was polished using a slurry by a CMP process so that a thin ferroelectric layer was formed on the second conductive layer. The slurry included an abrasive that contains basic silica having a pH of about 11.0. The preliminary ferroelectric layer was polished for about 60 seconds. In the CMP process, a downward pressure was about 2.5 psi, and a rotation speed of a polishing pad was about 10 rpm. The downward pressure and the rotation speed of the polishing pad were relatively low. After the CMP process, the thin ferroelectric layer had an average thickness of about 581 Å.

### EXAMPLE 17

After a first conductive layer and a second conductive layer were sequentially formed on a substrate, a preliminary ferroelectric layer was formed on the second conductive layer. The first and the second conductive layers were formed using titanium aluminum nitride and iridium, respectively. The preliminary ferroelectric layer was formed using PZT by an MOCVD process. The first and the second conductive layers and the preliminary ferroelectric layer had average thicknesses substantially identical to those of the first and the second conductive layers and the preliminary ferroelectric layer in Example 8.

A surface of the preliminary ferroelectric layer was polished using a slurry by a CMP process so that a thin ferroelectric layer was formed on the second conductive layer. The slurry included an abrasive that contains basic silica having a pH of about 10.9. The preliminary ferroelectric layer was polished for about 90 seconds. In the CMP process, a downward pressure was about 2.5 psi, and a rotation speed of a polishing pad was about 10 rpm. The downward pressure and the rotation speed of the polishing pad were relatively low. After the CMP process, the thin ferroelectric layer had an average thickness of about 501 Å.

### COMPARATIVE EXAMPLE 3

After a first conductive layer and a second conductive layer were sequentially formed on a substrate, a thin ferroelectric layer was formed on the second conductive layer without a CMP process. The first and the second conductive layers were formed using titanium aluminum nitride and iridium, respectively. The thin ferroelectric layer was formed using PZT by an MOCVD process. The first and the second conductive layers had average thicknesses substantially identical to those of the first and the second conductive layers in Example 8. The thin ferroelectric layer had an average thickness of about 1,152 Å.

### COMPARATIVE EXAMPLE 4

After a first conductive layer and a second conductive layer were sequentially formed on a substrate, a thin ferroelectric layer was formed on the second conductive layer without a CMP process. The first and the second conductive layers were formed using titanium aluminum nitride and iridium, respectively. The thin ferroelectric layer was formed using PZT by an MOCVD process. The first and the second conductive layers had average thicknesses substantially identical to those of the first and the second conductive layers in Example 8. The thin ferroelectric layer had an average thickness of about 1,151 Å.

FIG. 25 is a graph illustrating 2Pr values and thicknesses of the thin ferroelectric layers in accordance with Examples 8 to 17 and Comparative Examples 3 and 4.

Referring to FIG. 25, the thin ferroelectric layers of Comparative Examples 3 and 4 had the thicknesses of about 1,152 Å and about 1,151 Å, and 2Pr values of about 43.8 μC/cm² and about 43.7 μC/cm². The thicknesses of the thin ferroelectric layers of Examples 8 and 13 were about 942 Å and about 846 Å, respectively. The 2Pr values of the thin ferroelectric layers of Examples 8 and 13 were about 43.2 μC/cm² and about 41.5 μC/cm². The thin ferroelectric layers of Examples 9 and 14 had the thicknesses of about 864 Å and about 783 Å, and 2Pr values of about 43.0 μC/cm² and about 41.9 μC/cm². The thicknesses of the thin ferroelectric layers of Examples 10 and 15 were about 821 Å and about 725 Å, and the 2Pr values of the thin ferroelectric layers of Examples 10 and 15 were about 41.7 μC/cm² and about 40.1 μC/cm². The thicknesses of the thin ferroelectric layers of Examples 11 and 16 were about 796 Å and about 581 Å, and the 2Pr values of the thin ferroelectric layers of Examples 9 and 16 were about 42.2 μC/cm² and about 38.0 μC/cm². The thin ferroelectric layers of Examples 12 and 17 had the thicknesses of about 693 Å and about 502 Å, and 2Pr values of about 38.4 μC/cm² and about 31.6 μC/cm².

Referring to FIG. 25, when the polishing processes were performed with process conditions including the downward pressure of about 2.5 psi, the preliminary ferroelectric layers were more rapidly polished in comparison with the downward pressure of about 1.0 psi. For example, the preliminary ferroelectric layer was polished by a polishing rate of about 577 Å/minute under the downward pressure of about 1.0 psi, whereas the polishing rate of the preliminary ferroelectric layer was about 792 Å/minute under the downward pressure of about 2.5 psi. As the downward pressure was augmented, the thin ferroelectric layer might have a reduced 2Pr value even though the polishing rate of the preliminary ferroelectric layer was increased.

Method of Manufacturing a Ferroelectric Capacitor

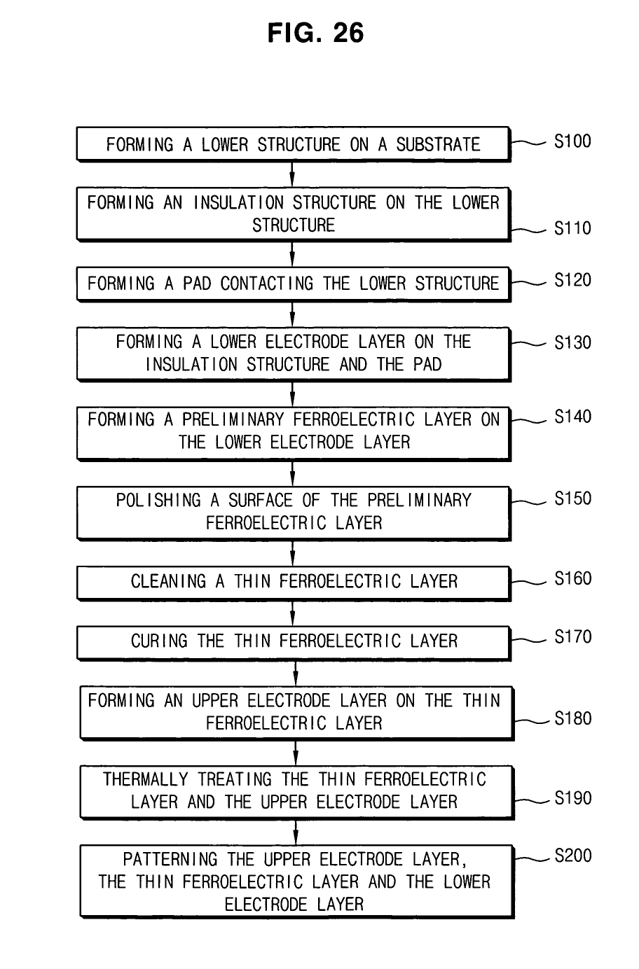

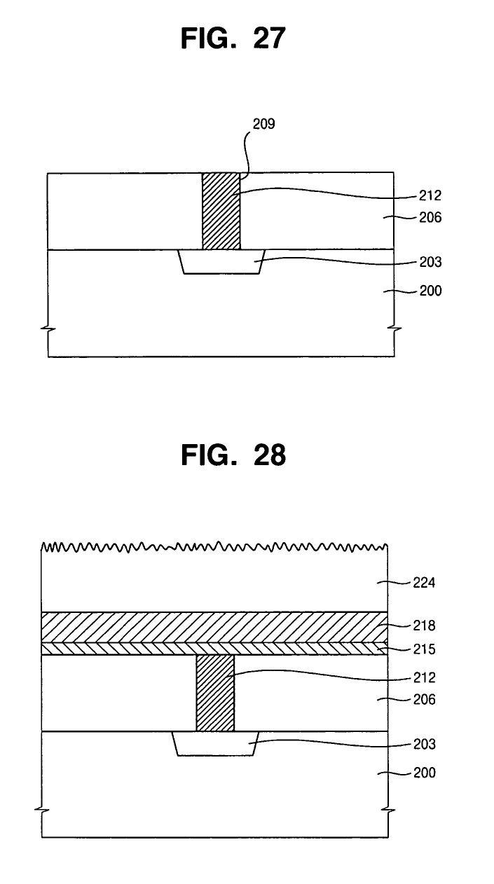

FIG. 26 is a flow chart illustrating a method of manufacturing a ferroelectric capacitor in accordance with an example embodiment of the present invention, and FIGS. 27 to 30 are cross-sectional views illustrating a method of manufacturing a ferroelectric capacitor in accordance with an example embodiment of the present invention.

Referring to FIGS. 26 and 27, a lower structure 203 is formed on a semiconductor substrate 200 in step S100. The substrate 200 may include a semiconductor substrate or a metal oxide substrate. For example, the substrate 200 includes a silicon wafer, an SOI substrate, a single crystalline aluminum oxide substrate, a single crystalline strontium titanium oxide substrate, a single crystalline magnesium oxide substrate, etc. The lower structure 203 may include a contact region, a conductive wiring, a conductive pattern, a pad, a contact, a plug, a gate structure, a transistor, etc.

An insulation structure 206 is formed on the substrate 200 to cover the lower structure 203 in step S110. The insulation structure 206 may be formed by a CVD process, a PECVD process, an HDP-CVD process, an ALD process, etc.

In one example embodiment of the present invention, the insulation structure 206 may include at least one insulation layer or an insulation interlayer formed using an oxide such as BPSG, PSG, USG, SOG, FOx, PE-TEOS, HDP-CVD oxide, etc.

In another example embodiment of the present invention, the insulation structure 206 may include a first insulation layer and a second insulation layer. Here, the first insulation layer may be formed using the oxide, and the second insulation layer may be formed using a nitride such as silicon nitride or an oxynitride such as silicon oxynitride.

In still another example embodiment of the present invention, the insulation structure 206 may include a plurality of first insulation layers and a plurality of second insulation layers alternatively formed on the substrate 200.

The insulation structure 206 is partially etched to thereby form a hole 209 that partially exposes the lower structure 203. In one example embodiment of the present invention, a first photoresist pattern (not shown) is formed on the insulation structure 206, and then the hole 209 is formed through the insulation structure 206 by etching the insulation structure 206 using the first photoresist pattern as an etching mask. The first photoresist pattern is removed from the insulation structure 206 by an ashing process and/or a stripping process. In another example embodiment of the present invention, an anti-reflection layer may be formed between the insulation structure 206 and the first photoresist pattern to ensure a process margin of the etching process for forming the hole 209.

After a first conductive layer is formed on the insulation structure 206 to fill up the hole 209, the first conductive layer is partially removed until the insulation structure 206 is exposed, thereby forming a pad 212 in the hole 209 in step S120. The first conductive layer may be removed by a CMP process, an etch back process, or a combination process of CMP and etch back. The pad 212 may be formed using a conductive material such as a metal, a conductive metal nitride or polysilicon doped with impurities. For example, the pad 212 is formed using tungsten, aluminum, copper, titanium, tungsten nitride, aluminum nitride, titanium nitride, etc. Additionally, the first conductive layer may be formed by a sputtering process, a CVD process, an ALD process, a PLD process, etc. The pad 212 electrically connects a lower electrode 245 (see FIG. 30) to the lower structure 203.

Referring to FIGS. 26 and 28, a lower electrode layer 221 is formed on the insulation structure 206 and the pad 212 in step S130. The lower electrode layer 221 includes a first lower electrode film 215 formed on the pad 212 and the insulation structure 206, and a second lower electrode film 218 formed on the first lower electrode film 215.

The first lower electrode film 215 may be formed using a metal nitride by a sputtering process, a CVD process, a PLD process or an ALD process. For example, the first lower electrode film 215 is formed using titanium aluminum nitride, aluminum nitride, titanium nitride, titanium silicon nitride, tantalum nitride, tungsten nitride, tantalum silicon nitride, etc. The first lower electrode film 215 may have a thickness of about 50 to about 300 Å measured from an upper face of the insulation structure 206.

The lower electrode film 218 may be formed using a metal such as ruthenium, iridium, palladium, platinum, gold, etc. The second lower electrode film 218 may be formed on the first lower electrode film 215 by a sputtering process, a CVD process, an ALD process, a PLD process, etc. For example, the second lower electrode film 218 is formed using iridium by the sputtering process. The second lower electrode film 218 may have a thickness of about 300 to about 1,200 Å measured from an upper face of the first lower electrode film 215. In a formation of the second lower electrode film 218, a reaction chamber where the substrate 200 is loaded may have a temperature of about 20 to about 350° C. and a pressure of about 3 to about 10 mTorr. The second lower electrode film 218 may be formed by applying a power of about 300 to about 1,000 W under an inactive gas atmosphere. The inactive gas may include a nitrogen gas, an argon gas, a helium gas, etc. For example, the inactive gas includes the argon gas only, and has a flow rate of about 10 to about 100 sccm.

In one example embodiment of the present invention, an adhesion layer may be formed between the insulation structure 206 and the first lower electrode film 215 to improve an adhesive strength between the insulation structure 206 and the first lower electrode film 215. The adhesion layer may be formed using a metal or a conductive metal nitride by a sputtering process, a CVD process, an ALD process or a PLD process. For example, the adhesion layer is formed using titanium, tantalum, aluminum, tungsten, titanium nitride, tantalum nitride, aluminum nitride, tungsten nitride, etc.

In another example embodiment of the present invention, the adhesion layer may be formed using the metal or the conductive metal nitride substantially identical to that of the pad 212.

In still another example embodiment of the present invention, the adhesion layer may be formed using the metal or the conductive metal nitride substantially different from that of the pad 212.

Referring now to FIGS. 26 and 28, a preliminary ferroelectric layer 224 is formed on the second lower electrode film 218 in step S140. The preliminary ferroelectric layer 224 may be formed by an MOCVD process, a sol-gel process or a CVD process. The preliminary ferroelectric layer 224 may have a thickness of about 200 Å to about 1,200 Å measured from an upper face of the second lower electrode film 218.

In one example embodiment of the present invention, the preliminary ferroelectric layer 224 may be formed using a ferroelectric material such as PZT, SBT, BLT, PLZT or BST. In another example embodiment of the present invention, the preliminary ferroelectric layer 224 may be formed using a ferroelectric material doped with a metal. For example, the preliminary ferroelectric layer 224 is formed using PZT, PLZT, SBT, BLT or BST doped with calcium, lanthanum, manganese or bismuth. In still another example embodiment of the present invention, the preliminary ferroelectric layer 224 may be formed using a metal oxide such as titanium oxide, tantalum oxide, aluminum oxide, zinc oxide, hafnium oxide, etc.

The preliminary ferroelectric layer 224 may be advantageously formed using PZT by the MOCVD process. Here, the preliminary ferroelectric layer 224 may be formed using an MOCVD apparatus described with reference to FIG. 3. As described above, the preliminary ferroelectric layer 224 may have a first RMS value of about 40 Å to about 80 Å and a first P-V value of about 200 Å to about 600 Å. Thus, a surface of the preliminary ferroelectric layer 224 may have a poor roughness.

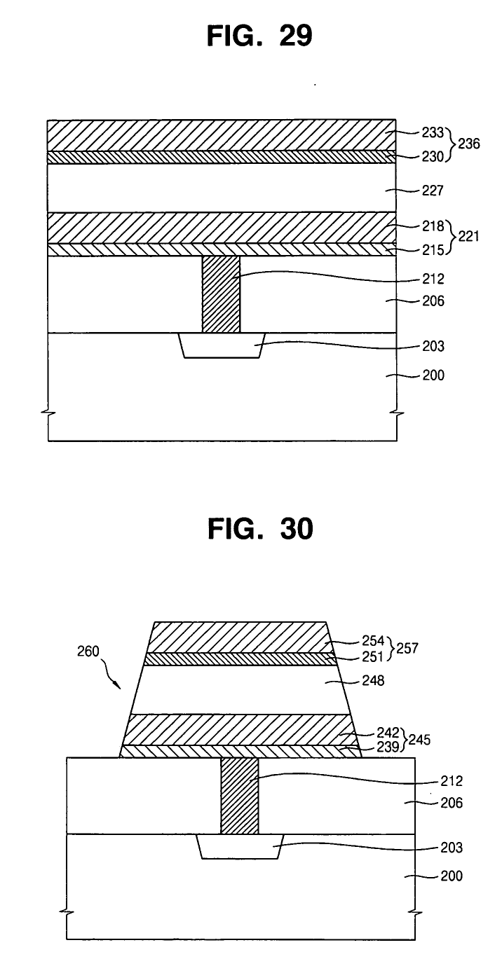

Referring to FIGS. 26 and 29, the preliminary ferroelectric layer 224 is polished by a polishing process substantially identical to the polishing process described with reference to FIG. 8, thereby forming a thin ferroelectric layer 227 in step S150. After the polishing process, the thin ferroelectric layer 227 may have a second RMS value of about 2 to about 10 Å and a second P-V value of about 20 Å to about 60 Å. Thus, the thin ferroelectric layer 227 may have a greatly uniform surface.

In step S160, the thin ferroelectric layer 227 is cleaned to remove slurry residues and/or polishing residues from the surface of the thin ferroelectric layer 227. Additionally, a damage to the surface of the thin ferroelectric layer 227 is somewhat cured through the cleaning process when the damage is generated in the polishing process. The cleaning process for the thin ferroelectric layer 227 is substantially identical to the cleaning process described with reference to FIGS. 1 and 4.

To remove the damage to the surface of the thin ferroelectric layer 227, the thin ferroelectric layer 227 is cured in step S170. The surface of the thin ferroelectric layer 227 may be cured by thermally treating the thin ferroelectric layer 227. The curing process for the thin ferroelectric layer 227 may be performed at a temperature of about 500° C. to about 600° C. for about 30 seconds to about 90 seconds. For example, the thin ferroelectric layer 227 is cured through an RTP.

In step S180, an upper electrode layer 236 is formed on the thin ferroelectric layer 227. The upper electrode layer 236 includes a first upper electrode film 230 formed on the thin ferroelectric layer 227, and a second upper electrode film 233 formed on the first upper electrode film 230.

The first upper electrode film 230 may be formed on the thin ferroelectric layer 227 by a sputtering process, a CVD process, a PLD process or an ALD process to have a thickness of about 10 Å to about 300 Å. The first upper electrode film 230 may be formed using a metal oxide such as SRO, STO, LNO or CRO. Alternatively, the first upper electrode film 230 may be formed using a metal oxide doped with a metal. For example, the first upper electrode film 230 is formed using SRO, STO, LNO or CRO doped with copper, lead or bismuth by a concentration of about 2 to about 5 atomic weight percent based on an entire atomic weight of the metal oxide.

In a formation of the first upper electrode film 230, the reaction chamber including the substrate 200 may have a temperature of about 20° C. to about 350° C. and a pressure of about 3 mTorr to about 10 mTorr. The first upper electrode film 230 may be formed in the reaction chamber by applying a power of about 300 W to about 1,000 W under an inactive gas atmosphere. The inactive gas may include an argon gas, a nitrogen gas, a helium gas or a mixture thereof. For example, the inactive gas includes the argon gas only and has a flow rate of about 10 sccm to about 100 sccm.

The second upper electrode film 233 may be formed using a metal such as iridium, ruthenium, platinum, palladium or gold. The second upper electrode film 233 may be formed on the first upper electrode film 230 by a sputtering process, a CVD process, a PLD process or an ALD process. For example, the second upper electrode film 233 is formed using iridium by the sputtering process. The second upper electrode film 233 may have a thickness of about 300 Å to about 1,000 Å.

In a formation of the second upper electrode film 233, the reaction chamber including the substrate 200 may have a temperature of about 20° C. to about 350° C. and a pressure of about 3 mTorr to about 10 mTorr. The second upper electrode film 233 may be formed in the reaction chamber by applying a power of about 300 W to about 1,000 W under an inactive gas atmosphere. The inactive gas may include an argon gas, a nitrogen gas, a helium gas or a mixture thereof. For example, the second upper electrode film 233 is formed under the inactive gas atmosphere including the argon gas only with a flow rate of about 10 sccm to about 100 sccm.

In step S190, the thin ferroelectric layer 227 and the upper electrode layer 236 are thermally treated to thereby crystallize ingredients in the thin ferroelectric layer 227 and the upper electrode layer 236. The thin ferroelectric layer 227 and the upper electrode layer 236 may be thermally treated by an RTP under an oxygen atmosphere, a nitrogen atmosphere or a mixture atmosphere including oxygen and nitrogen. The thin ferroelectric layer 227 and the upper electrode layer 236 may be thermally treated at a temperature of about 500° C. to about 600° C. for about 30 seconds to about 3 minutes.

Referring to FIGS. 26 and 30, a second photoresist pattern (not shown) is formed on the second upper electrode film 233. Using the second photoresist pattern as an etching mask, the second upper electrode film 233, the first upper electrode film 230, the thin ferroelectric layer 227, the second lower electrode film 218 and the first lower electrode film 215 are sequentially etched, thereby forming the ferroelectric capacitor 260 over the substrate 200 in step S200. The ferroelectric capacitor 260 includes the lower electrode 245, a thin ferroelectric layer pattern 248 and the upper electrode 257. The lower electrode 245 includes a first lower electrode film pattern 239 and a second lower electrode film pattern 242 sequentially formed on the pad 212 and the insulation structure 206. The upper electrode 227 includes a first upper electrode film pattern 251 and a second upper electrode film pattern 254 successively formed on the thin ferroelectric layer pattern 248. After the etching process is carried out, the ferroelectric capacitor 260 has a sidewall substantially inclined by an angle of about 50° to about 90° relative to a horizontal direction. For example, the ferroelectric capacitor 270 generally has a pyramid shape.

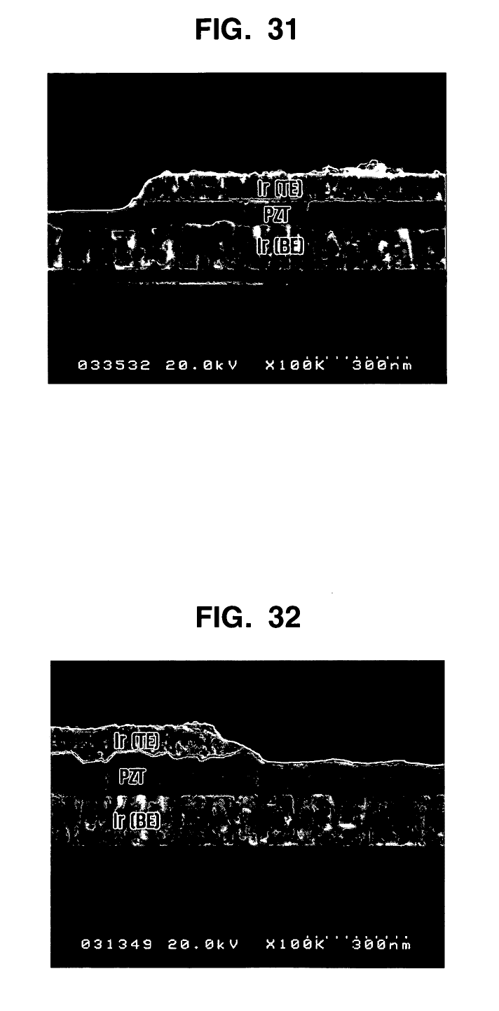

FIG. 31 is a picture showing a cross-section of a ferroelectric capacitor including a polished thin ferroelectric layer obtained using an SEM in accordance with an example embodiment of the present invention, and FIG. 32 is a picture showing a cross-section of a ferroelectric capacitor including an unpolished thin ferroelectric layer obtained using an SEM in accordance with an example embodiment of the present invention.

Referring to FIG. 32, in the ferroelectric capacitor including an unpolished thin ferroelectric layer, an upper electrode may not be firmly formed on the unpolished thin ferroelectric layer because the unpolished thin ferroelectric layer has a greatly irregular surface. In addition, the ferroelectric capacitor including an unpolished thin ferroelectric layer may have a more large leakage current from the unpolished ferroelectric layer and also charges may be irregularly distributed on a surface of the unpolished thin ferroelectric layer, thereby deteriorating electrical characteristics of the ferroelectric capacitor.

As shown in FIG. 31, since the polished thin ferroelectric layer has a very level surface, an upper electrode may be firmly attached to the polished thin ferroelectric layer and charges may be uniformly distributed on the surface of the polished thin ferroelectric layer. Therefore, the ferroelectric capacitor including the polished thin ferroelectric layer may have improved electrical characteristics.

Measurements of Characteristics of Ferroelectric Capacitors Relative to Processing Conditions of Surface Polishing Process

Hereinafter, there will be described the electrical characteristics of ferroelectric capacitors in accordance with various Examples and Comparative Examples of the present invention.

### EXAMPLE 18

A lower electrode layer including a first lower electrode film and a second lower electrode film was formed on a substrate. The first lower electrode film was formed using titanium aluminum nitride, and the second lower electrode film was formed using iridium. The first lower electrode film had an average thickness of about 300 Å, and the second lower electrode film had an average thickness of about 12,000 Å.

A preliminary ferroelectric layer was formed on the lower electrode layer. The preliminary ferroelectric layer included PZT formed by a metal organic chemical vapor deposition process. The preliminary ferroelectric layer had an average thickness of about 982 Å and a maximum thickness of about 1,012 Å.

The preliminary ferroelectric layer was polished through a CMP process for about 15 seconds so that a ferroelectric layer having a uniform surface was formed on the lower electrode layer. In the CMP process, a down pressure pressing the substrate was about 2.5 psi, and a rotation speed of a polishing pad was about 10 rpm. The ferroelectric layer had an average thickness of about 855 Å and a maximum thickness of about 899 Å.

An upper electrode layer was formed on the ferroelectric layer. The upper electrode layer included a first upper electrode film and a second upper electrode film. The first upper electrode film was formed using strontium ruthenium oxide (SRO), and the second upper electrode film was formed using iridium. The first upper electrode film had an average thickness of about 50 Å, and the second upper electrode film had an average thickness of about 600 Å.

### EXAMPLE 19

A lower electrode layer including a first lower electrode film and a second lower electrode film was formed on a substrate. The first lower electrode film was formed using titanium aluminum nitride, and the second lower electrode film was formed using iridium. Each of the first and the second lower electrode films had an average thickness substantially identical to those of Example 18.

A preliminary ferroelectric layer was formed on the lower electrode layer. The preliminary ferroelectric layer included PZT formed by a metal organic chemical vapor deposition process. The preliminary ferroelectric layer had an average thickness of about 982 Å and a maximum thickness of about 1,012 Å.

The preliminary ferroelectric layer was polished through a CMP process for about 30 seconds so that a ferroelectric layer having a uniform surface was formed on the lower electrode layer. In the CMP process, a down pressure pressing the substrate was about 2.5 psi, and a rotation speed of a polishing pad was about 10 rpm. The ferroelectric layer had an average thickness of about 770 Å and a maximum thickness of about 833 Å.

An upper electrode layer was formed on the ferroelectric layer. The upper electrode layer included a first upper electrode film and a second upper electrode film. The first upper electrode film was formed using strontium ruthenium oxide (SRO), and the second upper electrode film was formed using iridium. Each of the first and the second upper electrode films had an average thickness substantially identical to those of Example 18.

### EXAMPLE 20

A lower electrode layer including a first lower electrode film and a second lower electrode film was formed on a substrate. The first lower electrode film was formed using titanium aluminum nitride, and the second lower electrode film was formed using iridium. Each of the first and the second lower electrode films had an average thickness substantially identical to those of Example 18.

A preliminary ferroelectric layer was formed on the lower electrode layer. The preliminary ferroelectric layer included PZT formed by a metal organic chemical vapor deposition process. The preliminary ferroelectric layer had an average thickness of about 982 Å and a maximum thickness of about 1,012 Å.

The preliminary ferroelectric layer was polished through a CMP process for about 45 seconds so that a ferroelectric layer having a uniform surface was formed on the lower electrode layer. In the CMP process, a down pressure pressing the substrate was about 2.5 psi, and a rotation speed of a polishing pad was about 10 rpm. The ferroelectric layer had an average thickness of about 715 Å and a maximum thickness of about 798 Å.

An upper electrode layer was formed on the ferroelectric layer. The upper electrode layer included a first upper electrode film and a second upper electrode film. The first upper electrode film was formed using strontium ruthenium oxide (SRO), and the second upper electrode film was formed using iridium. Each of the first and the second upper electrode films had an average thickness substantially identical to those of Example 18.

### EXAMPLE 21

A lower electrode layer including a first lower electrode film and a second lower electrode film was formed on a substrate. The first lower electrode film was formed using titanium aluminum nitride, and the second lower electrode film was formed using iridium. Each of the first and the second lower electrode films had an average thickness substantially identical to those of Example 18.

A preliminary ferroelectric layer was formed on the lower electrode layer. The preliminary ferroelectric layer included PZT formed by a metal organic chemical vapor deposition process. The preliminary ferroelectric layer had an average thickness of about 982 Å and a maximum thickness of about 1,012 Å.

The preliminary ferroelectric layer was polished through a CMP process for about 60 seconds so that a ferroelectric layer having a uniform surface was formed on the lower electrode layer. In the CMP process, a down pressure pressing the substrate was about 2.5 psi, and a rotation speed of a polishing pad was about 10 rpm. The ferroelectric layer had an average thickness of about 577 Å and a maximum thickness of about 736 Å.

An upper electrode layer was formed on the ferroelectric layer. The upper electrode layer included a first upper electrode film and a second upper electrode film. The first upper electrode film was formed using strontium ruthenium oxide (SRO), and the second upper electrode film was formed using iridium. Each of the first and the second upper electrode films had an average thickness substantially identical to those of Example 18.

### EXAMPLE 22

A lower electrode layer including a first lower electrode film and a second lower electrode film was formed on a substrate. The first lower electrode film was formed using titanium aluminum nitride, and the second lower electrode film was formed using iridium. Each of the first and the second lower electrode films had an average thickness substantially identical to those of Example 18.

A preliminary ferroelectric layer was formed on the lower electrode layer. The preliminary ferroelectric layer included PZT formed by a metal organic chemical vapor deposition process. The preliminary ferroelectric layer had an average thickness of about 982 Å and a maximum thickness of about 1,012 Å.

The preliminary ferroelectric layer was polished through a CMP process for about 90 seconds so that a ferroelectric layer having a uniform surface was formed on the lower electrode layer. In the CMP process, a down pressure pressing the substrate was about 2.5 psi, and a rotation speed of a polishing pad was about 10 rpm. The ferroelectric layer had an average thickness of about 486 Å and a maximum thickness of about 696 Å.

An upper electrode layer was formed on the ferroelectric layer. The upper electrode layer included a first upper electrode film and a second upper electrode film. The first upper electrode film was formed using strontium ruthenium oxide (SRO), and the second upper electrode film was formed using iridium. Each of the first and the second upper electrode films had an average thickness substantially identical to those of Example 18.

### COMPARATIVE EXAMPLE 5

A lower electrode layer including a first lower electrode film and a second lower electrode film was formed on a substrate. The first lower electrode film was formed using titanium aluminum nitride, and the second lower electrode film was formed using iridium. Each of the first and the second lower electrode films had an average thickness substantially identical to those of Example 18.

A thin ferroelectric layer was formed on the lower electrode layer. The ferroelectric layer included PZT formed by a metal organic chemical vapor deposition process. The thin ferroelectric layer had an average thickness of about 982 Å and a maximum thickness of about 1,012 Å.

Without performing a CMP process, an upper electrode layer was formed on the thin ferroelectric layer. The upper electrode layer included a first upper electrode film and a second upper electrode film. The first upper electrode film was formed using strontium ruthenium oxide (SRO), and the second upper electrode film was formed using iridium. Each of the first and the second upper electrode films had an average thickness substantially identical to those of Example 18.

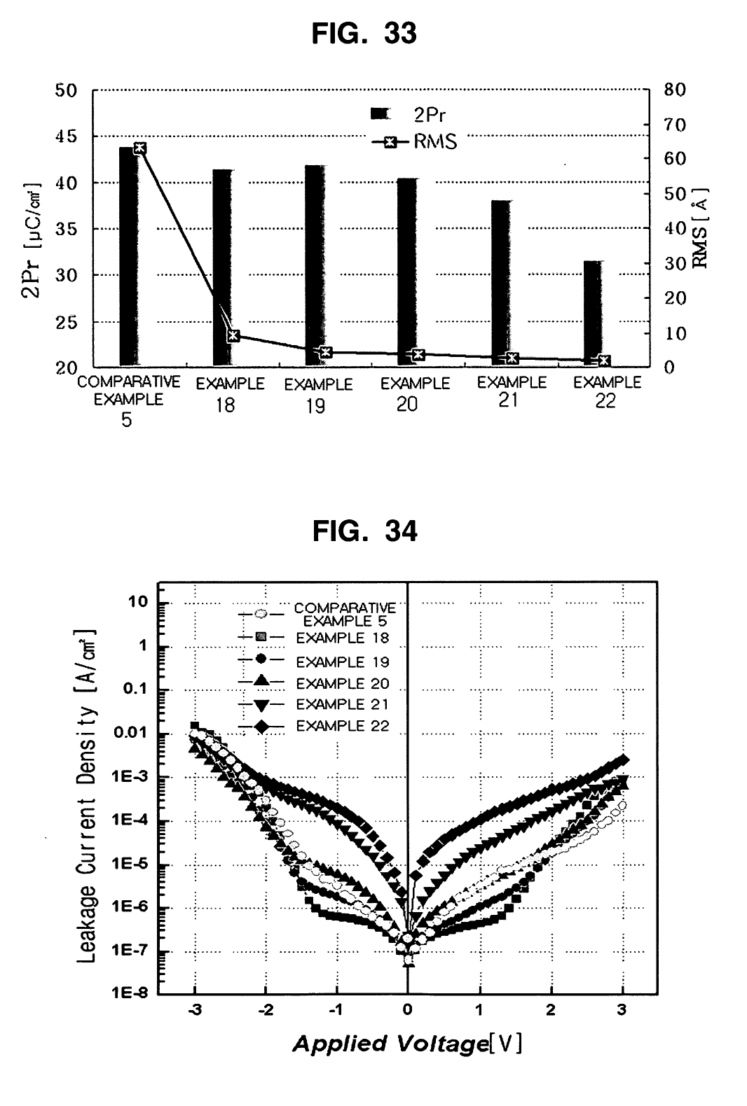

Table 1 shows average thicknesses, maximum thicknesses and RMS values of the thin ferroelectric layers and 2Pr values of the ferroelectric capacitors with respect to polishing times in accordance with Comparative Example 5 and Examples 18 to 22. FIG. 33 is a graph illustrating the 2Pr values and the RMS values of the thin ferroelectric layers relative to polishing times in accordance with Comparative Example 5 and Examples 18 to 22.

TABLE 1

| | Polishing | Average | | | |
|---|---|---|---|---|---|
| | time | thickness | Maximum | 2Pr | RMS |
| | [sec] | [Å] | thickness [Å] | [μC/cm²] | [Å] |
| Comparative | 0 | 982 | 1,012 | 43.66 | 63.44 |
| Example 5 | | | | | |
| Example 18 | 15 | 855 | 899 | 41.18 | 9.614 |
| Example 19 | 30 | 770 | 833 | 41.66 | 4.516 |
| Example 20 | 45 | 715 | 798 | 40.22 | 3.668 |
| Example 21 | 60 | 577 | 736 | 37.90 | 2.618 |
| Example 22 | 90 | 486 | 696 | 31.34 | 1.915 |

Referring to Table 1 and FIG. 33, under process conditions including the downward pressure of about 2.5 psi and the rotation speed of about 10 rpm, the preliminary ferroelectric layers of Examples 18 to 22 were relatively rapidly polished. When the polishing process was performed with the process conditions, the 2Pr values of the ferroelectric capacitors of Examples 18 to 22 were gradually reduced as the polishing time was increased although the surface of the thin ferroelectric layers of Examples 18 to 22 had improved roughness.

FIG. 34 is a graph illustrating leakage current densities of the ferroelectric capacitors relative to applied voltages in accordance with Comparative Example 5 and Examples 18 to 22.

Referring to FIG. 34, when the ferroelectric capacitors of Examples 18 and 19 were manufactured through the polishing process performed for below about 30 seconds, the ferroelectric capacitors of Examples 18 and 19 had leakage current densities lower than that of the ferroelectric capacitor of Comparative Example 5. However, the ferroelectric capacitors of Examples 20 to 22 had leakage current densities gradually higher than that of the ferroelectric capacitor of Comparative Example 5 when the polishing time exceeded about 30 seconds.

### EXAMPLE 23

A lower electrode layer including a first lower electrode film and a second lower electrode film was formed on a substrate. The first lower electrode film was formed using titanium aluminum nitride, and the second lower electrode film was formed using iridium. Each of the first and the second lower electrode films had an average thickness substantially identical to those of Example 18.

A preliminary ferroelectric layer was formed on the lower electrode layer. The preliminary ferroelectric layer included PZT formed by a metal organic chemical vapor deposition process. The preliminary ferroelectric layer had an average thickness of about 982 Å and a maximum thickness of about 1,012 Å.

The preliminary ferroelectric layer was polished through a CMP process for about 15 seconds so that a ferroelectric layer having a uniform surface was formed on the lower electrode layer. In the CMP process, a down pressure pressing the substrate was about 1.0 psi, and a rotation speed of a polishing pad was about 10 rpm. The ferroelectric layer had an average thickness of about 920 Å and a maximum thickness of about 955 Å.

An upper electrode layer was formed on the ferroelectric layer. The upper electrode layer included a first upper electrode film and a second upper electrode film. The first upper electrode film was formed using strontium ruthenium oxide (SRO), and the second upper electrode film was formed using iridium. Each of the first and the second upper electrode films had an average thickness substantially identical to those of Example 18.

### EXAMPLE 24

A lower electrode layer including a first lower electrode film and a second lower electrode film was formed on a substrate. The first lower electrode film was formed using titanium aluminum nitride, and the second lower electrode film was formed using iridium. Each of the first and the second lower electrode films had an average thickness substantially identical to those of Example 18.

A preliminary ferroelectric layer was formed on the lower electrode layer. The preliminary ferroelectric layer included PZT formed by a metal organic chemical vapor deposition process. The preliminary ferroelectric layer had an average thickness of about 982 Å and a maximum thickness of about 1,012 Å.

The preliminary ferroelectric layer was polished through a CMP process for about 30 seconds so that a ferroelectric layer having a uniform surface was formed on the lower electrode layer. In the CMP process, a down pressure pressing the substrate was about 1.0 psi, and a rotation speed of a polishing pad was about 10 rpm. The ferroelectric layer had an average thickness of about 863 Å and a maximum thickness of about 876 Å.

An upper electrode layer was formed on the ferroelectric layer. The upper electrode layer included a first upper electrode film and a second upper electrode film. The first upper electrode film was formed using strontium ruthenium oxide (SRO), and the second upper electrode film was formed using iridium. Each of the first and the second upper electrode films had an average thickness substantially identical to those of Example 18.

### EXAMPLE 25

A lower electrode layer including a first lower electrode film and a second lower electrode film was formed on a substrate. The first lower electrode film was formed using titanium aluminum nitride, and the second lower electrode film was formed using iridium. Each of the first and the second lower electrode films had an average thickness substantially identical to those of Example 18.

A preliminary ferroelectric layer was formed on the lower electrode layer. The preliminary ferroelectric layer included PZT formed by a metal organic chemical vapor deposition process. The preliminary ferroelectric layer had an average thickness of about 982 Å and a maximum thickness of about 1,012 Å.

The preliminary ferroelectric layer was polished through a CMP process for about 45 seconds so that a ferroelectric layer having a uniform surface was formed on the lower electrode layer. In the CMP process, a down pressure pressing the substrate was about 1.0 psi, and a rotation speed of a polishing pad was about 10 rpm. The ferroelectric layer had an average thickness of about 829 Å and a maximum thickness of about 842 Å.

An upper electrode layer was formed on the ferroelectric layer. The upper electrode layer included a first upper electrode film and a second upper electrode film. The first upper electrode film was formed using strontium ruthenium oxide (SRO), and the second upper electrode film was formed using iridium. Each of the first and the second upper electrode films had an average thickness substantially identical to those of Example 18.

### EXAMPLE 26

A lower electrode layer including a first lower electrode film and a second lower electrode film was formed on a substrate. The first lower electrode film was formed using titanium aluminum nitride, and the second lower electrode film was formed using iridium. Each of the first and the second lower electrode films had an average thickness substantially identical to those of Example 18.

A preliminary ferroelectric layer was formed on the lower electrode layer. The preliminary ferroelectric layer included PZT formed by a metal organic chemical vapor deposition process. The preliminary ferroelectric layer had an average thickness of about 982 Å and a maximum thickness of about 1,012 Å.

The preliminary ferroelectric layer was polished through a CMP process for about 60 seconds so that a ferroelectric layer having a uniform surface was formed on the lower electrode layer. In the CMP process, a down pressure pressing the substrate was about 1.0 psi, and a rotation speed of a polishing pad was about 10 rpm. The ferroelectric layer had an average thickness of about 792 Å and a maximum thickness of about 800 Å.

An upper electrode layer was formed on the ferroelectric layer. The upper electrode layer included a first upper electrode film and a second upper electrode film. The first upper electrode film was formed using strontium ruthenium oxide (SRO), and the second upper electrode film was formed using iridium. Each of the first and the second upper electrode films had an average thickness substantially identical to those of Example 18.

### EXAMPLE 27

A lower electrode layer including a first lower electrode film and a second lower electrode film was formed on a substrate. The first lower electrode film was formed using titanium aluminum nitride, and the second lower electrode film was formed using iridium. Each of the first and the second lower electrode films had an average thickness substantially identical to those of Example 18.

A preliminary ferroelectric layer was formed on the lower electrode layer. The preliminary ferroelectric layer included PZT formed by a metal organic chemical vapor deposition process. The preliminary ferroelectric layer had an average thickness of about 982 Å and a maximum thickness of about 1,012 Å.

The preliminary ferroelectric layer was polished through a CMP process for about 90 seconds so that a ferroelectric layer having a uniform surface was formed on the lower electrode layer. In the CMP process, a down pressure pressing the substrate was about 1.0 psi, and a rotation speed of a polishing pad was about 10 rpm. The ferroelectric layer had an average thickness of about 685 Å and a maximum thickness of about 716 Å.

An upper electrode layer was formed on the ferroelectric layer. The upper electrode layer included a first upper electrode film and a second upper electrode film. The first upper electrode film was formed using strontium ruthenium oxide (SRO), and the second upper electrode film was formed using iridium. Each of the first and the second upper electrode films had an average thickness substantially identical to those of Example 18.

### COMPARATIVE EXAMPLE 6

A lower electrode layer including a first lower electrode film and a second lower electrode film was formed on a substrate. The first lower electrode film was formed using titanium aluminum nitride, and the second lower electrode film was formed using iridium. Each of the first and the second lower electrode films had an average thickness substantially identical to those of Example 18.

A thin ferroelectric layer was formed on the lower electrode layer. The ferroelectric layer included PZT formed by a metal organic chemical vapor deposition process. The thin ferroelectric layer had an average thickness of about 982 Å and a maximum thickness of about 1,012 Å.

Without performing a CMP process, an upper electrode layer was formed on the thin ferroelectric layer. The upper electrode layer included a first upper electrode film and a second upper electrode film. The first upper electrode film was formed using strontium ruthenium oxide (SRO), and the second upper electrode film was formed using iridium. Each of the first and the second upper electrode films had an average thickness substantially identical to those of Example 18.

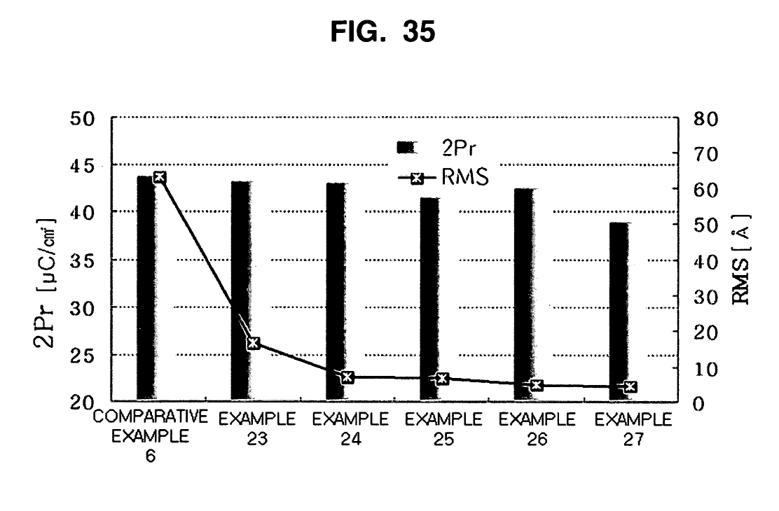

Table 2 shows average thicknesses, maximum thicknesses and RMS values of the thin ferroelectric layers and 2Pr values of the ferroelectric capacitors with respect to polishing times in accordance with Comparative Example 6 and Examples 23 to 27. FIG. 35 is a graph illustrating the 2Pr values and the RMS values of the thin ferroelectric layers relative to polishing times in accordance with Comparative Example 6 and Examples 23 to 27.

TABLE 2

| | Polishing | Average | | | |
|---|---|---|---|---|---|
| | time | thickness | Maximum | 2Pr | RMS |
| | [sec] | [Å] | thickness [Å] | [μC/cm²] | [Å] |
| Comparative | 0 | 982 | 1,012 | 43.66 | 63.44 |
| Example 6 | | | | | |
| Example 23 | 15 | 920 | 955 | 43.02 | 16.78 |
| Example 24 | 30 | 896 | 876 | 42.94 | 7.179 |
| Example 25 | 45 | 829 | 842 | 41.26 | 6.994 |
| Example 27 | 60 | 792 | 800 | 42.30 | 5.059 |
| Example 27 | 90 | 685 | 6716 | 38.78 | 4.380 |

As shown in Table 2 and FIG. 35, under process conditions including the downward pressure of about 1.0 psi and the rotation speed of about 10 rpm, the preliminary ferroelectric layers of Examples 23 to 27 were more slowly polished than the preliminary ferroelectric layers of Examples 18 to 22. However, the 2Pr values of the ferroelectric capacitors of Examples 23 to 27 were slightly reduced as the polishing time was increased. When the preliminary ferroelectric layers of Examples 23 to 27 were polished under the downward pressure of about 1.0 psi, the thin ferroelectric layers of Examples 23 to 27 had relatively high 2Pr values as well as improved surface uniformity.

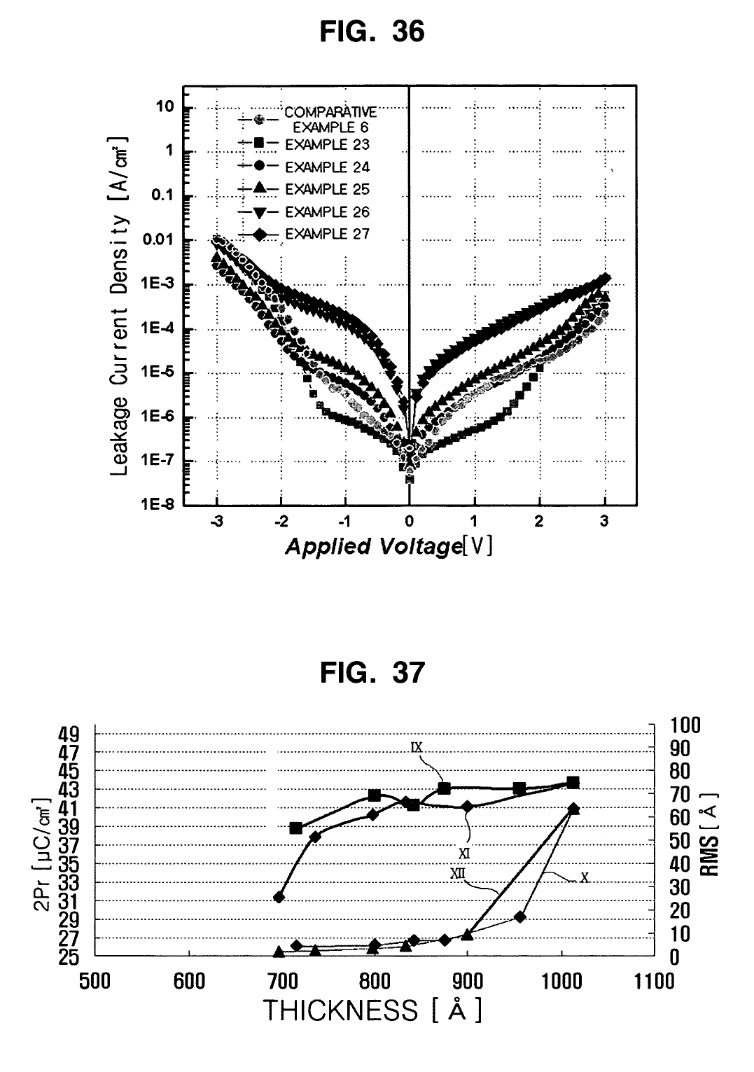

FIG. 36 is a graph illustrating leakage current densities of the ferroelectric capacitors relative to applied voltages in accordance with Comparative Example 6 and Examples 23 to 27.

Referring to FIG. 36, when the ferroelectric capacitors of Examples 23 to 25 were manufactured through the polishing process performed with the downward pressure of about 1.0 psi for below about 45 seconds, the ferroelectric capacitors of Examples 23 to 25 had leakage current densities lower than that of the ferroelectric capacitor of Comparative Example 6. However, the ferroelectric capacitors of Examples 26 and 27 had leakage current densities higher than that of the ferroelectric capacitor of Comparative Example 6 when the polishing time exceeded about 45 seconds.

FIG. 37 is a graph illustrating RMS values and thicknesses of thin ferroelectric layers and 2Pr values of ferroelectric capacitors in accordance with example embodiments of the present invention. In FIG. 37, “IX” and “X” indicate 2Pr values of ferroelectric capacitors and RMS values of thin ferroelectric layers polished under a downward pressure of about 1.0 psi, respectively. In addition, “XI” and “XII” represent 2Pr values of ferroelectric capacitors and RMS values of thin ferroelectric layers polished under a downward pressure of about 2.5 psi, respectively.

Referring to FIG. 37, since a polishing rate of the thin ferroelectric layers is increased as the downward pressure is augmented, the thin ferroelectric layer may have a more uniform surface. However, when the downward pressure is increased, much stress may be generated at the surface of the thin ferroelectric layer so that the ferroelectric capacitor including the thin ferroelectric layer may have poor ferroelectric and electrical characteristics. Therefore, the thin ferroelectric layer is advantageously formed by applying the downward pressure of about 1.0 psi to thereby improve a roughness of the surface of the thin ferroelectric layer and simultaneously enhance the ferroelectric and electrical characteristics of the ferroelectric capacitor.

Measurements of Characteristics of Ferroelectric Capacitors Relative to Slurries Used in Polishing Processes

### EXAMPLE 28

A lower electrode layer including a first lower electrode film and a second lower electrode film was formed on a substrate. The first and the second lower electrode films were formed using titanium aluminum nitride and iridium, respectively. The first and the second lower electrode films had average thicknesses of about 300 Å and about 1,200 Å, respectively.

A preliminary ferroelectric layer was formed on the lower electrode layer. The preliminary ferroelectric layer was formed using PZT by an MOCVD process. The preliminary ferroelectric layer had an equivalent oxide thickness (Tox) of about 158 nm.

The preliminary ferroelectric layer was polished by a CMP process for about 30 seconds to thereby form a thin ferroelectric layer on the lower electrode layer. The preliminary ferroelectric layer was polished using a slurry that included an abrasive containing acidic silica. The acidic silica had a pH of about 2.2. In the CMP process, a downward pressure was substantially identical to the above-described relatively high pressure, and a rotation speed of a polishing pad was also substantially identical to the above-described relatively high speed. The thin ferroelectric layer had an equivalent oxide thickness of about 133 nm.

After the thin ferroelectric layer was cleaned for about 60 seconds using a cleaning solution that included an SC1 solution, the thin ferroelectric layer was thermally treated at a temperature of about 550° C. for about 60 seconds.

An upper electrode layer was formed on the thin ferroelectric layer. The upper electrode layer had a first upper electrode film and a second upper electrode film. The first upper electrode film was formed using iridium oxide to have an average thickness of about 300 Å, and the second upper electrode film was formed using iridium to have an average thickness of about 400 Å. The thin ferroelectric layer and the upper electrode layer were thermally treated at a temperature of about 550° C. for about 60 seconds.

### EXAMPLE 29

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 28.

A preliminary ferroelectric layer was formed on the lower electrode layer. The preliminary ferroelectric layer was formed using PZT by an MOCVD process. The preliminary ferroelectric layer had an equivalent oxide thickness of about 150 nm and a P-V value of about 35.8 Å.

The preliminary ferroelectric layer was polished by a CMP process for about 30 seconds to thereby form a thin ferroelectric layer on the lower electrode layer. The preliminary ferroelectric layer was polished using a slurry that included an abrasive containing acidic silica. The acidic silica had a pH of about 2.1. In the CMP process, a downward pressure was substantially identical to the above-described relatively high pressure, and a rotation speed of a polishing pad was also substantially identical to the above-described relatively high speed. The thin ferroelectric layer had an equivalent oxide thickness of about 114 nm and a P-V value of about 2.04 Å. The thin ferroelectric layer was thermally treated at a temperature of about 550° C. for about 60 seconds.

An upper electrode layer was formed on the thin ferroelectric layer. The upper electrode layer had a first upper electrode film and a second upper electrode film. The first upper electrode film was formed using iridium oxide, and the second upper electrode film was formed using iridium. The first and the second upper electrode films had average thicknesses substantially identical to those of the first and the second upper electrode films in Example 28. The thin ferroelectric layer and the upper electrode layer were thermally treated at a temperature of about 550° C. for about 60 seconds. A ferroelectric capacitor had a 2Pr value of about 23.475 μC/cm².

### EXAMPLE 30

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 28.

A preliminary ferroelectric layer was formed on the lower electrode layer. The preliminary ferroelectric layer was formed using PZT by an MOCVD process. The preliminary ferroelectric layer had an equivalent oxide thickness of about 158 nm.

The preliminary ferroelectric layer was polished by a CMP process for about 30 seconds to thereby form a thin ferroelectric layer on the lower electrode layer. The preliminary ferroelectric layer was polished using a slurry that included an abrasive containing acidic silica. The acidic silica had a pH of about 2.5. In the CMP process, a downward pressure was substantially identical to the above-described relatively low pressure, and a rotation speed of a polishing pad was also substantially identical to the above-described relatively low speed. The thin ferroelectric layer had an equivalent oxide thickness of about 148 nm.

After the thin ferroelectric layer was cleaned for about 60 seconds using a cleaning solution that included an SC1 solution, the thin ferroelectric layer was thermally treated at a temperature of about 550° C. for about 60 seconds.

An upper electrode layer was formed on the thin ferroelectric layer. The upper electrode layer had a first upper electrode film and a second upper electrode film. The first upper electrode film was formed using iridium oxide, and the second upper electrode film was formed using iridium. The first and the second upper electrode films had average thicknesses substantially identical to those of the first and the second upper electrode films in Example 28. The thin ferroelectric layer and the upper electrode layer were thermally treated at a temperature of about 550° C. for about 60 seconds.

### EXAMPLE 31

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 28.

A preliminary ferroelectric layer was formed on the lower electrode layer. The preliminary ferroelectric layer was formed using PZT by an MOCVD process. The preliminary ferroelectric layer had an equivalent oxide thickness of about 157 nm and a P-V value of about 32.3 Å.

The preliminary ferroelectric layer was polished by a CMP process for about 30 seconds to thereby form a thin ferroelectric layer on the lower electrode layer. The preliminary ferroelectric layer was polished using a slurry that included an abrasive containing acidic silica. The acidic silica had a pH of about 2.5. In the CMP process, a downward pressure was substantially identical to the above-described relatively low pressure, and a rotation speed of a polishing pad was also substantially identical to the above-described relatively low speed. The thin ferroelectric layer had an equivalent oxide thickness of about 144 nm and a P-V value of about 6.13 Å. The thin ferroelectric layer was thermally treated at a temperature of about 550° C. for about 60 seconds.

An upper electrode layer was formed on the thin ferroelectric layer. The upper electrode layer had a first upper electrode film and a second upper electrode film. The first upper electrode film was formed using iridium oxide, and the second upper electrode film was formed using iridium. The first and the second upper electrode films had average thicknesses substantially identical to those of the first and the second upper electrode films in Example 28. The thin ferroelectric layer and the upper electrode layer were thermally treated at a temperature of about 550° C. for about 60 seconds. A ferroelectric capacitor had a 2Pr value of about 29.744 μC/cm².

### EXAMPLE 32

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 28.

A preliminary ferroelectric layer was formed on the lower electrode layer. The preliminary ferroelectric layer was formed using PZT by an MOCVD process. The preliminary ferroelectric layer had an equivalent oxide thickness of about 152 nm and a P-V value of about 32.9 Å.

The preliminary ferroelectric layer was polished by a CMP process for about 30 seconds to thereby form a thin ferroelectric layer on the lower electrode layer. The preliminary ferroelectric layer was polished using a slurry that included an abrasive containing basic silica. The basic silica had a pH of about 10.9. In the CMP process, a downward pressure was substantially identical to the above-described relatively low pressure, and a rotation speed of a polishing pad was also substantially identical to the above-described relatively low speed. The thin ferroelectric layer had an equivalent oxide thickness of about 144 nm and a P-V value of about 12.05 Å. The thin ferroelectric layer was thermally treated at a temperature of about 550° C. for about 60 seconds.

An upper electrode layer was formed on the thin ferroelectric layer. The upper electrode layer had a first upper electrode film and a second upper electrode film. The first upper electrode film was formed using iridium oxide, and the second upper electrode film was formed using iridium. The first and the second upper electrode films had average thicknesses substantially identical to those of the first and the second upper electrode films in Example 28. The thin ferroelectric layer and the upper electrode layer were thermally treated at a temperature of about 550° C. for about 60 seconds. A ferroelectric capacitor had a 2Pr value of about 30.543 μC/cm².

### EXAMPLE 33

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 28.

A preliminary ferroelectric layer was formed on the lower electrode layer. The preliminary ferroelectric layer was formed using PZT by an MOCVD process. The preliminary ferroelectric layer had an equivalent oxide thickness of about 156 nm and a P-V value of about 32.5 Å.

The preliminary ferroelectric layer was polished by a CMP process for about 60 seconds to thereby form a thin ferroelectric layer on the lower electrode layer. The preliminary ferroelectric layer was polished using a slurry that included an abrasive containing basic silica. The basic silica had a pH of about 11.2. In the CMP process, a downward pressure was substantially identical to the above-described relatively low pressure, and a rotation speed of a polishing pad was also substantially identical to the above-described relatively low speed. The thin ferroelectric layer had an equivalent oxide thickness of about 144 nm and a P-V value of about 4.44 Å. The thin ferroelectric layer was thermally treated at a temperature of about 550° C. for about 60 seconds.

An upper electrode layer was formed on the thin ferroelectric layer. The upper electrode layer had a first upper electrode film and a second upper electrode film. The first upper electrode film was formed using iridium oxide, and the second upper electrode film was formed using iridium. The first and the second upper electrode films had average thicknesses substantially identical to those of the first and the second upper electrode films in Example 28. The thin ferroelectric layer and the upper electrode layer were thermally treated at a temperature of about 550° C. for about 60 seconds. A ferroelectric capacitor had a 2Pr value of about 27.377° C./cm².

### EXAMPLE 34

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 28.

A preliminary ferroelectric layer was formed on the lower electrode layer. The preliminary ferroelectric layer was formed using PZT by an MOCVD process. The preliminary ferroelectric layer had an equivalent oxide thickness of about 153 nm and a P-V value of about 32.1 Å.

The preliminary ferroelectric layer was polished by a CMP process for about 30 seconds to thereby form a thin ferroelectric layer on the lower electrode layer. The preliminary ferroelectric layer was polished using a slurry that included an abrasive containing ceria. The ceria had a pH of about 7.7. In the CMP process, a downward pressure was substantially identical to the above-described relatively low pressure, and a rotation speed of a polishing pad was also substantially identical to the above-described relatively low speed. The thin ferroelectric layer had an equivalent oxide thickness of about 147 nm and a P-V value of about 9.56 Å. The thin ferroelectric layer was thermally treated at a temperature of about 550° C. for about 60 seconds.

An upper electrode layer was formed on the thin ferroelectric layer. The upper electrode layer had a first upper electrode film and a second upper electrode film. The first upper electrode film was formed using iridium oxide, and the second upper electrode film was formed using iridium. The first and the second upper electrode films had average thicknesses substantially identical to those of the first and the second upper electrode films in Example 28. The thin ferroelectric layer and the upper electrode layer were thermally treated at a temperature of about 550° C. for about 60 seconds. A ferroelectric capacitor had a 2Pr value of about 31.183 μC/cm².

### EXAMPLE 35

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 28.

A preliminary ferroelectric layer was formed on the lower electrode layer. The preliminary ferroelectric layer was formed using PZT by an MOCVD process. The preliminary ferroelectric layer had an equivalent oxide thickness of about 156 nm and a P-V value of about 32.2 Å.

The preliminary ferroelectric layer was polished by a CMP process for about 30 seconds to thereby form a thin ferroelectric layer on the lower electrode layer. The preliminary ferroelectric layer was polished using a slurry that included an abrasive containing ceria. The ceria had a pH of about 7.5. In the CMP process, a downward pressure was substantially identical to the above-described relatively low pressure, and a rotation speed of a polishing pad was also substantially identical to the above-described relatively low speed. The thin ferroelectric layer had an equivalent oxide thickness of about 146 nm and a P-V value of about 4.05 Å. The thin ferroelectric layer was thermally treated at a temperature of about 550° C. for about 60 seconds.

An upper electrode layer was formed on the thin ferroelectric layer. The upper electrode layer had a first upper electrode film and a second upper electrode film. The first upper electrode film was formed using iridium oxide, and the second upper electrode film was formed using iridium. The first and the second upper electrode films had average thicknesses substantially identical to those of the first and the second upper electrode films in Example 28. The thin ferroelectric layer and the upper electrode layer were thermally treated at a temperature of about 550° C. for about 60 seconds. A ferroelectric capacitor had a 2Pr value of about 27.473 μC/cm².

### COMPARATIVE EXAMPLE 7

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 28.

A thin ferroelectric layer was formed on the lower electrode layer without a CMP process. The thin ferroelectric layer was thermally treated at a temperature of about 550° C. for about 60 seconds without a cleaning process.

An upper electrode layer was formed on the thin ferroelectric layer. The upper electrode layer had a first upper electrode film and a second upper electrode film. The first upper electrode film was formed using iridium oxide, and the second upper electrode film was formed using iridium. The first and the second upper electrode films had average thicknesses substantially identical to those of the first and the second upper electrode films in Example 28. The thin ferroelectric layer and the upper electrode layer were thermally treated at a temperature of about 550° C. for about 60 seconds. A ferroelectric capacitor had a 2Pr value of about 37.036 μC/cm².

FIG. 38 is a graph illustrating polishing rates at different portions of the preliminary ferroelectric layers in accordance with Examples 30 to 35. In FIG. 38, “T” indicates polishing rates at the highest surface portions of the preliminary ferroelectric layers, and “C” represents polishing rates at central surface portions of the preliminary ferroelectric layers. “B” means polishing rates at the lowest surface portions of the preliminary ferroelectric layers, and “L” indicates polishing rates at left surface portions of the preliminary ferroelectric layers. “R” means polishing rates at right surface portions of the preliminary ferroelectric layers, and “Avg” represents average polishing rates at entire surface portions of the preliminary ferroelectric layers.

Referring to FIG. 38, the entire surface portions of the preliminary ferroelectric layers of Examples 32 to 35 were uniformly polished; however, the polishing rates of the preliminary ferroelectric layers of Examples 30 and 31 were relatively irregular according to the surface portions thereof.

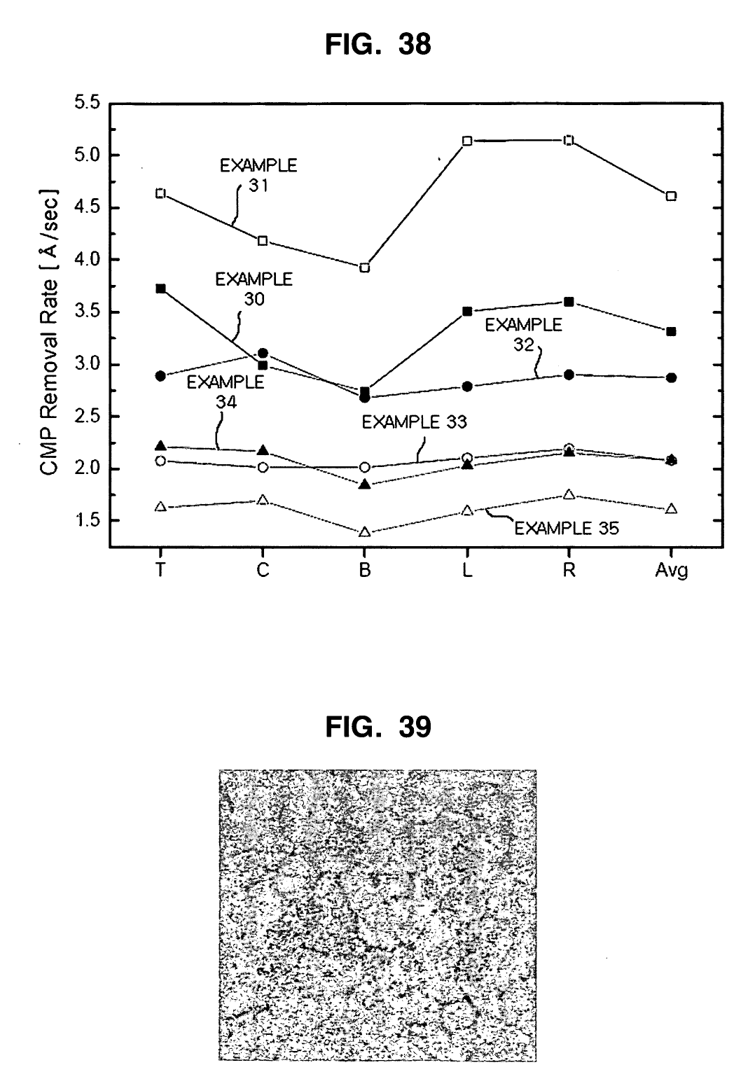

FIG. 39 is a picture showing the surface of the thin ferroelectric layer obtained using an SEM in accordance with Comparative Example 7.

As shown in FIG. 39, the surface of the thin ferroelectric layer of Comparative Example 7 was irregular because the polishing process and the cleaning process were not executed.

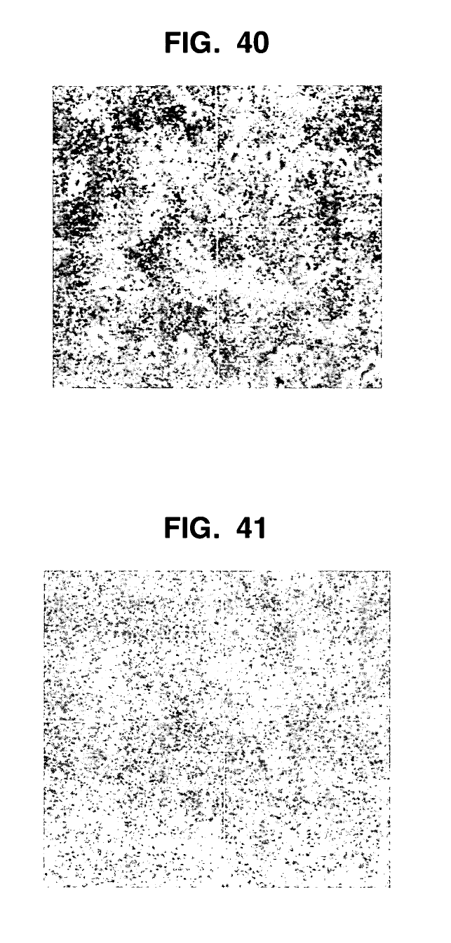

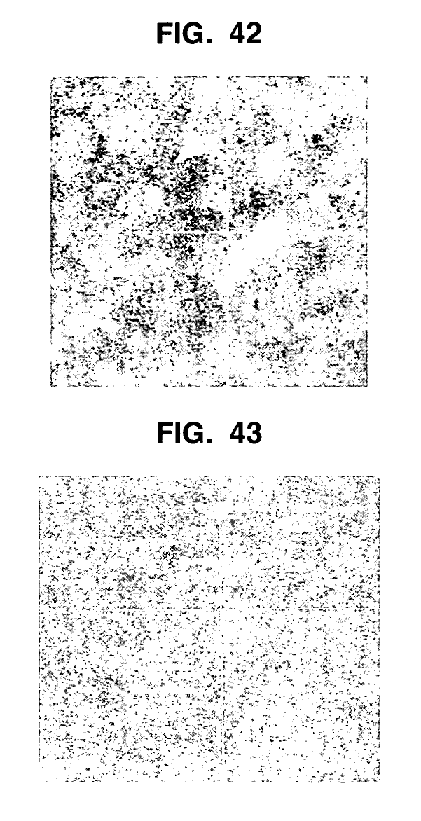

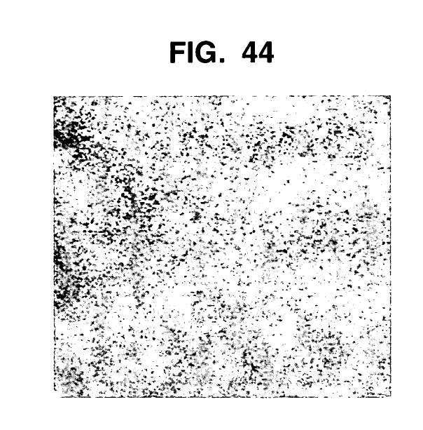

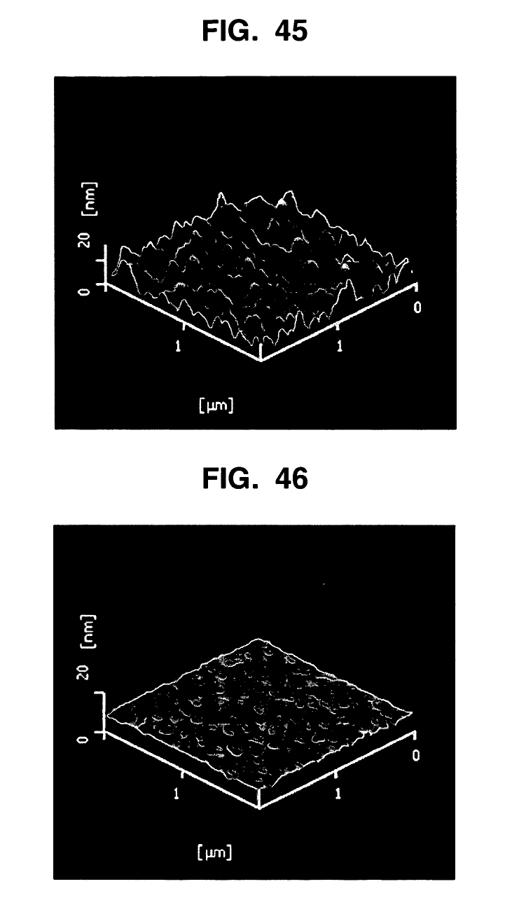

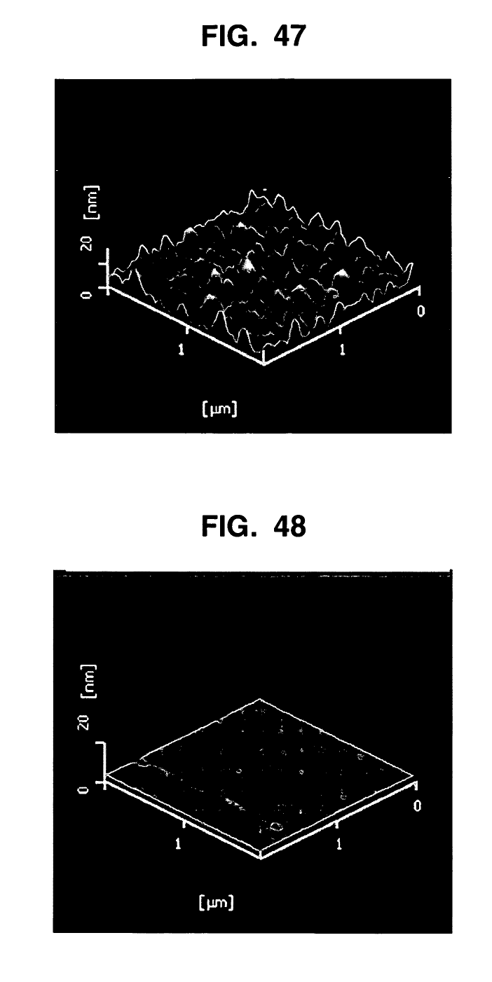

FIG. 40 is a picture showing the surface of the thin ferroelectric layer obtained using an SEM in accordance with Example 32, and FIG. 41 is a picture showing the surface of the thin ferroelectric layer obtained using an SEM in accordance with Example 33. FIG. 42 is a picture showing the surface of the thin ferroelectric layer obtained using an SEM in accordance with Example 34, and FIG. 43 is a picture showing the surface of the thin ferroelectric layer obtained using an SEM in accordance with Example 35. FIG. 44 is a picture showing the surface of the thin ferroelectric layer obtained using an SEM in accordance with Example 28. FIG. 45 is a picture showing the surface of the preliminary ferroelectric layer obtained using an AFM in accordance with Example 32, and FIG. 46 is a picture showing the surface of the thin ferroelectric layer obtained using an AFM in accordance with Example 32. FIG. 47 is a picture showing the surface of the preliminary ferroelectric layer obtained using an AFM in accordance with Example 33, and FIG. 48 is a picture showing the surface of the thin ferroelectric layer obtained using an AFM in accordance with Example 33.

As shown in FIGS. 45 and 47, the preliminary ferroelectric layers had very irregular surfaces before performing the polishing process.

Referring to FIGS. 40, 44 and 46, when the preliminary ferroelectric layers were polished using the slurries including the basic silica for about 30 seconds, the thin ferroelectric layers had uniform surfaces on which recesses or grooves were partially formed. As shown in FIGS. 41 and 48, the thin ferroelectric layers had very uniform surfaces from which recesses or grooves were removed when the preliminary ferroelectric layers were polished using the slurries including the basic silica for about 60 seconds.

Referring to FIG. 42, when the preliminary ferroelectric layer was polished using the slurry including the ceria for about 30 seconds, the thin ferroelectric layer had a relatively irregular surface. However, the thin ferroelectric layer had a relatively uniform surface when the preliminary ferroelectric layer was polished using the slurry including the ceria for about 60 seconds as shown in FIG. 43.

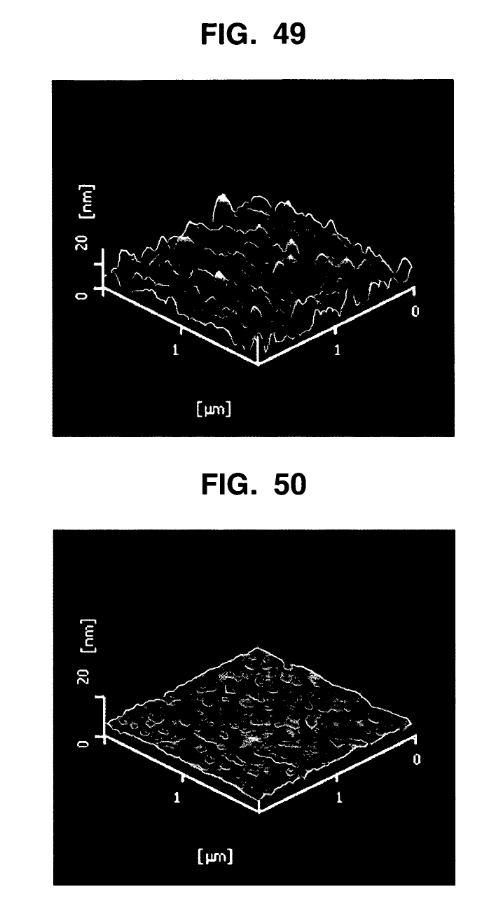

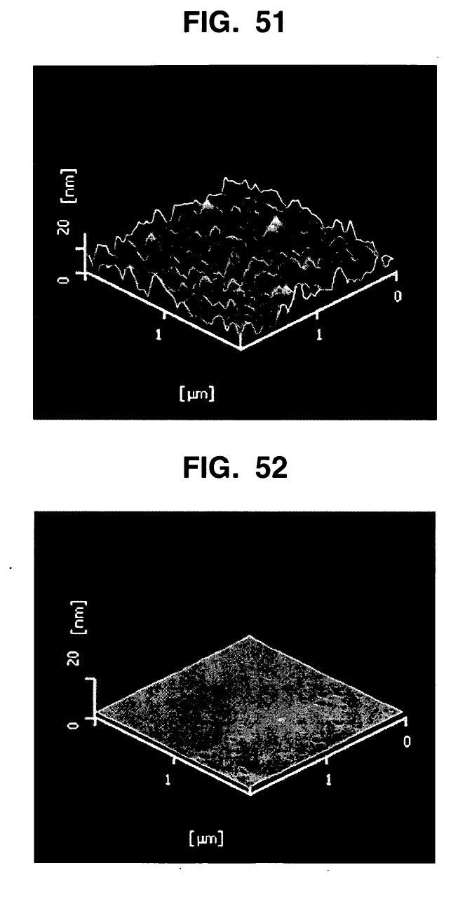

FIG. 49 is a picture showing the surface of the preliminary ferroelectric layer obtained using an AFM in accordance with Example 34, and FIG. 50 is a picture showing the surface of the thin ferroelectric layer obtained using an AFM in accordance with Example 34. FIG. 51 is a picture showing the surface of the preliminary ferroelectric layer obtained using an AFM in accordance with Example 35, and FIG. 52 is a picture showing the surface of the thin ferroelectric layer obtained using an AFM in accordance with Example 35.

Referring to FIGS. 49 and 51, the preliminary ferroelectric layers had very irregular surfaces when the polishing process was not executed on the preliminary ferroelectric layers. However, the thin ferroelectric layers had relatively uniform surfaces from which recesses or grooves were removed when the preliminary ferroelectric layers were polished using the slurries including the ceria for about 30 seconds as shown in FIGS. 42 and 50. Additionally, as shown in FIGS. 43 and 52, when the preliminary ferroelectric layers were polished using the slurries including the ceria for about 60 seconds, the thin ferroelectric layers had relatively uniform surfaces from which the recesses or the grooves were removed.

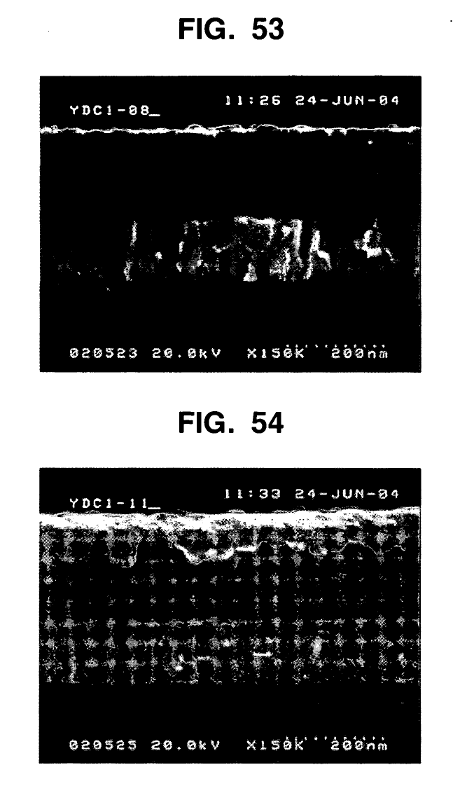

FIGS. 53 to 59 are pictures showing cross sections of the ferroelectric capacitors in accordance with Examples 29 and 31 to 35, and Comparative Example 7.

Referring to FIG. 53, when the preliminary ferroelectric layer was polished for about 30 seconds using the slurry that included the acidic silica having the pH of about 2.1, the obtained thin ferroelectric layer had a uniform surface.

As shown in FIG. 54, when the preliminary ferroelectric layer was polished for about 30 seconds using the slurry that included the acidic silica having the pH of about 2.5, the obtained thin ferroelectric layer had a relatively irregular surface.

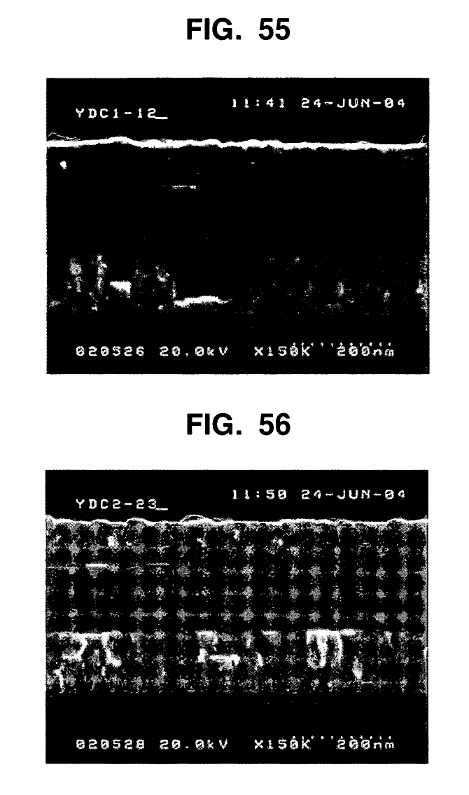

Referring to FIG. 55, when the preliminary ferroelectric layer was polished for about 30 seconds using the slurry that included the basic silica having the pH of about 10.9, the obtained thin ferroelectric layer had a relatively uniform surface.

Referring to FIG. 56, when the preliminary ferroelectric layer was polished for about 60 seconds using the slurry that included the basic silica having the pH of about 11.2, the obtained thin ferroelectric layer had a uniform surface.

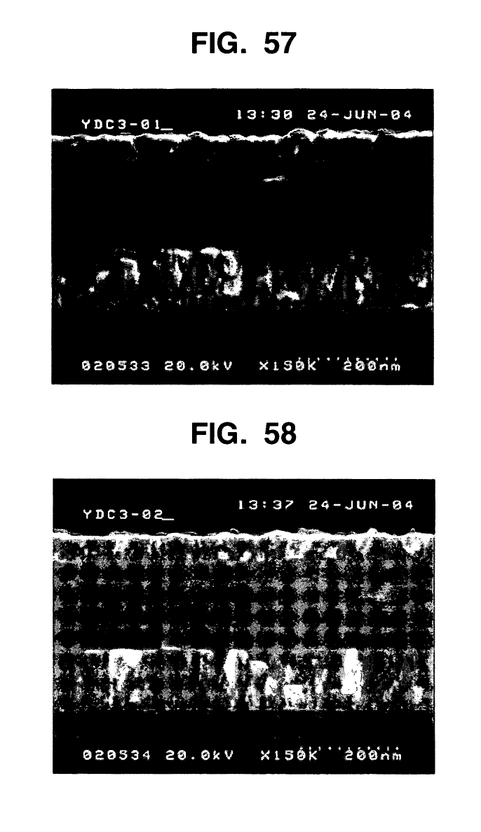

As shown in FIG. 57, when the preliminary ferroelectric layer was polished for about 30 seconds using the slurry that included the ceria, the obtained thin ferroelectric layer had a relatively irregular surface.

Referring to FIG. 58, when the preliminary ferroelectric layer was polished for about 60 seconds using the slurry that included the ceria, the obtained thin ferroelectric layer had a relatively uniform surface.

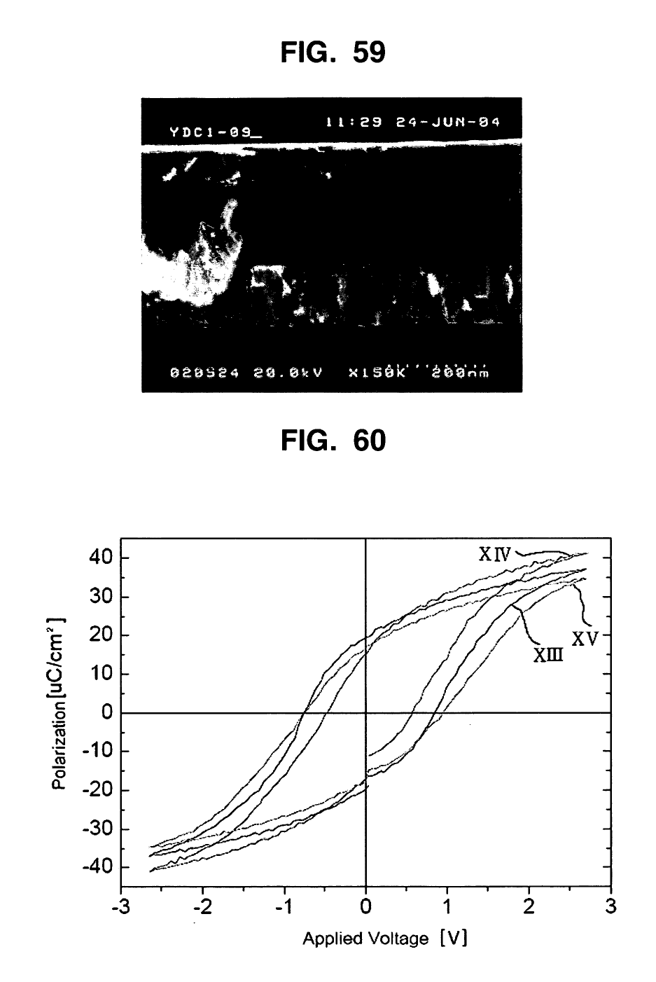

However, as shown in FIG. 59, the thin ferroelectric layer had a very irregular surface when the polishing process was not performed.

FIG. 60 is a graph illustrating P-V hysteresis loops of the ferroelectric capacitors in accordance with Comparative Example 7 and Examples 29 and 31. In FIG. 60, the P-V hysteresis loops were obtained by measuring the polarizations of the ferroelectric capacitors relative to applied voltages. Additionally, in FIG. 60, “XIII” indicates the P-V hysteresis loop of the ferroelectric capacitor of Comparative Example 7, “XIV” represents the P-V hysteresis loop of the ferroelectric capacitor of Example 29, and “XV” indicates the P-V hysteresis loop of the ferroelectric capacitor of Example 31.

Referring to FIG. 60, when +V_{C} was about 0.85 V and −V_{C} was about −0.73 V, the ferroelectric capacitor of Comparative Example 7 had a 2Pr value of about 37.036 μC/cm². The ferroelectric capacitor of Example 29 had a 2Pr value of about 23.475 μC/cm² when +V_{C} was about 0.57 V and −V_{C} was about −0.48 V. Additionally, the ferroelectric capacitor of Example 31 had a 2Pr value of about 29.744 μC/cm² when +V_{C} was about 0.95 V and −V_{C} was about −0.75 V. As shown in FIG. 60, when the thin ferroelectric layers were obtained though the polishing process using the slurry that including the acidic silica, the surfaces of the thin ferroelectric layers had improved roughness, and the ferroelectric capacitors had the relatively reduced 2Pr values.

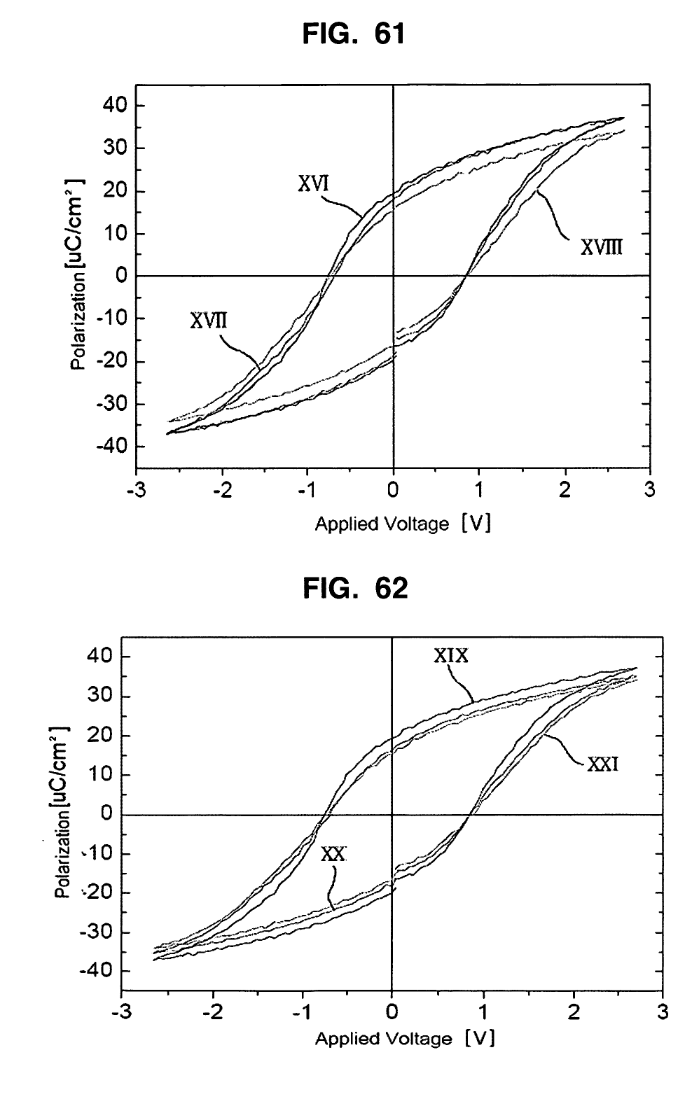

FIG. 61 is a graph illustrating P-V hysteresis loops of the ferroelectric capacitors in accordance with Comparative Example 7 and Examples 32 and 33. In FIG. 61, the P-V hysteresis loops were obtained by measuring the polarizations of the ferroelectric capacitors relative to applied voltages. In FIG. 61, “XVI” indicates the P-V hysteresis loop of the ferroelectric capacitor of Comparative Example 7, “XVII” represents the P-V hysteresis loop of the ferroelectric capacitor of Example 32, and “XVIII” indicates the P-V hysteresis loop of the ferroelectric capacitor of Example 33.

Referring to FIG. 61, when +V_{C} was about 0.85 V and −V_{C} was about −0.73 V, the ferroelectric capacitor of Comparative Example 7 had a 2Pr value of about 37.036 μC/cm². The ferroelectric capacitor of Example 32 had a 2Pr value of about 30.543 μC/cm² when +V_{C} was about 0.84 V and −V_{C} was about −0.69 V. Additionally, the ferroelectric capacitor of Example 33 had a 2Pr value of about 27.377 μC/cm² when +V_{C} was about 0.86 V and −V_{C} was about −0.73 V. As shown in FIG. 61, when the thin ferroelectric layers were obtained though the polishing process using the slurry that including the basic silica, the surfaces of the thin ferroelectric layers had improved roughness, and also the ferroelectric capacitors had the slightly reduced 2Pr values. However, the ferroelectric capacitor of Example 33 had a more reduced 2Pr value as the polishing time increased.

FIG. 62 is a graph illustrating P-V hysteresis loops of the ferroelectric capacitors in accordance with Comparative Example 7 and Examples 34 and 35. In FIG. 62, the P-V hysteresis loops were obtained by measuring the polarizations of the ferroelectric capacitors relative to applied voltages. In FIG. 62, “XIX” indicates the P-V hysteresis loop of the ferroelectric capacitor of Comparative Example 7, “XX” represents the P-V hysteresis loop of the ferroelectric capacitor of Example 34, and “XXI” indicates the P-V hysteresis loop of the ferroelectric capacitor of Example 35.

Referring to FIG. 62, when +V_{C} was about 0.85 V and −V_{C} was about −0.73 V, the ferroelectric capacitor of Comparative Example 7 had a 2Pr value of about 37.036 μC/cm². The ferroelectric capacitor of Example 34 had a 2Pr value of about 31.951 μC/cm² when +V_{C} was about 0.85 V and −V_{C} was about −0.69 V. Additionally, the ferroelectric capacitor of Example 35 had a 2Pr value of about 31.951 μC/cm² when +V_{C} was about 0.88 V and −V_{C} was about −0.73 V. As shown in FIG. 62, when the thin ferroelectric layers were obtained though the polishing process using the slurry that including the ceria, the surfaces of the thin ferroelectric layers had improved roughness, and the ferroelectric capacitors had the slightly reduced 2Pr values. The ferroelectric capacitors had gradually reduced 2Pr values as the polishing time increased.

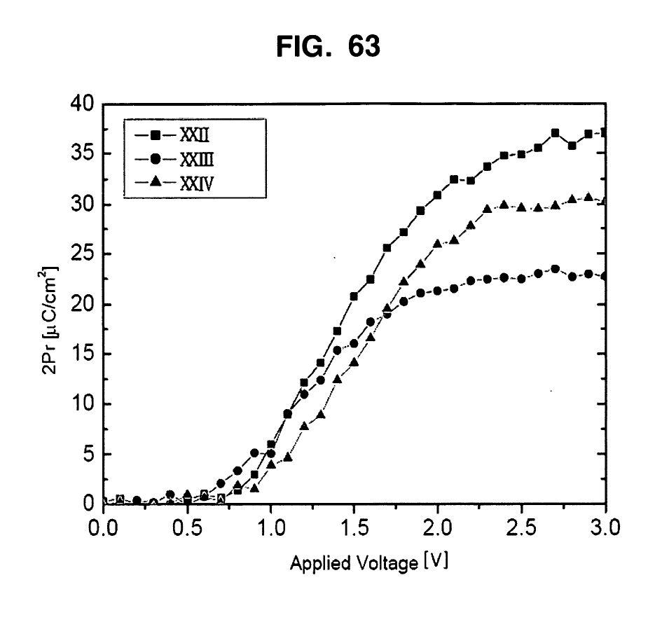

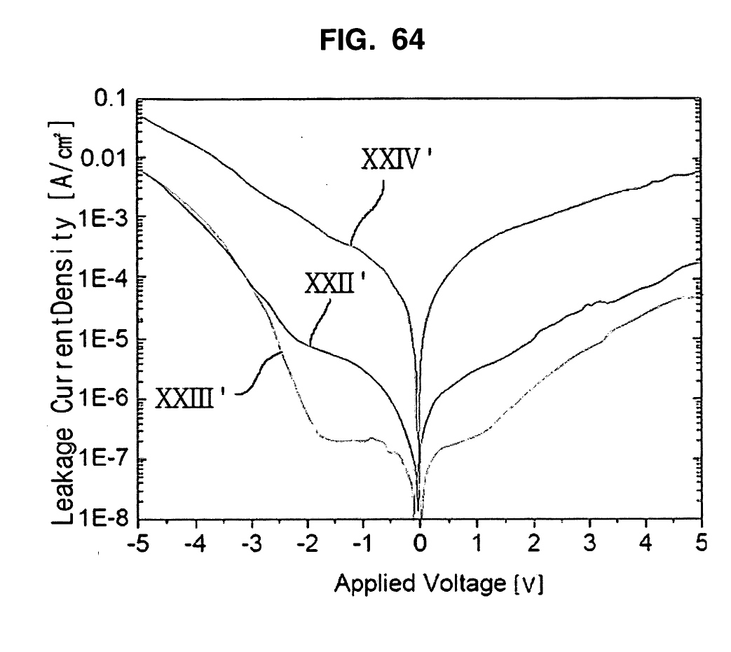

FIG. 63 is a graph illustrating 2Pr values of the ferroelectric capacitors in accordance with Comparative Example 7 and Examples 29 and 31, and FIG. 64 is a graph illustrating leakage current densities of the ferroelectric capacitors in accordance with Comparative Example 7 and Examples 29 and 31. The 2Pr values were measured with respect to applied voltages in FIG. 63, and the leakage current densities of the ferroelectric capacitors were also measured relative to applied voltages in FIG. 64. In FIGS. 63 and 64, “XXII” and “XXII′” indicate the 2Pr value and the leakage current density of the ferroelectric capacitor of Comparative Example 7, “XXIII” and “XXIII ′” represent the 2Pr value and the leakage current density of the ferroelectric capacitor of Example 29, and “XXIV” and “XXIV′” indicate the 2Pr value and the leakage current density of the ferroelectric capacitor of Example 31.

Referring to FIG. 63, the ferroelectric capacitor manufactured without the polishing process had the 2Pr value relatively higher than those of the ferroelectric capacitors manufactured by performing the polishing process as the applied voltage increased. However, as shown in FIG. 64, when the ferroelectric capacitor had the thin ferroelectric layer obtained using the slurry that included the acidic silica having the pH of about 2.1, the ferroelectric capacitor had the leakage current density lower than that of the ferroelectric capacitor manufactured without the polishing process. On the other hand, when the ferroelectric capacitor had the thin ferroelectric layer obtained using the slurry that included the acidic silica having the pH of about 2.5, the ferroelectric capacitor had the leakage current density substantially higher than that of the ferroelectric capacitor manufactured without the polishing process.

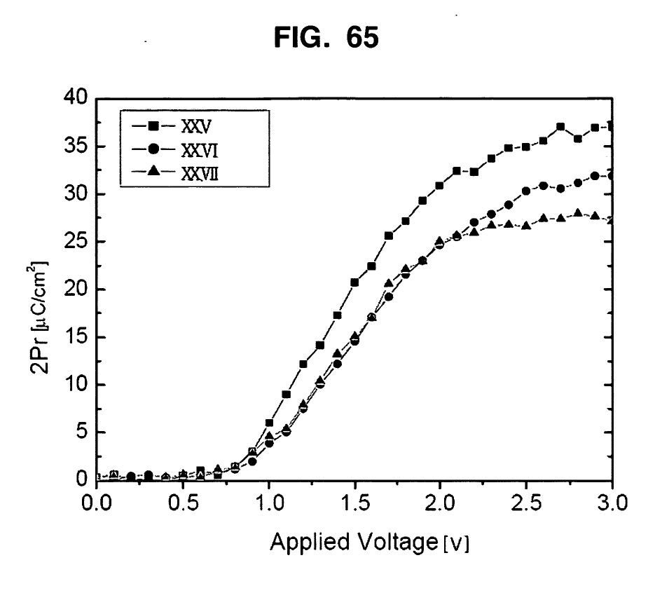

FIG. 65 is a graph illustrating 2Pr values of the ferroelectric capacitors in accordance with Comparative Example 7 and Examples 32 and 33, and FIG. 66 is a graph illustrating leakage current densities of the ferroelectric capacitors in accordance with Comparative Example 7 and Examples 32 and 33. The 2Pr values were measured with respect to applied voltages in FIG. 65, and the leakage current densities of the ferroelectric capacitors were also measured relative to applied voltages in FIG. 66. In FIGS. 65 and 66, “XXV” and “XXV′” indicate the 2Pr value and the leakage current density of the ferroelectric capacitor of Comparative Example 7, “XXVI” and “XXVI′” represent the 2Pr value and the leakage current density of the ferroelectric capacitor of Example 32, and “XXVII” and “XXVII′” indicate the 2Pr value and the leakage current density of the ferroelectric capacitor of Example 33.

Referring to FIG. 65, the ferroelectric capacitor manufactured without the polishing process had the 2Pr value relatively higher than those of the ferroelectric capacitors manufactured by performing the polishing process using the basic silica as the applied voltage increased. However, as shown in FIG. 66, when the ferroelectric capacitors had the thin ferroelectric layers obtained using the slurries that included the basic silica, the ferroelectric capacitors had the leakage current densities much lower than that of the ferroelectric capacitor manufactured without the polishing process.

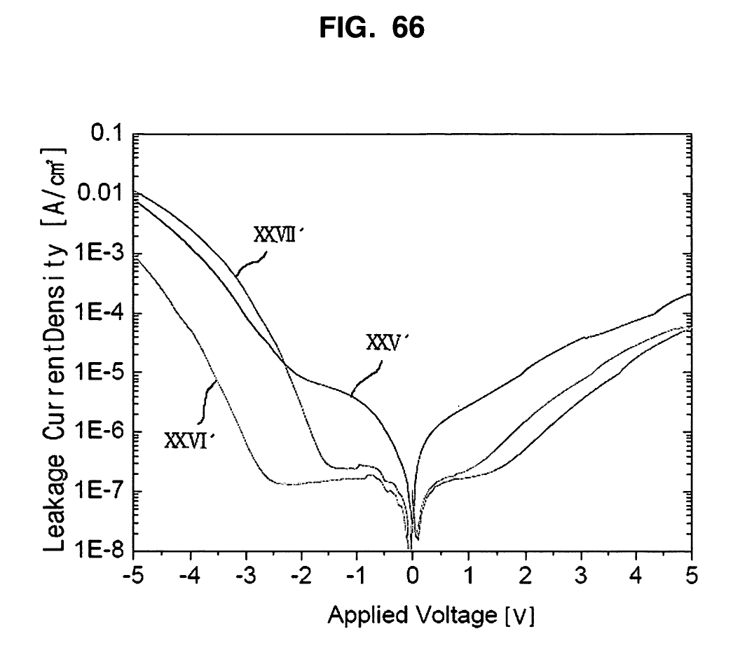

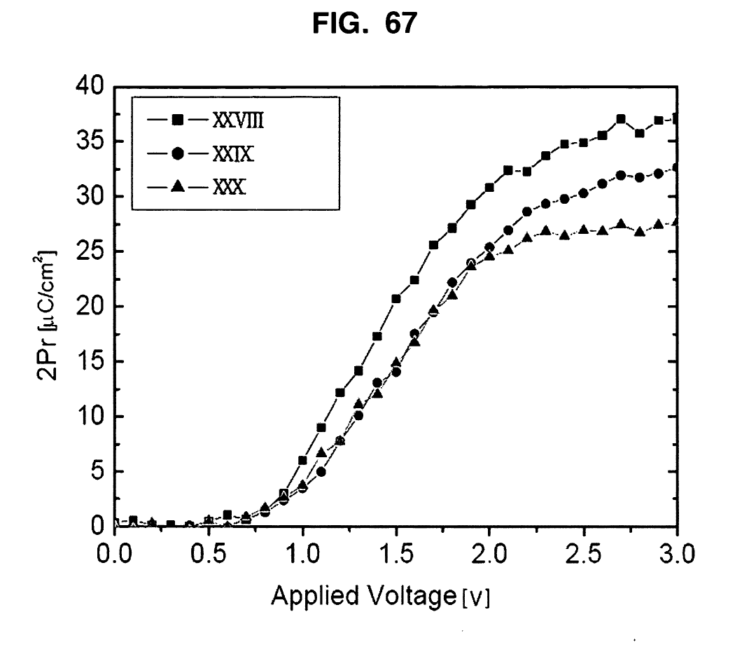

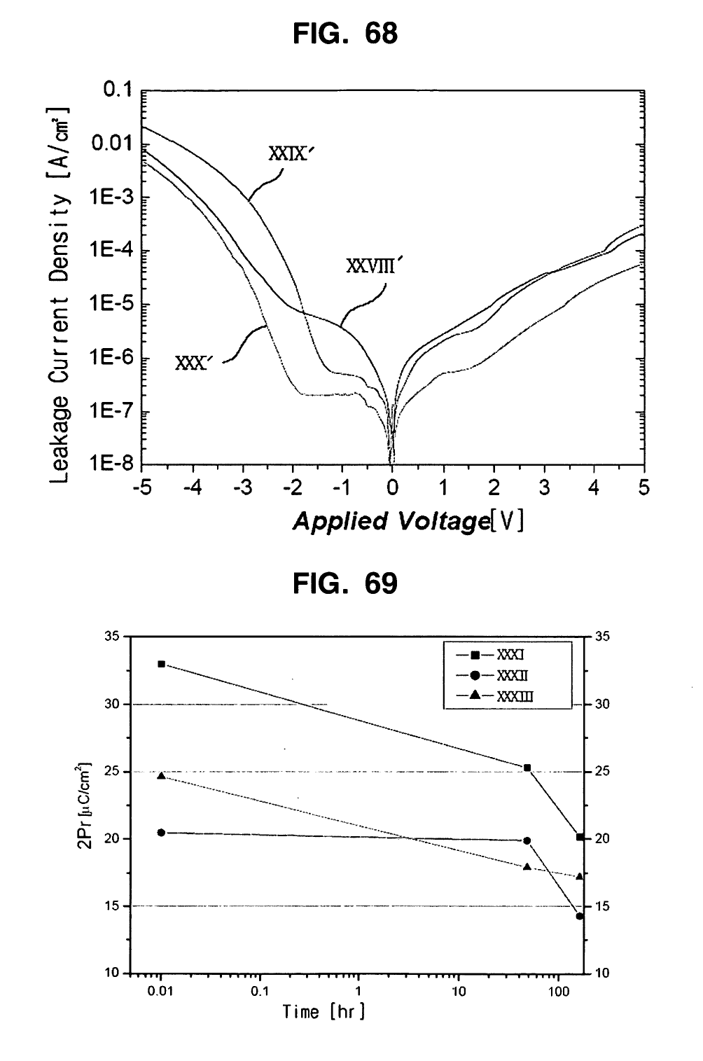

FIG. 67 is a graph illustrating 2Pr values of the ferroelectric capacitors in accordance with Comparative Example 7 and Examples 34 and 35, and FIG. 68 is a graph illustrating leakage current densities of the ferroelectric capacitors in accordance with Comparative Example 7 and Examples 34 and 35. The 2Pr values were measured with respect to applied voltages in FIG. 65, and the leakage current densities of the ferroelectric capacitors were also measured relative to applied voltages in FIG. 68. In FIGS. 67 and 68, “XXVIII” and “XXVIII′” indicate the 2Pr value and the leakage current density of the ferroelectric capacitor of Comparative Example 7, “XXIX” and “XXIX′” represent the 2Pr value and the leakage current density of the ferroelectric capacitor of Example 34, and “XXX” and “XXX′” indicate the 2Pr value and the leakage current density of the ferroelectric capacitor of Example 35.

Referring to FIG. 67, the ferroelectric capacitor manufactured without the polishing process had the 2Pr value relatively higher than those of the ferroelectric capacitors manufactured by performing the polishing process using the ceria as the applied voltage increased. However, as shown in FIG. 68, when the ferroelectric capacitor had the thin ferroelectric layer obtained using the slurry that included the ceria, the ferroelectric capacitors had the leakage current densities relatively lower than that of the ferroelectric capacitor manufactured without the polishing process.

FIG. 69 is a graph illustrating reduction rates of 2Pr values of the ferroelectric capacitors relative to time in accordance with Examples 29 and 31, and Comparative Example 7. In FIG. 69, “XXXI” indicates the reduction rate of the 2Pr value of the ferroelectric capacitor according to Comparative Example 7, “XXXII” means the reduction rate of the 2Pr value of the ferroelectric capacitor according to Example 29, and “XXXIII” represents the reduction rate of the 2Pr value of the ferroelectric capacitor according to Example 31.

Referring to FIG. 69, after about 100 hours at a temperature of about 150° C., the 2Pr value of the ferroelectric capacitor of Comparative Example 7 was reduced from about 32.9 μC/cm² to about 20.1 μC/cm² so that the ferroelectric capacitor of Comparative Example 7 had a high reduction rate of the 2Pr value of about 38.9%. However, the 2Pr value of the ferroelectric capacitor of Example 29 was reduced from about 24.9 μC/cm² to about 17.3 μC/cm² after about 100 hours at a temperature of about 150° C. Thus, the ferroelectric capacitor of Example 29 had a relatively low reduction rate of the 2Pr value of about 30.5%. Additionally, the 2Pr value of the ferroelectric capacitor of Example 31 was reduced from about 20.6 μC/cm² to about 14.7° C./cm² after about 100 hours at a temperature of about 150° C. Thus, the ferroelectric capacitor of Example 31 had a low reduction rate of the 2Pr value of about 28.6%. In particular, the 2Pr value of the ferroelectric capacitor of Example 31 was constantly maintained even though about 70 hours passed by.

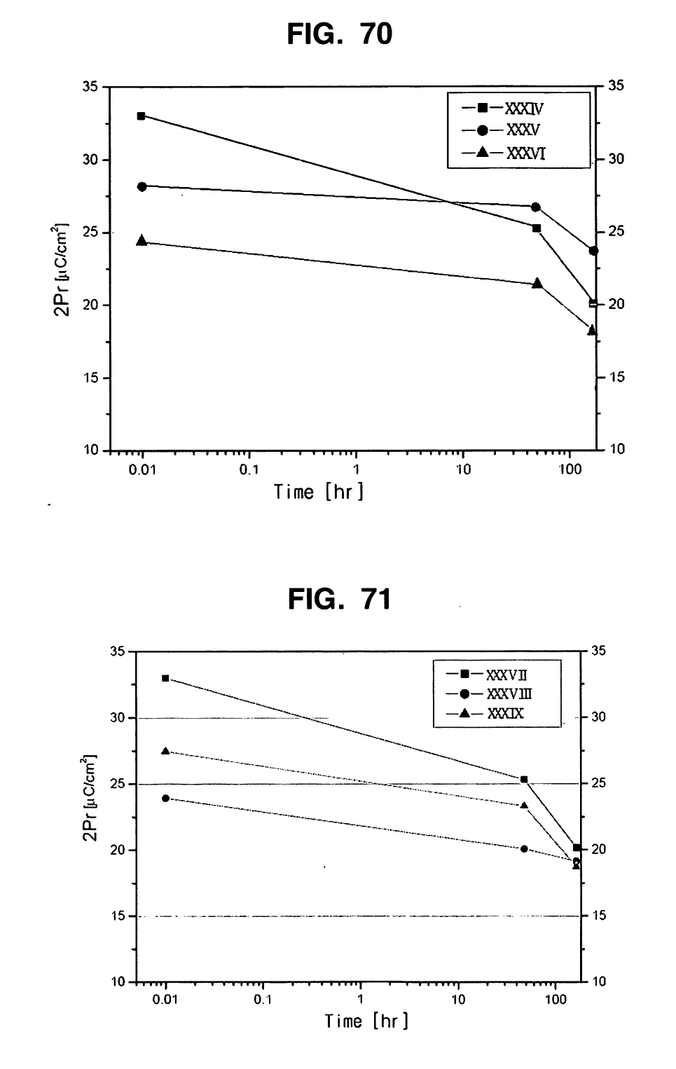

FIG. 70 is a graph illustrating reduction rates of 2Pr values of the ferroelectric capacitors relative to time in accordance with Examples 32 and 33, and Comparative Example 7. In FIG. 70, “XXXIV” indicates the reduction rate of the 2Pr value of the ferroelectric capacitor according to Comparative Example 7, “XXXV” means the reduction rate of the 2Pr value of the ferroelectric capacitor according to Example 32, and “XXXVI” represents the reduction rate of the 2Pr value of the ferroelectric capacitor according to Example 33.

Referring to FIG. 70, after about 100 hours at a temperature of about 150° C., the 2Pr value of the ferroelectric capacitor of Comparative Example 7 was reduced from about 32.9 μC/cm² to about 20.1 μC/cm² so that the ferroelectric capacitor of Comparative Example 7 had a high reduction rate of the 2Pr value of about 38.9%. However, the 2Pr value of the ferroelectric capacitor of Example 32 was reduced from about 28.1 μC/cm² to about 23.8 μC/cm² after about 100 hours at a temperature of about 150° C. Hence, the ferroelectric capacitor of Example 32 had a very low reduction rate of the 2Pr value of about 15.3%. Additionally, the 2Pr value of the ferroelectric capacitor of Example 33 was reduced from about 24.8° C./cm² to about 17.9 μC/cm² after about 100 hours at a temperature of about 150° C. Thus, the ferroelectric capacitor of Example 33 had a slightly low reduction rate of the 2Pr value of about 27.8%.

FIG. 71 is a graph illustrating reduction rates of 2Pr values of the ferroelectric capacitors relative to time in accordance with Examples 34 and 35, and Comparative Example 7. In FIG. 71, “X VI” indicates the reduction rate of the 2Pr value of the ferroelectric capacitor according to Comparative Example 7, “XXXVII” means the reduction rate of the 2Pr value of the ferroelectric capacitor according to Example 34, and “XXXVIII” represents the reduction rate of the 2Pr value of the ferroelectric capacitor according to Example 35.

Referring to FIG. 71, after about 100 hours at a temperature of about 150° C., the 2Pr value of the ferroelectric capacitor of Comparative Example 7 was reduced from about 32.9 μC/cm² to about 20.1 μC/cm² so that the ferroelectric capacitor of Comparative Example 7 had a high reduction rate of the 2Pr value of about 38.9%. However, the 2Pr value of the ferroelectric capacitor of Example 34 was reduced from about 24.2 μC/cm² to about 19.5 μC/cm² after about 100 hours at a temperature of about 150° C. Hence, the ferroelectric capacitor of Example 34 had a very low reduction rate of the 2Pr value of about 19.4%. Additionally, the 2Pr value of the ferroelectric capacitor of Example 35 was reduced from about 27.5 μC/cm² to about 18.3 μC/cm² after about 100 hours at a temperature of about 150° C. Thus, the ferroelectric capacitor of Example 33 had a relatively low reduction rate of the 2Pr value of about 33.5%.

Measurements of Characteristics of Ferroelectric Capacitors Relative to Cleaning and Thermal Treating Processes

### EXAMPLE 36

A lower electrode layer including a first lower electrode film and a second lower electrode film was formed on a substrate. The first and the second lower electrode films were formed using titanium aluminum nitride and iridium, respectively. The first and the second lower electrode films had average thicknesses of about 300 Å and about 1,200 Å, respectively.

A preliminary ferroelectric layer was formed on the lower electrode layer. The preliminary ferroelectric layer was formed using PZT by an MOCVD process. The preliminary ferroelectric layer had an average thickness of about 937 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 60 seconds using a cleaning solution that included an SMF solution. After the cleaning process, the thin ferroelectric layer had an average thickness of about 878 Å.

An upper electrode layer was formed on the thin ferroelectric layer. The upper electrode layer had a first upper electrode film and a second upper electrode film. The first upper electrode film was formed using SRO to have an average thickness of about 50 Å, and the second upper electrode film was formed using iridium to have an average thickness of about 600 Å.

### EXAMPLE 37

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 949 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 60 seconds using a cleaning solution that included an SMF solution. After the cleaning process, the thin ferroelectric layer had an average thickness of about 890 Å.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### EXAMPLE 38

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 945 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 60 seconds using a cleaning solution that included an SMF solution. After the cleaning process, the thin ferroelectric layer had an average thickness of about 892 Å. The thin ferroelectric layer was thermally treated at a temperature of about 550° C. for about 60 seconds.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### EXAMPLE 39

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 945 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 60 seconds using a cleaning solution that included an SMC solution. After the cleaning process, the thin ferroelectric layer had an average thickness of about 943 Å.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### EXAMPLE 40

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 954 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 60 seconds using a cleaning solution that included an SMC solution. After the cleaning process, the thin ferroelectric layer had an average thickness of about 945 Å.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### EXAMPLE 41

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 941 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 60 seconds using a cleaning solution that included an SMC solution. After the cleaning process, the thin ferroelectric layer had an average thickness of about 939 Å. The thin ferroelectric layer was thermally treated at a temperature of about 550° C. for about 60 seconds.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### EXAMPLE 42

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 936 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 80 seconds using a cleaning solution that included an ammonia solution. After the cleaning process, the thin ferroelectric layer had an average thickness of about 932 Å.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### EXAMPLE 43

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 924 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 60 seconds using a cleaning solution that included an ammonia solution. After the cleaning process, the thin ferroelectric layer had an average thickness of about 922 Å.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### EXAMPLE 44

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 950 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 80 seconds using a cleaning solution that included an ammonia solution. After the cleaning process, the thin ferroelectric layer had an average thickness of about 944 Å. The thin ferroelectric layer was thermally treated at a temperature of about 550° C. for about 60 seconds.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### EXAMPLE 45

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 956 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 60 seconds using a cleaning solution that included a nitric acid solution. After the cleaning process, the thin ferroelectric layer had an average thickness of about 934 Å.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### EXAMPLE 46

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 933 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 60 seconds using a cleaning solution that included a nitric acid solution. After the cleaning process, the thin ferroelectric layer had an average thickness of about 909 Å.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### EXAMPLE 47

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 925 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 60 seconds using a cleaning solution that included a nitric acid solution. After the cleaning process, the thin ferroelectric layer had an average thickness of about 903 Å. The thin ferroelectric layer was thermally treated at a temperature of about 550° C. for about 60 seconds.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### EXAMPLE 48

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 941 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 60 seconds using a cleaning solution that included an SC1 solution. After the cleaning process, the thin ferroelectric layer had an average thickness of about 937 Å.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### EXAMPLE 49

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 937 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 60 seconds using a cleaning solution that included an SC1 solution. After the cleaning process, the thin ferroelectric layer had an average thickness of about 935 Å.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### EXAMPLE 50

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 920 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was cleaned for about 60 seconds using a cleaning solution that included an SC1 solution. After the cleaning process, the thin ferroelectric layer had an average thickness of about 913 Å. The thin ferroelectric layer was thermally treated at a temperature of about 550° C. for about 60 seconds.

An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second lower electrode films in Example 36.

### COMPARATIVE EXAMPLE 8

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 915 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was not cleaned. An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### COMPARATIVE EXAMPLE 9

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 950 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

The thin ferroelectric layer was not cleaned. An upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second upper electrode films in Example 36.

### COMPARATIVE EXAMPLE 10

A lower electrode layer including a first lower electrode film and a second lower electrode film was formed on a substrate. The first and the second lower electrode films were formed using titanium aluminum nitride and iridium, respectively. The first and the second lower electrode films had average thicknesses substantially identical to those of the first and the second lower electrode films in Example 36.

A preliminary ferroelectric layer was formed on the lower electrode layer. The preliminary ferroelectric layer was formed using PZT by an MOCVD process. The preliminary ferroelectric layer had an average thickness of about 925 Å.

The preliminary ferroelectric layer was polished by a CMP process to thereby form a thin ferroelectric layer on the lower electrode layer. In the CMP process, a downward pressure was substantially identical to the above-described relatively low pressure, and a rotation speed of a polishing pad was also substantially identical to the above-described relatively low speed.

After the thin ferroelectric layer was cleaned, an upper electrode layer was formed on the thin ferroelectric layer. The upper electrode layer had a first upper electrode film and a second upper electrode film. The first upper electrode film was formed using SRO, and the second upper electrode film was formed using iridium. The first and the second upper electrode films had average thicknesses substantially identical to those of the first and the second lower electrode films in Example 36.

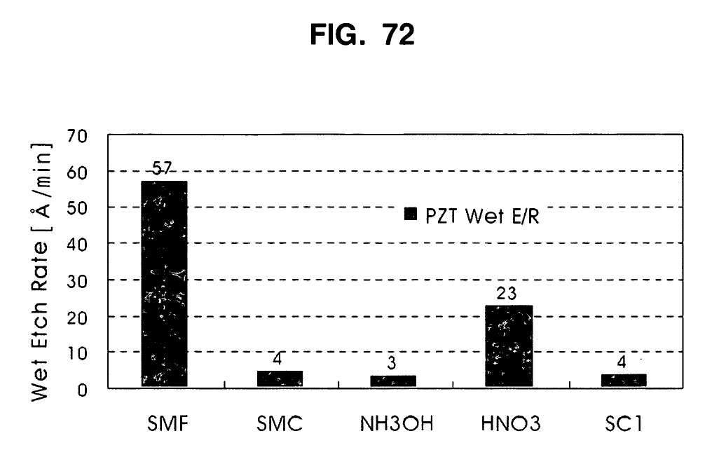

FIG. 72 is a graph illustrating etch rates of thin ferroelectric layers relative to cleaning solutions in accordance with example embodiments of the present invention.

As shown in FIG. 72, an average etch rate of a thin ferroelectric layer was about 57 Å/minute with respect to a cleaning solution including an SMF solution, and an average etch rate of a thin ferroelectric layer was about 23 Å/minute relative to a cleaning solution including a nitric acid solution. A thin ferroelectric layer had an average etch rate of about 4 Å/minute relative to a cleaning solution including an SMC solution, and a thin ferroelectric layer also had an average etch rate of about 4 Å/minute with respect to a cleaning solution including an SC1 solution. In addition, an average etch rate of a thin ferroelectric layer was about 3 Å/minute relative to a cleaning solution including an ammonia solution. The etch rates of the thin ferroelectric layers were generally in a range of about 3 Å/minute to about 4 Å/minute with respect to the cleaning solutions including the SMC solution, the ammonia solution and the SC1 solution; however, the etch rate of the thin ferroelectric layer was relatively high relative to the cleaning solution including an SMF solution because the SMF solution included minute fluoride that may rapidly etch the thin ferroelectric layer.

When the thin ferroelectric layer was cleaned using the above-described cleaning solution, a surface of the thin ferroelectric layer was slightly etched. Therefore, a damage to the surface of the thin ferroelectric layer might be somewhat cured after the cleaning process when the damage to the surface of the thin ferroelectric layer is cured in a polishing process.

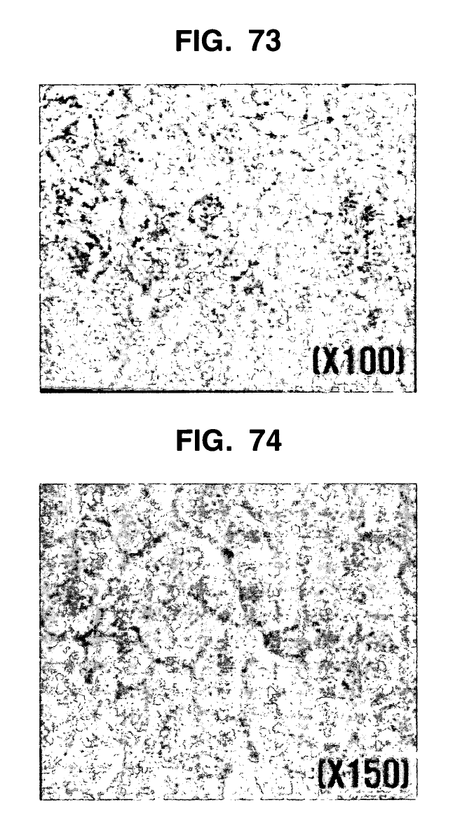

FIG. 73 is a picture showing a surface of the thin ferroelectric layer obtained using an SEM in accordance with Comparative Example 9, and FIG. 74 is an enlarged picture showing the surface of the thin ferroelectric layer in FIG. 73. In FIG. 73, the surface of the thin ferroelectric layer of Comparative Example 9 is magnified by a ratio of about 100. Additionally, the surface of the thin ferroelectric layer of Comparative Example 9 is magnified by a ratio of about 150 in FIG. 74.

Referring to FIGS. 73 and 74, when the cleaning process and the thermal treatment process were not performed on the thin ferroelectric layer, slurry residues and/or polishing residues remained on the surface of the thin ferroelectric layer. Additionally, the surface of the thin ferroelectric layer was irregular.

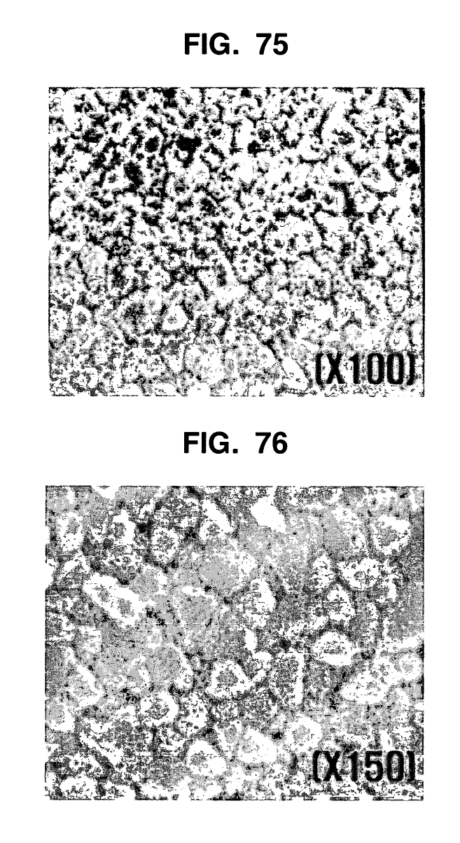

FIG. 75 is a picture showing a surface of the thin ferroelectric layer obtained using an SEM in accordance with Example 39, and FIG. 76 is an enlarged picture showing the surface of the thin ferroelectric layer in FIG. 75. In FIG. 75, the surface of the thin ferroelectric layer of Example 39 is magnified by a ratio of about 100. Additionally, the surface of the thin ferroelectric layer of Example 39 is magnified by a ratio of about 150 in FIG. 76.

As shown in FIGS. 75 and 76, when the cleaning process was executed on the thin ferroelectric layer using the SMF solution without the thermal treatment process, an etched damage was generated to the surface of the thin ferroelectric layer even though slurry residues and/or polishing residues were removed from the surface of the thin ferroelectric layer.

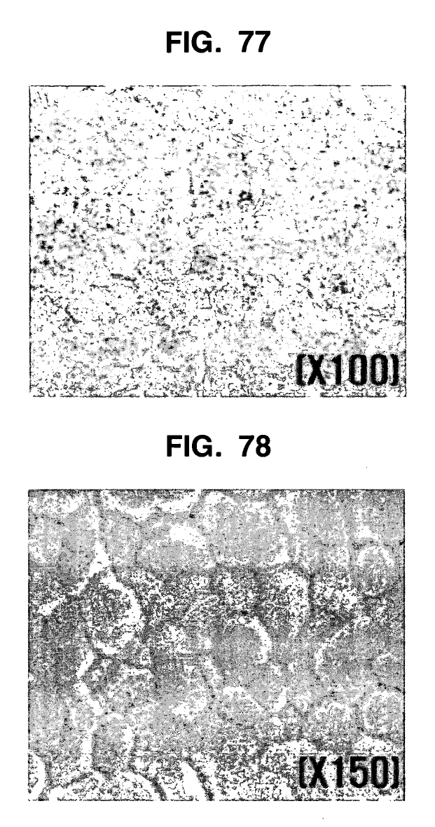

FIG. 77 is a picture showing a surface of the thin ferroelectric layer obtained using an SEM in accordance with Example 40, and FIG. 78 is an enlarged picture showing the surface of the thin ferroelectric layer in FIG. 77. In FIG. 78, the surface of the thin ferroelectric layer of Example 40 is magnified by a ratio of about 100. Additionally, the surface of the thin ferroelectric layer of Example 40 is magnified by a ratio of about 150 in FIG. 78.

Referring to FIGS. 77 and 78, when the cleaning process was performed on the thin ferroelectric layer using the SMC solution, slurry residues and/or polishing residues were removed from the surface of the thin ferroelectric layer, and also the polished damage to the surface of the thin ferroelectric layer was somewhat cured even though the thermal treatment process was not carried out.

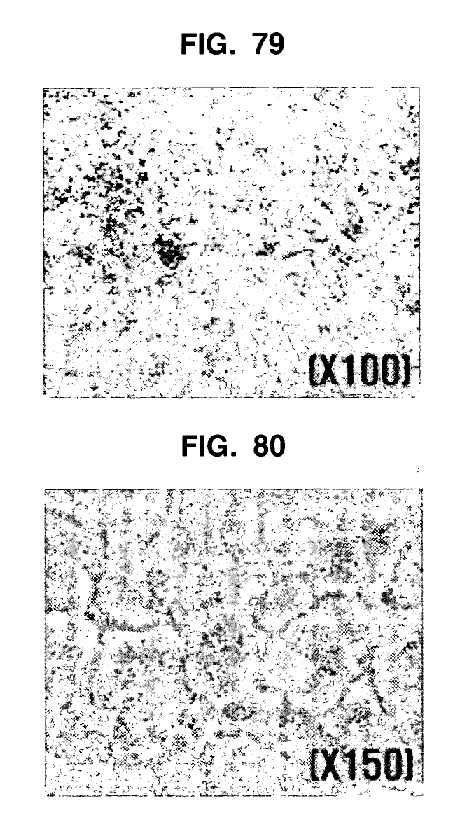

FIG. 79 is a picture showing a surface of the thin ferroelectric layer obtained using an SEM in accordance with Example 43, and FIG. 80 is an enlarged picture showing the surface of the thin ferroelectric layer in FIG. 79. In FIG. 79, the surface of the thin ferroelectric layer of Example 43 is magnified by a ratio of about 100. Additionally, the surface of the thin ferroelectric layer of Example 43 is magnified by a ratio of about 150 in FIG. 80.

Referring to FIGS. 79 and 80, when the cleaning process was performed on the thin ferroelectric layer using the ammonia solution without the thermal treatment process, slurry residues and/or polishing residues were removed from the surface of the thin ferroelectric layer, and also the polished damage to the surface of the thin ferroelectric layer was somewhat cured.

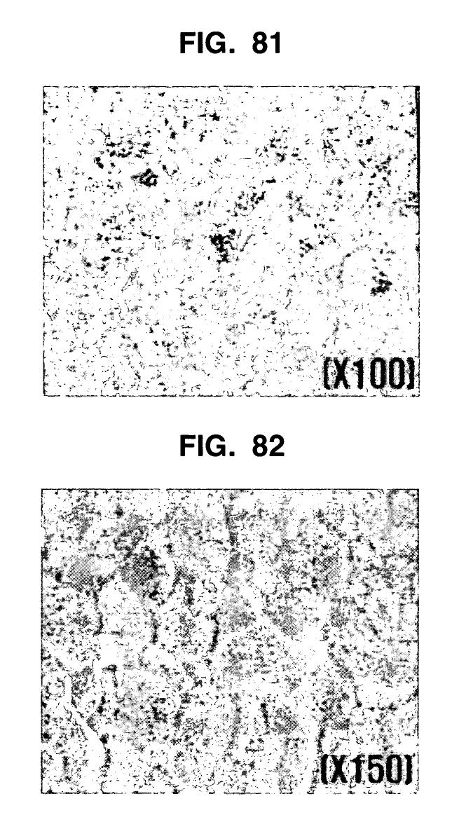

FIG. 81 is a picture showing a surface of the thin ferroelectric layer obtained using an SEM in accordance with Example 46, and FIG. 82 is an enlarged picture showing the surface of the thin ferroelectric layer in FIG. 81. In FIG. 81, the surface of the thin ferroelectric layer of Example 46 is magnified by a ratio of about 100. Additionally, the surface of the thin ferroelectric layer of Example 46 is magnified by a ratio of about 150 in FIG. 82.

As shown in FIGS. 81 and 82, when the cleaning process was performed on the thin ferroelectric layer using the nitric acid solution without the thermal treatment process, slurry residues and/or polishing residues were removed from the surface of the thin ferroelectric layer, and also the polished damage to the surface of the thin ferroelectric layer was substantially cured.

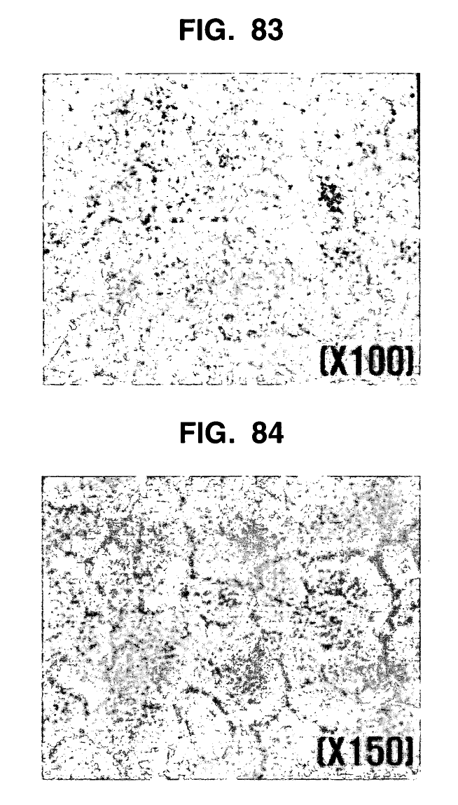

FIG. 83 is a picture showing a surface of the thin ferroelectric layer obtained using an SEM in accordance with Example 49, and FIG. 84 is an enlarged picture showing the surface of the thin ferroelectric layer in FIG. 83. In FIG. 83, the surface of the thin ferroelectric layer of Example 49 is magnified by a ratio of about 100. Additionally, the surface of the thin ferroelectric layer of Example 49 is magnified by a ratio of about 150 in FIG. 84.

As shown in FIGS. 83 and 84, when the cleaning process was performed on the thin ferroelectric layer using the SC1 solution without the thermal treatment process, slurry residues and/or polishing residues were removed from the surface of the thin ferroelectric layer, and also the polished damage to the surface of the thin ferroelectric layer was partially cured.

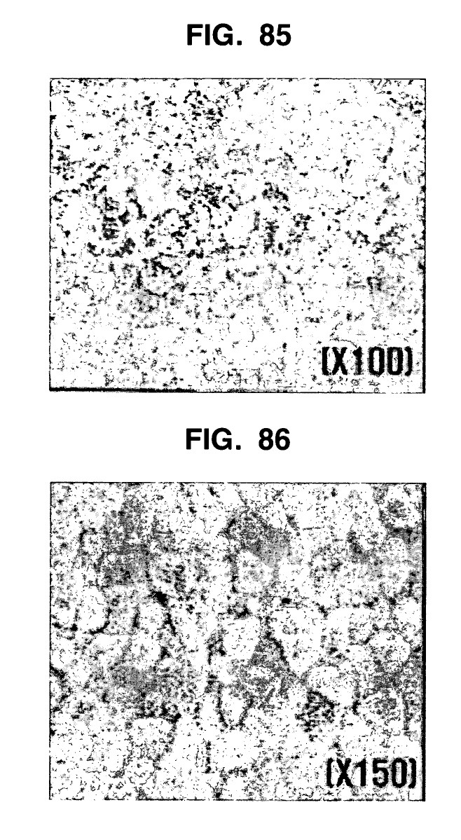

FIG. 85 is a picture showing a surface of the thin ferroelectric layer obtained using an SEM in accordance with Comparative Example 10, and FIG. 86 is an enlarged picture showing the surface of the thin ferroelectric layer in FIG. 85. In FIG. 85, the surface of the thin ferroelectric layer of Comparative Example 10 is magnified by a ratio of about 100. Additionally, the surface of the thin ferroelectric layer of Comparative Example 10 is magnified by a ratio of about 150 in FIG. 86.

Referring to FIGS. 85 and 86, when the thermal treatment was performed on the thin ferroelectric layer without the cleaning process, although slurry residues and/or polishing residues partially remained on the surface of the thin ferroelectric layer, the polished damage to the surface of the thin ferroelectric layer was partially cured.

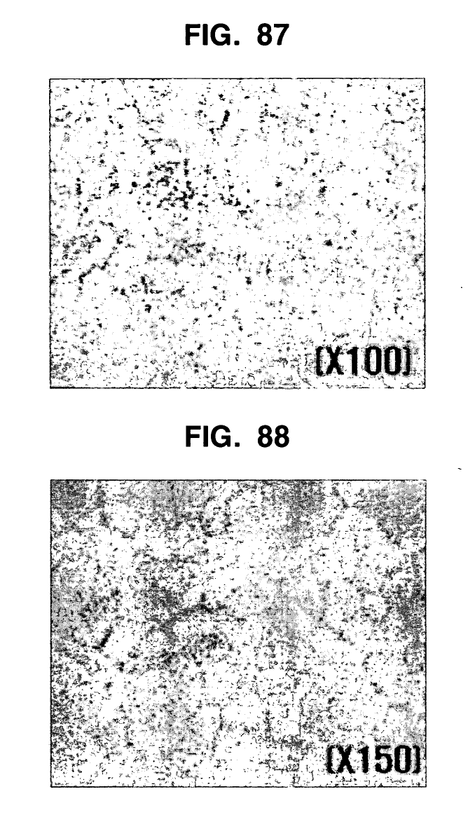

FIG. 87 is a picture showing a surface of the thin ferroelectric layer obtained using an SEM in accordance with Example 44, and FIG. 88 is an enlarged picture showing the surface of the thin ferroelectric layer in FIG. 87. In FIG. 87, the surface of the thin ferroelectric layer of Example 44 is magnified by a ratio of about 100. Additionally, the surface of the thin ferroelectric layer of Example 44 is magnified by a ratio of about 150 in FIG. 88.

Referring to FIGS. 87 and 88, when the cleaning process was performed on the thin ferroelectric layer using the nitric acid solution, and the thermal treatment process was additionally executed on the thin ferroelectric layer, slurry residues and/or polishing residues were removed from the surface of the thin ferroelectric layer, and also the polished damage to the surface of the thin ferroelectric layer was cured.

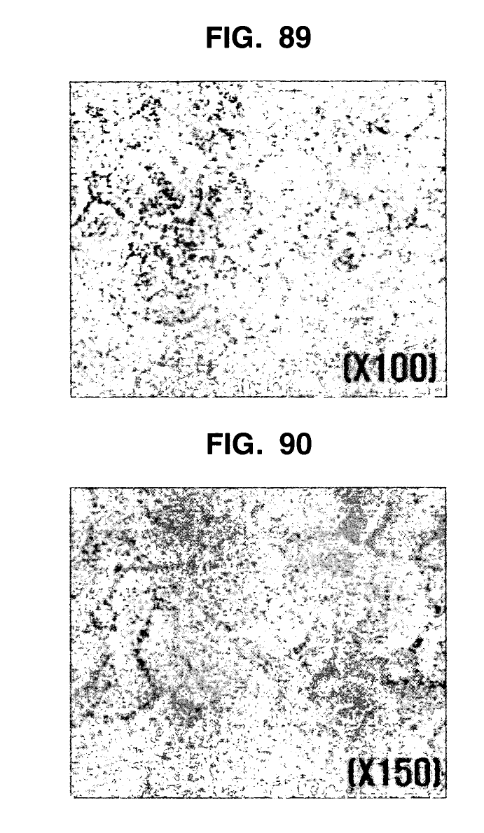

FIG. 89 is a picture showing a surface of the thin ferroelectric layer obtained using an SEM in accordance with Example 50, and FIG. 90 is an enlarged picture showing the surface of the thin ferroelectric layer in FIG. 89. In FIG. 89, the surface of the thin ferroelectric layer of Example 50 is magnified by a ratio of about 100. Additionally, the surface of the thin ferroelectric layer of Example 50 is magnified by a ratio of about 150 in FIG. 90.

Referring to FIGS. 89 and 90, when the cleaning process was performed on the thin ferroelectric layer using the SC1 solution, and the thermal treatment process was additionally executed on the thin ferroelectric layer, slurry residues and/or polishing residues were removed from the surface of the thin ferroelectric layer, and also the polished damage to the surface of the thin ferroelectric layer was cured.

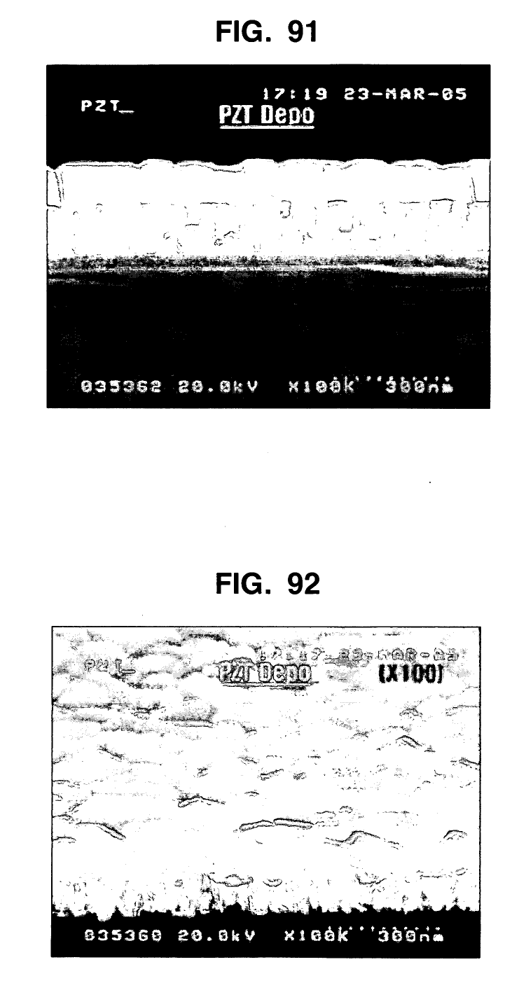

FIG. 91 is a picture showing a cross-section of the thin ferroelectric layer obtained using an SEM in accordance with Comparative Example 8, and FIG. 92 is a picture showing a surface of the thin ferroelectric layer obtained using an SEM in accordance with Comparative Example 8.

Referring to FIGS. 91 and 92, when the cleaning process and the thermal treatment process were not executed on the thin ferroelectric layer, slurry residues and/or polishing residues remained on the surface of the thin ferroelectric layer, and also the polished damage to the surface of the thin ferroelectric layer was not cured. Thus, defects were observed on the surface of the thin ferroelectric film.

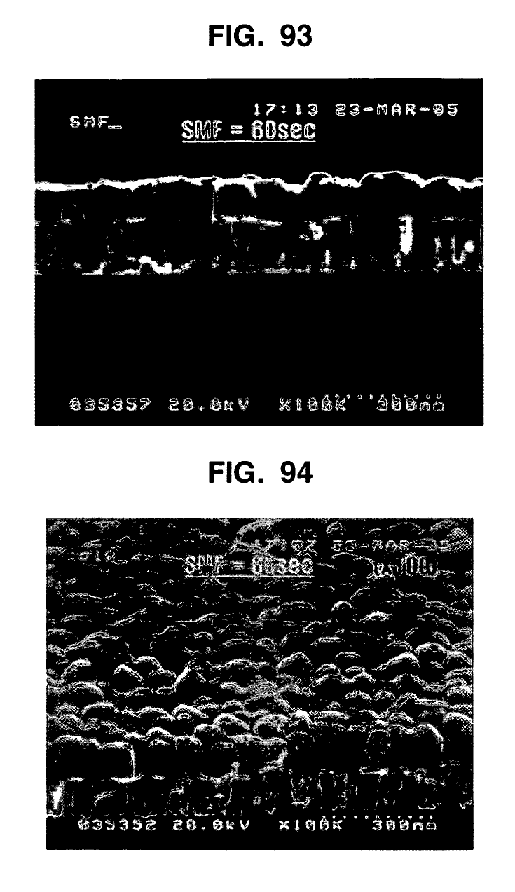

FIG. 93 is a picture showing a cross-section of the thin ferroelectric layer obtained using an SEM in accordance with Example 36, and FIG. 94 is a picture showing a surface of the thin ferroelectric layer obtained using an SEM in accordance with Example 36.

Referring to FIGS. 93 and 94, when the cleaning process was executed on the thin ferroelectric layer using the SMF solution without the thermal treatment process, although defects of the surface of the thin ferroelectric layer were somewhat cured, an etched damage was generated at the surface of the thin ferroelectric layer. Thus, the surface of the thin ferroelectric layer was very irregular.

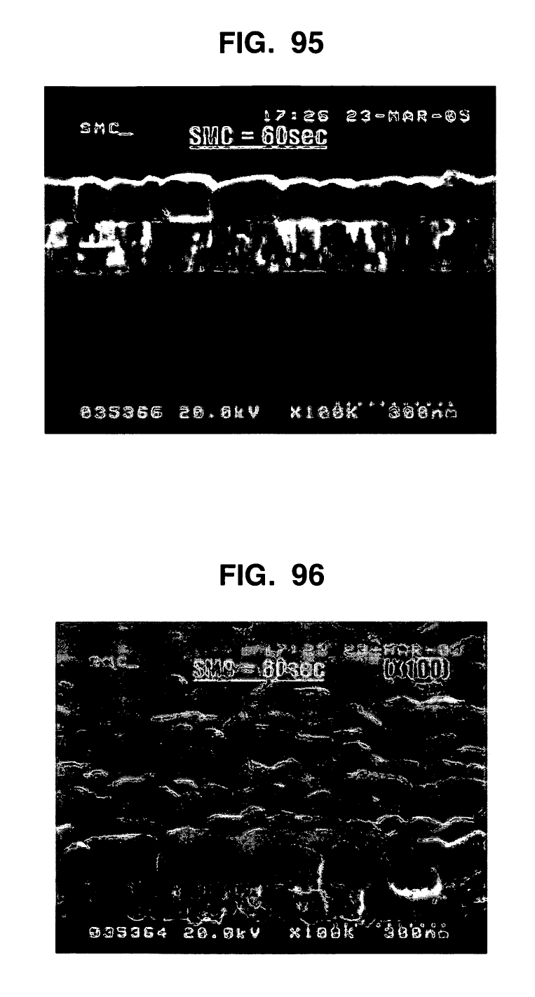

FIG. 95 is a picture showing a cross-section of the thin ferroelectric layer obtained using an SEM in accordance with Example 39, and FIG. 96 is a picture showing a surface of the thin ferroelectric layer obtained using an SEM in accordance with Example 39.

As shown in FIGS. 95 and 96, when the cleaning process was performed on the thin ferroelectric layer using the SMC solution without the thermal treatment process, defects of the surface of the thin ferroelectric layer were cured so that the surface of the thin ferroelectric layer was relatively uniform.

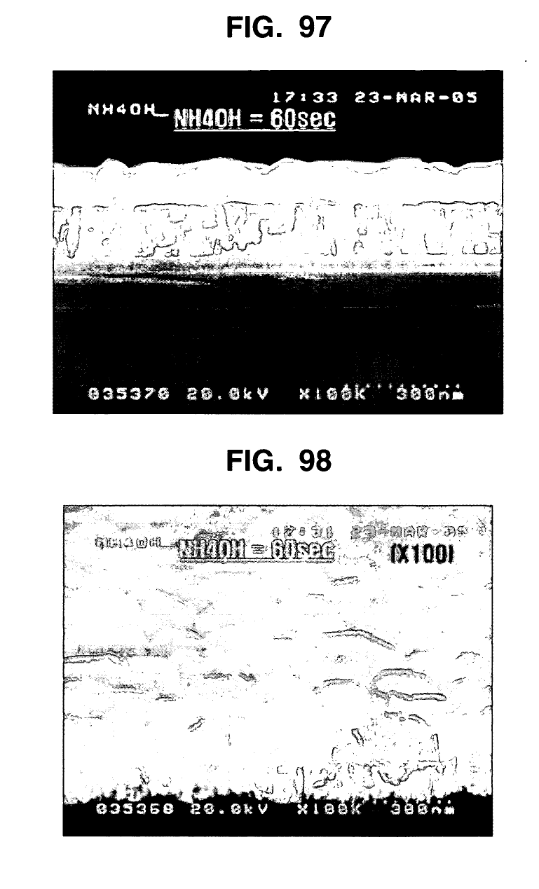

FIG. 97 is a picture showing a cross-section of the thin ferroelectric layer obtained using an SEM in accordance with Example 42, and FIG. 98 is a picture showing a surface of the thin ferroelectric layer obtained using an SEM in accordance with Example 42.

Referring to FIGS. 97 and 98, when the cleaning process was performed on the thin ferroelectric layer using the ammonia solution without the thermal treatment process, defects of the surface of the thin ferroelectric layer were cured so that the surface of the thin ferroelectric layer became uniform.

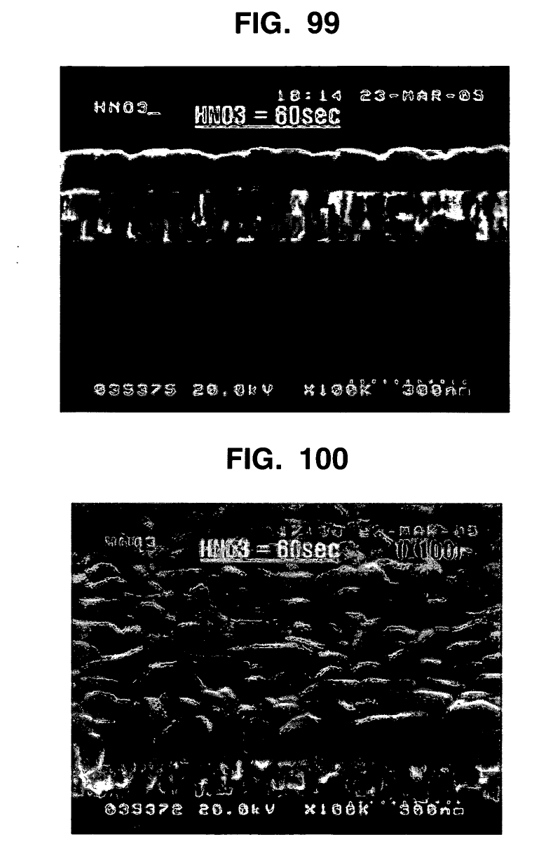

FIG. 99 is a picture showing a cross-section of the thin ferroelectric layer obtained using an SEM in accordance with Example 45, and FIG. 100 is a picture showing a surface of the thin ferroelectric layer obtained using an SEM in accordance with Example 45.

Referring to FIGS. 99 and 100, when the cleaning process was performed on the thin ferroelectric layer using the nitric acid solution without the thermal treatment process, although defects of the surface of the thin ferroelectric layer were cured, an etched damage was partially generated at the surface of the thin ferroelectric layer. Thus, the surface of the thin ferroelectric layer was irregular.

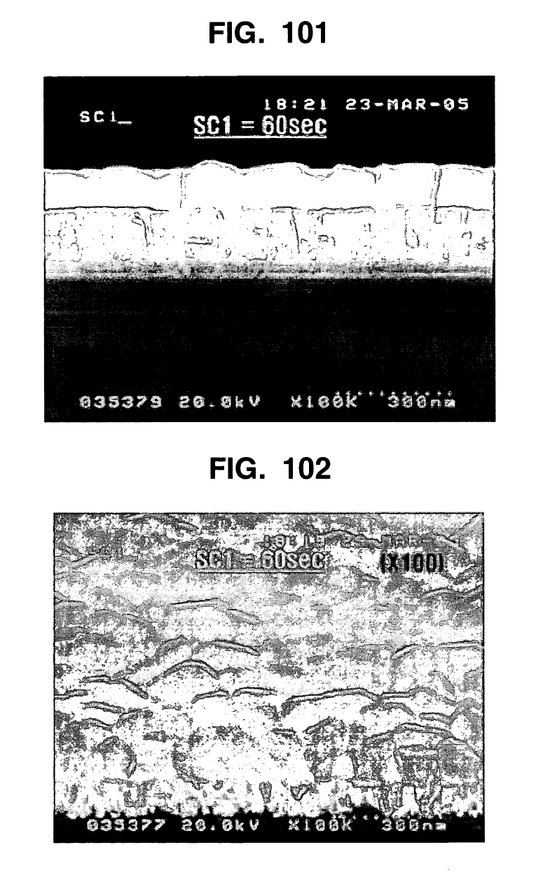

FIG. 101 is a picture showing a cross-section of the thin ferroelectric layer obtained using an SEM in accordance with Example 48, and FIG. 102 is a picture showing a surface of the thin ferroelectric layer obtained using an SEM in accordance with Example 48.

Referring to FIGS. 101 and 102, when the cleaning process was performed on the thin ferroelectric layer using the SC1 solution without the thermal treatment process, defects of the surface of the thin ferroelectric layer were somewhat cured so that the surface of the thin ferroelectric layer was relatively uniform.

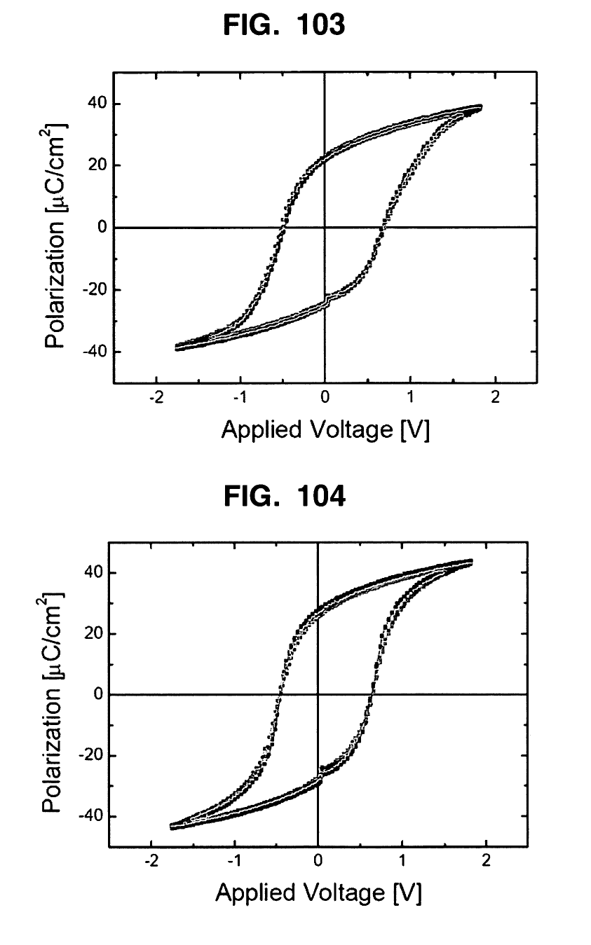

FIG. 103 is a graph illustrating a P-V hysteresis loop of a ferroelectric capacitor in accordance with Comparative Example 8. In FIG. 103, a polarization of the ferroelectric capacitor of Comparative Example 8 was measured with respect to an applied voltage.

Referring to FIG. 103, when +V_{C} was about 0.69 V and −V_{C} was about −0.49 V, the ferroelectric capacitor of Comparative Example 8 had an average 2Pr value of about 44.5 μC/cm². However, the ferroelectric capacitor of Comparative Example 8 had a relatively small leakage current density of about +8.90×10⁻⁹ A/cm² to about −4.07×10⁻⁹ A/cm² when +V_{C} was about 0.69 V and −V_{C} was about −0.49 V.

FIG. 104 is a graph illustrating a P-V hysteresis loop of a ferroelectric capacitor in accordance with Comparative Example 10. In FIG. 104, a polarization of the ferroelectric capacitor of Comparative Example 10 was measured with respect to an applied voltage.

Referring to FIG. 104, when +V_{C} was about 0.64 V and −V_{C} was about −0.45 V, the ferroelectric capacitor of Comparative Example 10 had an average 2Pr value of about 51.0 μC/cm². However, the ferroelectric capacitor of Comparative Example 10 had a relatively large leakage current density of about +2.92×10⁻⁷ A/cm² to about −1.52×10⁻⁷ A/cm².

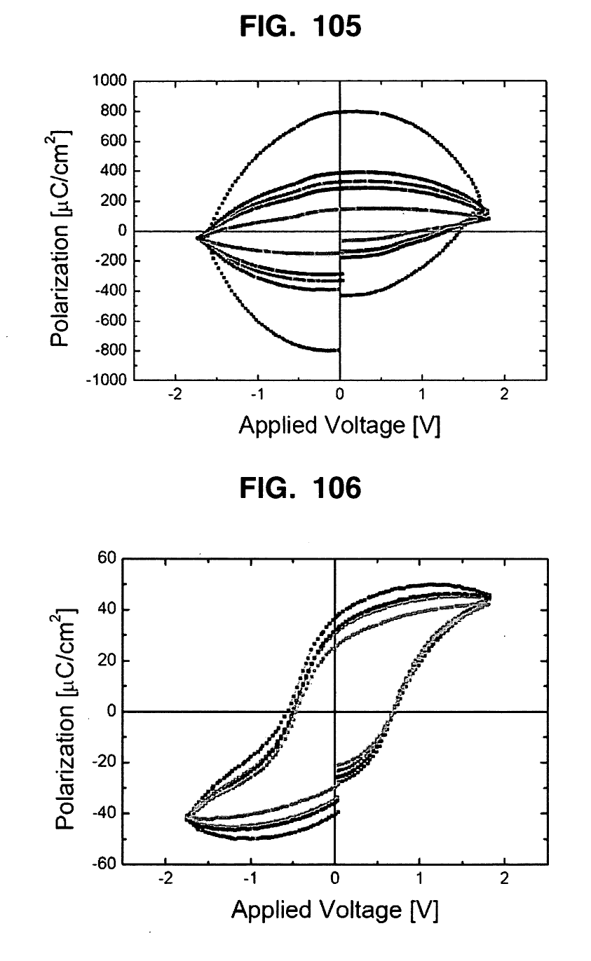

FIG. 105 is a graph illustrating a P-V hysteresis loop of a ferroelectric capacitor in accordance with Example 36. In FIG. 105, a polarization of the ferroelectric capacitor of Example 36 was measured with respect to an applied voltage.

Referring to FIG. 105, when +V_{C} was about 0.63 V and −V_{C} was about −1.26 V, the ferroelectric capacitor of Example 36 had an average 2Pr value of about 46.2 μC/cm². However, the ferroelectric capacitor of Example 36 had a large leakage current density of about +3.53×10⁻⁴ A/cm² to about −3.77×10⁻⁴ A/cm² when +V_{C} was about 0.63 V and −V_{C} was about −1.26 V.

FIG. 106 is a graph illustrating a P-V hysteresis loop of a ferroelectric capacitor in accordance with Example 38. In FIG. 106, a polarization of the ferroelectric capacitor of Example 38 was measured with respect to an applied voltage.

Referring to FIG. 106, when +V_{C} was about 0.69 V and −V_{C} was about −0.50 V, the ferroelectric capacitor of Example 38 had an average 2Pr value of about 39.8 μC/cm². However, the ferroelectric capacitor of Example 38 had a relatively large leakage current density of about +6.50×10⁻⁵ A/cm² to about −7.27×10⁻⁵ A/cm².

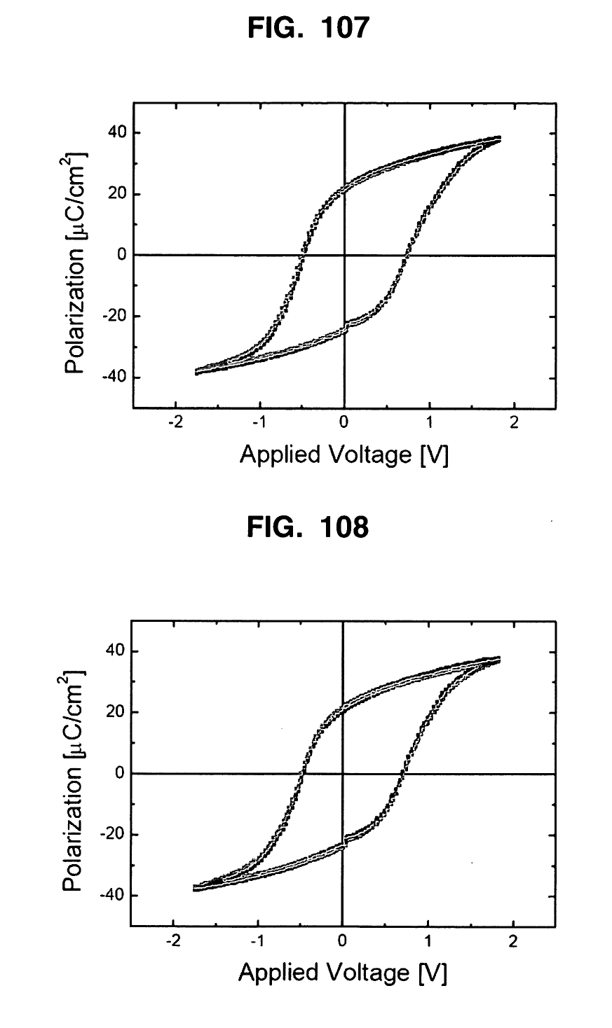

FIG. 107 is a graph illustrating a P-V hysteresis loop of a ferroelectric capacitor in accordance with Example 40. In FIG. 107, a polarization of the ferroelectric capacitor of Example 40 was measured with respect to an applied voltage.

Referring to FIG. 107, when +V_{C} was about 0.74 V and −V_{C} was about −0.49 V, the ferroelectric capacitor of Example 40 had an average 2Pr value of about 43.8 μC/cm². Additionally, the ferroelectric capacitor of Example 40 had a very small leakage current density of about +5.10×10⁻⁹ A/cm² to about −3.31×10⁻⁹ A/cm² when +V_{C} was about 0.74 V and −V_{C} was about −0.49 V.

FIG. 108 is a graph illustrating a P-V hysteresis loop of a ferroelectric capacitor in accordance with Example 41. In FIG. 108, a polarization of the ferroelectric capacitor of Example 41 was measured with respect to an applied voltage.

Referring to FIG. 108, when +V_{C} was about 0.71 V and −V_{C} was about −0.48 V, the ferroelectric capacitor of Example 41 had an average 2Pr value of about 42.5 μc/m². In addition, the ferroelectric capacitor of Example 41 had a very small leakage current density of about +7.78×10⁻⁹ A/cm² to about −1.29×10⁻⁹ A/cm².

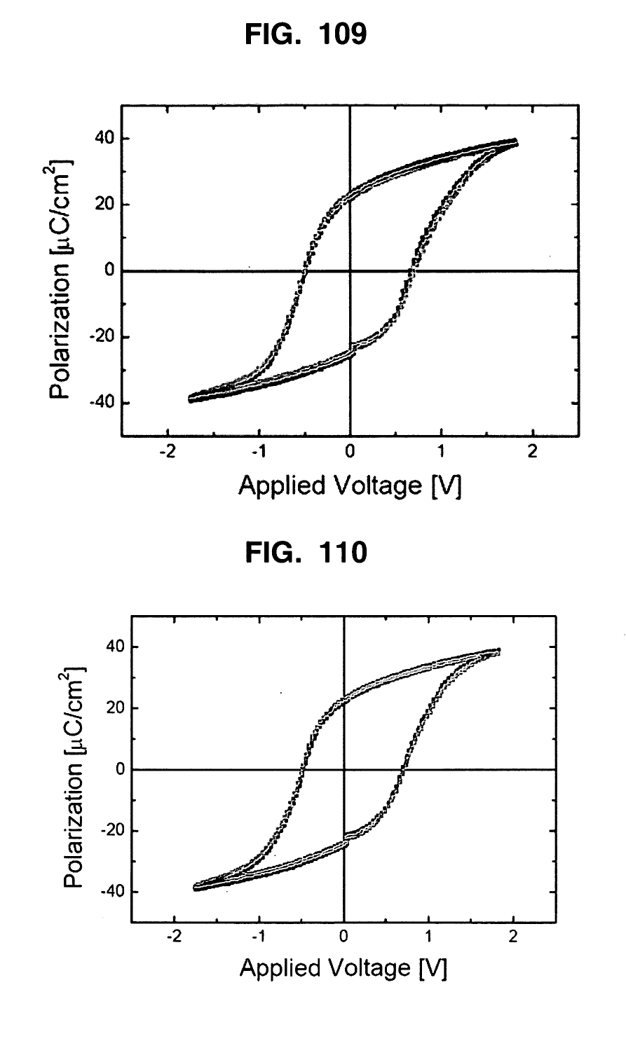

FIG. 109 is a graph illustrating a P-V hysteresis loop of a ferroelectric capacitor in accordance with Example 43. In FIG. 109, a polarization of the ferroelectric capacitor of Example 43 was measured with respect to an applied voltage.

Referring to FIG. 109, when +V_{C} was about 0.69 V and −V_{C} was about −0.50 V, the ferroelectric capacitor of Example 43 had an average 2Pr value of about 45.6 μC/cm². Additionally, the ferroelectric capacitor of Example 43 had a very small leakage current density of about +1.03×10⁻⁸ A/cm² to about −3.24×10⁻⁹ A/cm² when +V_{C} was about 0.69 V and −V_{C} was about −0.50 V.

FIG. 110 is a graph illustrating a P-V hysteresis loop of a ferroelectric capacitor in accordance with Example 44. In FIG. 110, a polarization of the ferroelectric capacitor of Example 44 was measured with respect to an applied voltage.

Referring to FIG. 110, when +V_{C} was about 0.71 V and −V_{C} was about −0.49 V, the ferroelectric capacitor of Example 44 had an average 2Pr value of about 44.7 μC/cm². Additionally, the ferroelectric capacitor of Example 44 had a considerably small leakage current density of about +5.46×10⁻⁹ A/cm² to about −7.83×10⁻⁸ A/cm².

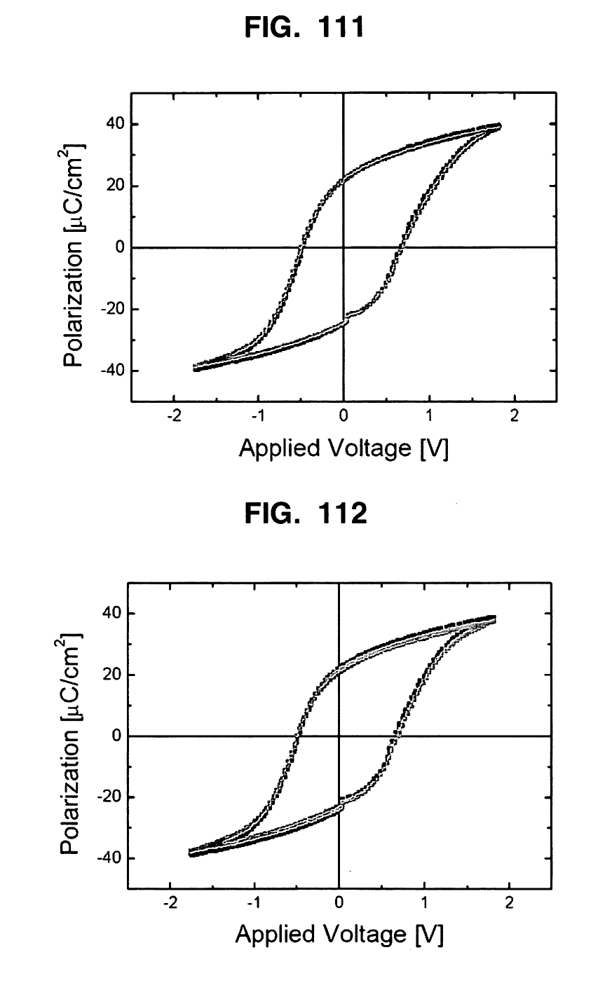

FIG. 111 is a graph illustrating a P-V hysteresis loop of a ferroelectric capacitor in accordance with Example 46. In FIG. 111, a polarization of the ferroelectric capacitor of Example 46 was measured with respect to an applied voltage.

Referring to FIG. 111, when +V_{C} was about 0.68 V and −V_{C} was about −0.48 V, the ferroelectric capacitor of Example 46 had an average 2Pr value of about 43.5 μC/cm². Additionally, the ferroelectric capacitor of Example 46 had a very small leakage current density of about +9.43×10⁻⁹ A/cm² to about −3.38×10⁻⁹ A/cm² when +V_{C} was about 0.68 V and −V_{C} was about −0.48 V.

FIG. 112 is a graph illustrating a P-V hysteresis loop of a ferroelectric capacitor in accordance with Example 47. In FIG. 112, a polarization of the ferroelectric capacitor of Example 47 was measured with respect to an applied voltage.

Referring to FIG. 112, when +V_{C} was about 0.67 V and −V_{C} was about −0.48 V, the ferroelectric capacitor of Example 47 had an average 2Pr value of about 42.7 μC/cm². In addition, the ferroelectric capacitor of Example 47 had a very small leakage current density of about +6.59×10⁻⁹ A/cm² to about −9.51×10⁻⁹ A/cm² when +V_{C} was about 0.69 V and −V_{C} was about −0.50 V.

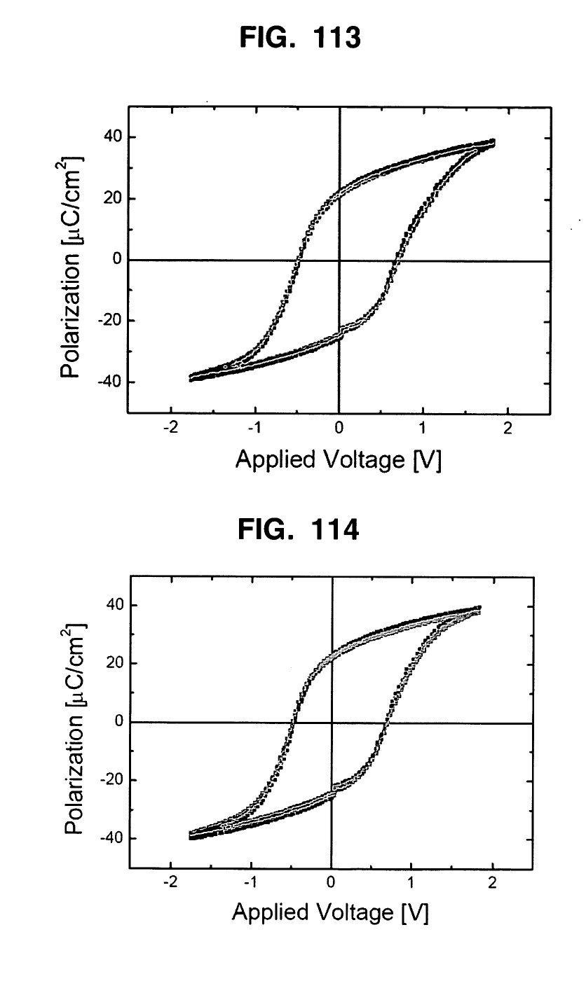

FIG. 113 is a graph illustrating a P-V hysteresis loop of a ferroelectric capacitor in accordance with Example 49. In FIG. 113, a polarization of the ferroelectric capacitor of Example 49 was measured with respect to an applied voltage.

Referring to FIG. 113, when +V_{C} was about 0.70 V and −V_{C} was about −0.49 V, the ferroelectric capacitor of Example 49 had an average 2Pr value of about 44.1 μC/cm². Additionally, the ferroelectric capacitor of Example 49 had a very small leakage current density of about +9.94×10⁻⁹ A/cm² to about −4.03×10⁻⁹ A/Cm².

FIG. 114 is a graph illustrating a P-V hysteresis loop of a ferroelectric capacitor in accordance with Example 50. In FIG. 114, a polarization of the ferroelectric capacitor of Example 50 was measured with respect to an applied voltage.

Referring to FIG. 114, when +V_{C} was about 0.70 V and −V_{C} was about −0.48 V, the ferroelectric capacitor of Example 50 had an average 2Pr value of about 44.5 μC/Cm². In addition, the ferroelectric capacitor of Example 50 had a considerably small leakage current density of about +6.40×10⁻⁹ A/cm² to about −1.18×10⁻⁸ A/cm² when +V_{C} was about 0.70 V and −V_{C} was about −0.48 V.

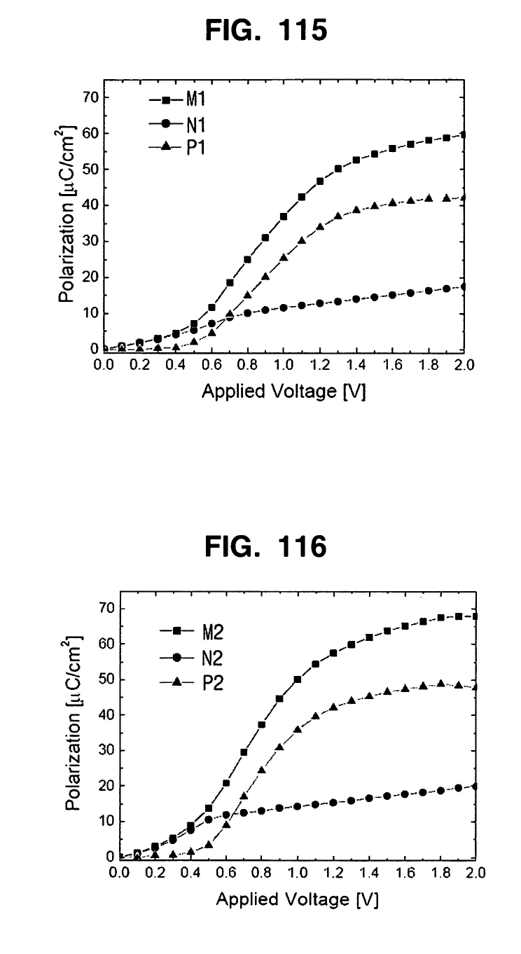

FIG. 115 is a graph illustrating a polarization of the ferroelectric capacitor relative to an applied voltage in accordance with Comparative Example 9. In FIG. 115, “M1” indicates a maximum polarization value, whereas “N1” represents a minimum polarization value. Additionally, “P1” means a difference between the maximum polarization value M1 and the minimum polarization value N1.

Referring to FIG. 115, when a maximum applied voltage was about 2.0 V, the ferroelectric capacitor of Comparative Example 9 had the maximum polarization value M1 of about 59.2 μC/cm², and the minimum polarization value N1 of about 17.8° C./cm². Thus, the difference P1 between the maximum polarization value M1 and the minimum polarization value N1 was about 41.4 μC/cm².

FIG. 116 is a graph illustrating a polarization of the ferroelectric capacitor relative to an applied voltage in accordance with Comparative Example 10. In FIG. 116, “M2” indicates a maximum polarization value, whereas “N2” represents a minimum polarization value. “P2” means a difference between the maximum polarization value M2 and the minimum polarization value N2.

Referring to FIG. 116, when a maximum applied voltage was about 2.0V, the ferroelectric capacitor of Comparative Example 10 had the maximum polarization value M2 of about 66.3 μC/cm², and the minimum polarization value N2 of about 18.1 μC/cm². The difference P2 between the maximum polarization value M2 and the minimum polarization value N2 was about 48.2 μC/cm².

FIG. 117 is a graph illustrating a polarization of the ferroelectric capacitor relative to an applied voltage in accordance with Example 37. In FIG. 117, “M3” indicates a maximum polarization value, whereas “N3” represents a minimum polarization value. “P3” means a difference between the maximum polarization value M3 and the minimum polarization value N3.

Referring to FIG. 117, when a maximum applied voltage was about 2.0 V, the ferroelectric capacitor of Example 37 had the maximum polarization value M3 of about 68.5 μC/cm², and the minimum polarization value N3 of about 0.1 μC/cm². The difference P3 between the maximum polarization value M3 and the minimum polarization value N3 was about 68.4 μC/cm².

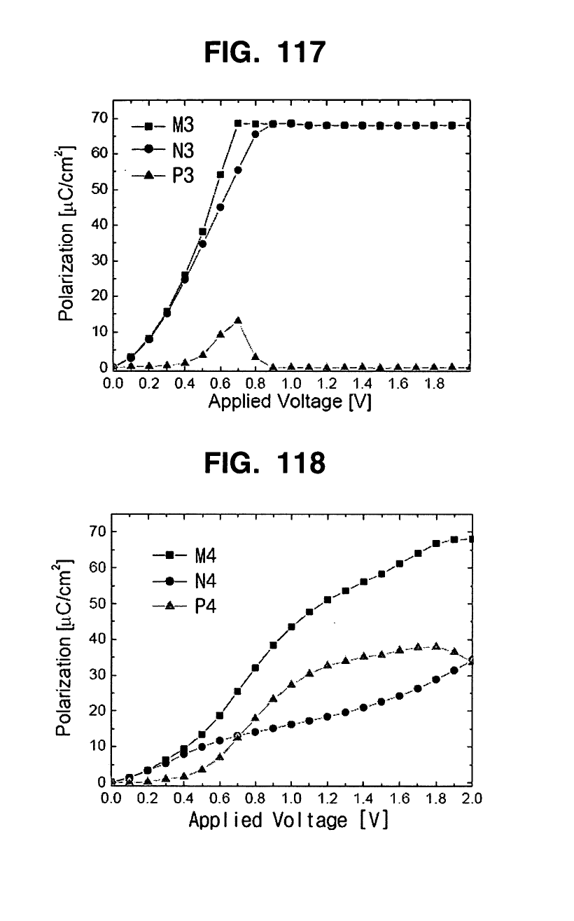

FIG. 118 is a graph illustrating a polarization of the ferroelectric capacitor relative to an applied voltage in accordance with Example 38. In FIG. 118, “M4” indicates a maximum polarization value, whereas “N4” represents a minimum polarization value. “P4” means a difference between the maximum polarization value M4 and the minimum polarization value N4.

Referring to FIG. 118, when a maximum applied voltage was about 2.0V, the ferroelectric capacitor of Example 38 had the maximum polarization value M4 of about 67.6 μC/cm², and the minimum polarization value N4 of about 33.9 μC/cm². The difference P4 between the maximum polarization value M4 and the minimum polarization value N4 was about 33.7 μC/cm².

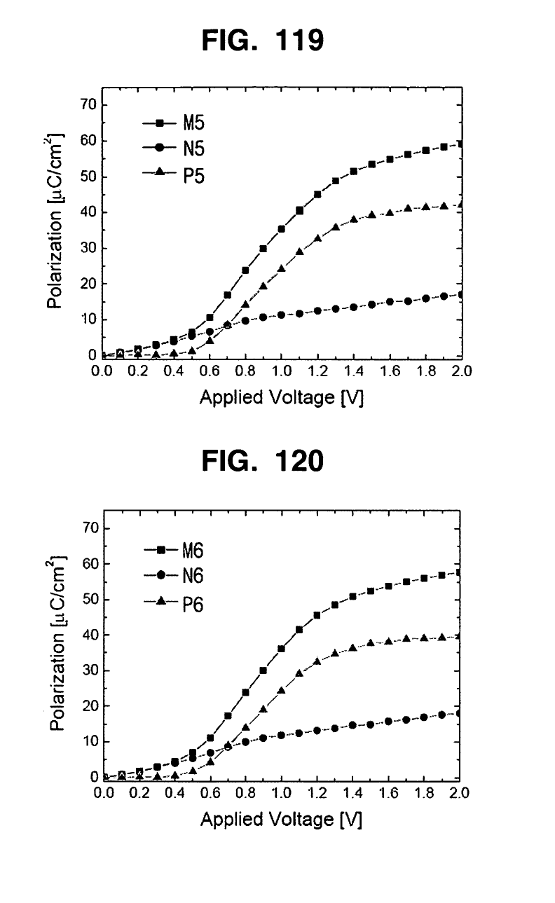

FIG. 119 is a graph illustrating a polarization of the ferroelectric capacitor relative to an applied voltage in accordance with Example 40. In FIG. 119, “M5” indicates a maximum polarization value, whereas “N5” represents a minimum polarization value. “P5” means a difference between the maximum polarization value M5 and the minimum polarization value N5.

Referring to FIG. 119, when a maximum applied voltage was about 2.0V, the ferroelectric capacitor of Example 40 had the maximum polarization value M5 of about 59.7 μC/Cm², and the minimum polarization value N5 of about 17.5° C./cm². The difference P5 between the maximum polarization value M5 and the minimum polarization value N5 was about 42.2 μC/cm².

FIG. 120 is a graph illustrating a polarization of the ferroelectric capacitor relative to an applied voltage in accordance with Example 41. In FIG. 120, “M6” indicates a maximum polarization value, whereas “N6” represents a minimum polarization value. “P6” means a difference between the maximum polarization value M6 and the minimum polarization value N6.

Referring to FIG. 120, when a maximum applied voltage was about 2.0 V, the ferroelectric capacitor of Example 41 had the maximum polarization value M6 of about 58.1 μC/cm², and the minimum polarization value N6 of about 18.2 μC/cm². The difference P6 between the maximum polarization value M6 and the minimum polarization value N6 was about 39.9 μC/cm².

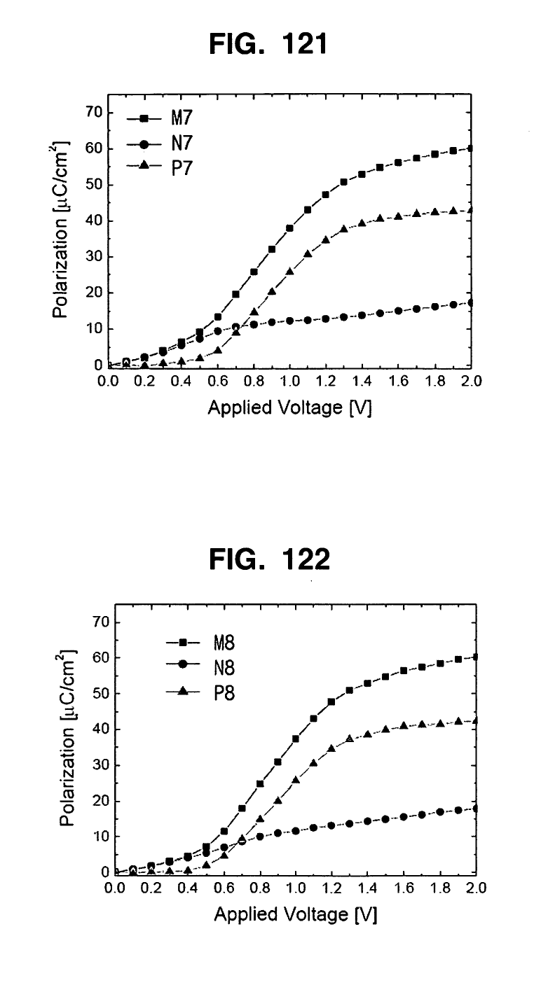

FIG. 121 is a graph illustrating a polarization of the ferroelectric capacitor relative to an applied voltage in accordance with Example 43. In FIG. 121, “M7” indicates a maximum polarization value, whereas “N7” represents a minimum polarization value. “P7” means a difference between the maximum polarization value M7 and the minimum polarization value N7.

Referring to FIG. 121, when a maximum applied voltage was about 2.0 V, the ferroelectric capacitor of Example 43 had the maximum polarization value M7 of about 59.6 μC/cm², and the minimum polarization value N7 of about 17.3 μC/cm². The difference P7 between the maximum polarization value M7 and the minimum polarization value N7 was about 42.3 μC/cm².

FIG. 122 is a graph illustrating a polarization of the ferroelectric capacitor relative to an applied voltage in accordance with Example 44. In FIG. 122, “M8” indicates a maximum polarization value, whereas “N8” represents a minimum polarization value. “P8” means a difference between the maximum polarization value M8 and the minimum polarization value N8.

Referring to FIG. 122, when a maximum applied voltage was about 2.0 V, the ferroelectric capacitor of Example 44 had the maximum polarization value M8 of about 59.8 μC/cm², and the minimum polarization value N8 of about 17.7 μC/cm². The difference P8 between the maximum polarization value M8 and the minimum polarization value N8 was about 42.1 μC/cm².

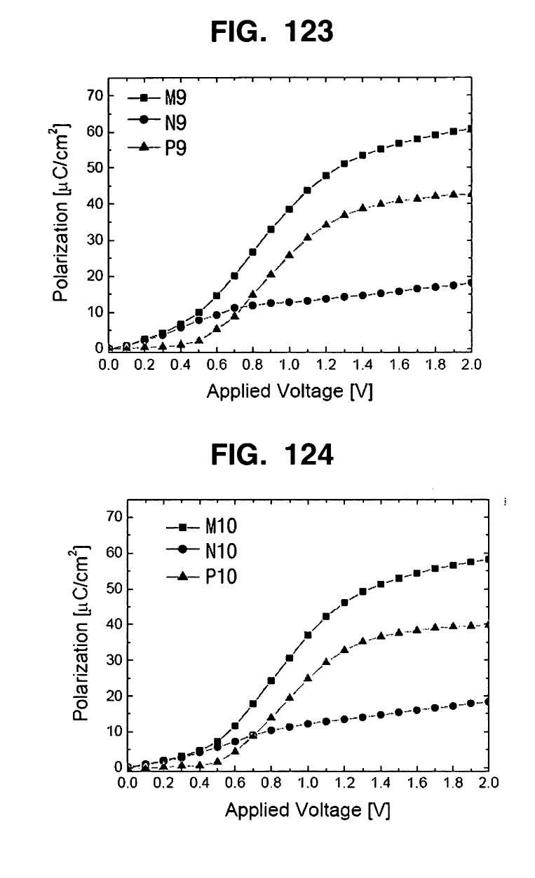

FIG. 123 is a graph illustrating a polarization of the ferroelectric capacitor relative to an applied voltage in accordance with Example 46. In FIG. 123, “M9” indicates a maximum polarization value, whereas “N9” represents a minimum polarization value. “P9” means a difference between the maximum polarization value M9 and the minimum polarization value N9.

Referring to FIG. 123, when a maximum applied voltage was about 2.0 V, the ferroelectric capacitor of Example 46 had the maximum polarization value M9 of about 61.6 μC/cm², and the minimum polarization value N9 of about 18.7 μC/cm². The difference P9 between the maximum polarization value M9 and the minimum polarization value N9 was about 42.9 μC/cm².

FIG. 124 is a graph illustrating a polarization of the ferroelectric capacitor relative to an applied voltage in accordance with Example 47. In FIG. 124, “M10” indicates a maximum polarization value, whereas “N10” represents a minimum polarization value. “P10” means a difference between the maximum polarization value M10 and the minimum polarization value N10.

Referring to FIG. 124, when a maximum applied voltage was about 2.0 V, the ferroelectric capacitor of Example 47 had the maximum polarization value M10 of about 58.3° C./cm², and the minimum polarization value N10 of about 18.8 μC/cm². The difference P10 between the maximum polarization value M10 and the minimum polarization value N10 was about 39.5 μC/cm².

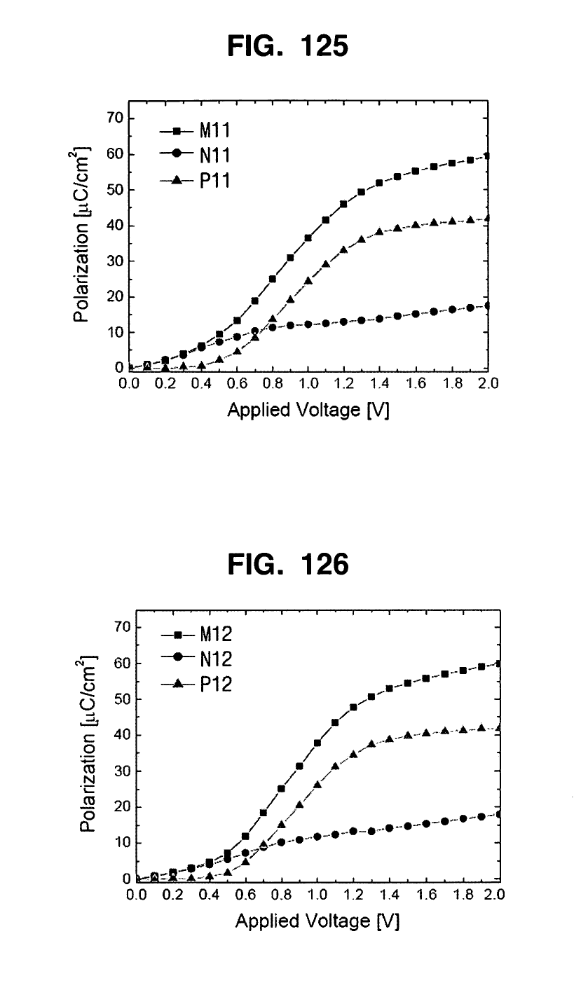

FIG. 125 is a graph illustrating a polarization of the ferroelectric capacitor relative to an applied voltage in accordance with Example 49. In FIG. 125, “M11” indicates a maximum polarization value, whereas “N11” represents a minimum polarization value. “P11” means a difference between the maximum polarization value M11 and the minimum polarization value N11.

Referring to FIG. 125, when a maximum applied voltage was about 2.0 V, the ferroelectric capacitor of Example 49 had the maximum polarization value M11 of about 59.1 μC/cm², and the minimum polarization value N11 of about 17.4 μC/cm². The difference P11 between the maximum polarization value M11 and the minimum polarization value N11 was about 41.7 μC/cm².

FIG. 126 is a graph illustrating a polarization of the ferroelectric capacitor relative to an applied voltage in accordance with Example 50. In FIG. 126, “M12” indicates a maximum polarization value, whereas “N12” represents a minimum polarization value. “P12” means a difference between the maximum polarization value M12 and the minimum polarization value N12.

Referring to FIG. 126, when a maximum applied voltage was about 2.0 V, the ferroelectric capacitor of Example 50 had the maximum polarization value M12 of about 59.7 μC/cm², and the minimum polarization value N12 of about 17.9 μC/Cm². The difference P12 between the maximum polarization value M12 and the minimum polarization value N12 was about 41.8 μC/cm².

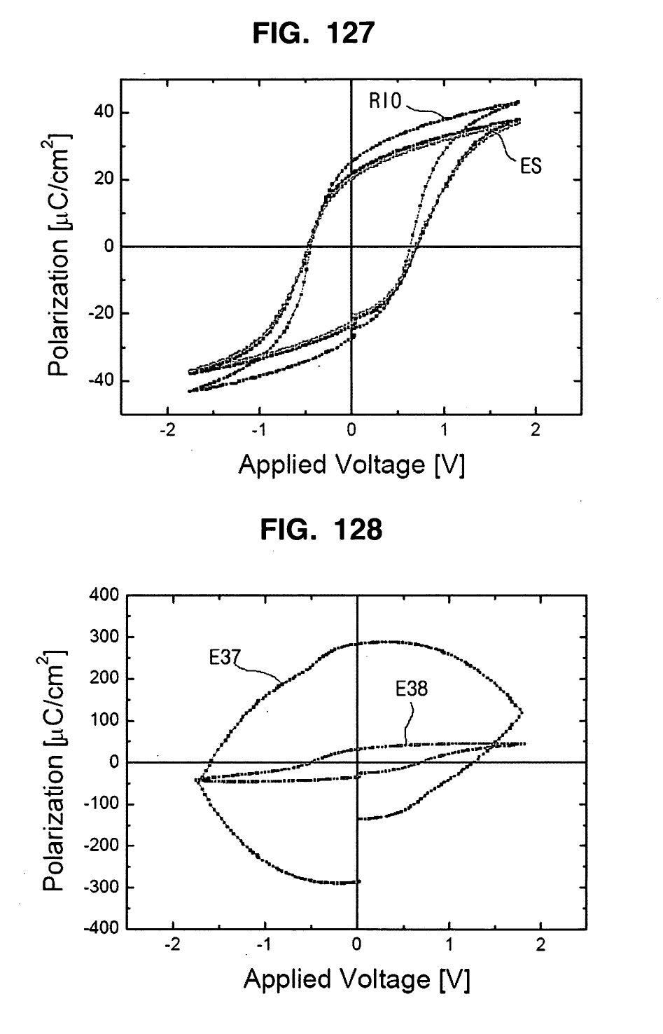

FIG. 127 is a graph illustrating P-V hysteresis loops of the ferroelectric capacitors in accordance with Comparative Example 10, and Examples 38, 44, 47 and 50. In FIG. 127, the polarizations of the ferroelectric capacitors were measured with respect to applied voltages. In FIG. 127, “R10” indicates the P-V hysteresis loop of the ferroelectric capacitor of Comparative Example 10, and “ES” represents the P-V hysteresis loops of the ferroelectric capacitors of Examples 38, 44, 47 and 50.

Referring to FIG. 127, the ferroelectric capacitor R10 of the Comparative Example 10 had a 2Pr value substantially larger than those of the ferroelectric capacitors ES of Examples 38, 44, 47 and 50. However, since the ferroelectric capacitor R10 of the Comparative Example 10 had dielectric characteristics rather than ferroelectric characteristics, the ferroelectric capacitor R10 of the Comparative Example 10 showed the high 2Pr value. The dielectric characteristics of the ferroelectric capacitor R10 of the Comparative Example 10 were identified as that of lead-based material that was contained in the ferroelectric capacitor R10 of the Comparative Example 10, and was removed from the ferroelectric capacitor R10 of the Comparative Example 10 after the thermal treatment process. However, the ferroelectric capacitor R10 of the Comparative Example 10 had greatly deteriorated leakage current density after the thermal treatment process was performed on the ferroelectric capacitor R10 of the Comparative Example 10.

FIG. 128 is a graph illustrating P-V hysteresis loops of the ferroelectric capacitors in accordance with Examples 37 and 38. In FIG. 128, the polarizations of the ferroelectric capacitors were measured with respect to applied voltages. In FIG. 128, “E37” indicates the P-V hysteresis loop of the ferroelectric capacitor of Example 37, and “E38” represents the P-V hysteresis loops of the ferroelectric capacitors of Example 38.

Referring to FIG. 128, the ferroelectric capacitor E37 of Example 37 did not show a normal P-V hysteresis loop when the thin ferroelectric layer was cleaned using the SMF solution. The ferroelectric capacitor E38 of Example 38 had a relatively normal P-V hysteresis loop after the thermal treatment process; however, the ferroelectric capacitor E38 of Example 38 showed a poor leakage current density.

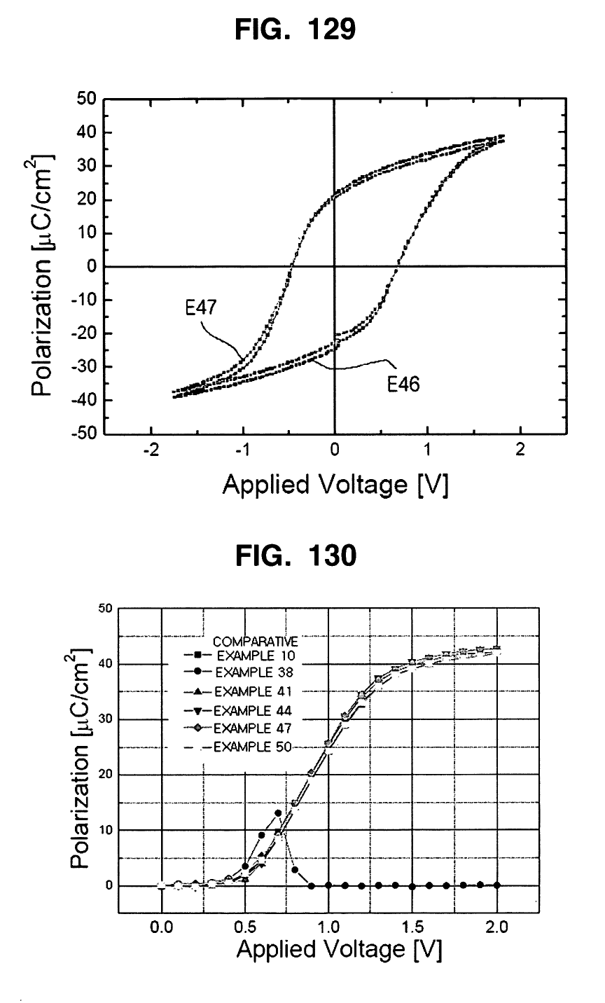

FIG. 129 is a graph illustrating P-V hysteresis loops of the ferroelectric capacitors in accordance with Examples 46 and 47. In FIG. 129, the polarizations of the ferroelectric capacitors were measured with respect to applied voltages. In FIG. 129, “E46” indicates the P-V hysteresis loop of the ferroelectric capacitor of Example 46, and “E47” represents the P-V hysteresis loops of the ferroelectric capacitors of Example 47.

Referring to FIG. 129, the thermally treated ferroelectric capacitor E47 had a 2Pr value substantially lower than that of the ferroelectric capacitor E46 formed without the thermal treatment by about 1 to about 2 μC/cm². However, the ferroelectric capacitor E47 of Example 47 had a leakage current density smaller than that of the ferroelectric capacitor E46 of Example 46.

FIG. 130 is a graph illustrating polarizations of the ferroelectric capacitors relative to applied voltages in accordance with Comparative Example 10 and Examples 38, 41, 44, 47 and 50. In FIG. 130, “▪” represents the polarization of the ferroelectric capacitor of Comparative Example 10, and “●” indicates the polarization of the ferroelectric capacitor of Example 38. Additionally, “▴” means the polarization of the ferroelectric capacitor of Example 41, and “▾” indicates the polarization of the ferroelectric capacitor of Example 44. Furthermore, “⋄” indicates the polarization of the ferroelectric capacitor of Example 47, and “∘” represents the polarization of the ferroelectric capacitor of Example 50.

Referring to FIG. 130, the ferroelectric capacitors of Examples 41, 44, 47 and 50 had the polarizations substantially identical to the polarization of the ferroelectric capacitor of Comparative Example 10 except for the ferroelectric capacitor of Example 38 formed through the cleaning process using the SMF solution.

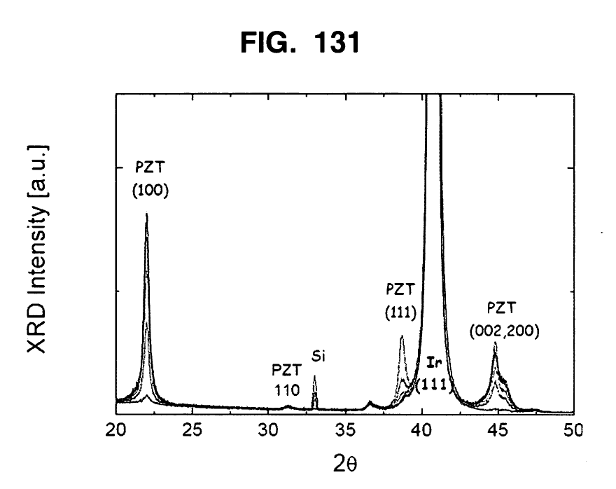

FIG. 131 is a graph illustrating contents of ingredients in the thin ferroelectric layers in accordance with Comparative Example 10, and Examples 38, 41, 44, 47 and 50. In FIG. 131, the contents of ingredients in the thin ferroelectric layers of Comparative Example 10, and Examples 38, 41, 44, 47 and 50 were measured using an X-ray diffractometer (XRD), and peaks of the ingredients in the thin ferroelectric layers of Comparative Example 10, and Examples 38, 41, 44, 47 and 50 were superimposed on one another to easily compare the contents of the ingredients.

Referring to FIG. 131, the ingredients of silicon, iridium and PZT in the thin ferroelectric layer of Comparative Example 10 had the contents substantially similar to those of the ingredients of silicon, iridium and PZT in the thin ferroelectric layers of Examples 38, 41, 44, 47 and 50. That is, the ingredients in the thin ferroelectric layers without the cleaning process had the contents substantially similar to those of the ingredients in the thin ferroelectric layers cleaned using the SMF solution, the SMC solution, the ammonia solution, the nitric acid solution and the SC1 solution. Therefore, the cleaning process did not affect the contents of the ingredients contained in the thin ferroelectric layers.

Method of Manufacturing a Semiconductor Device having a Thin Ferroelectric Layer

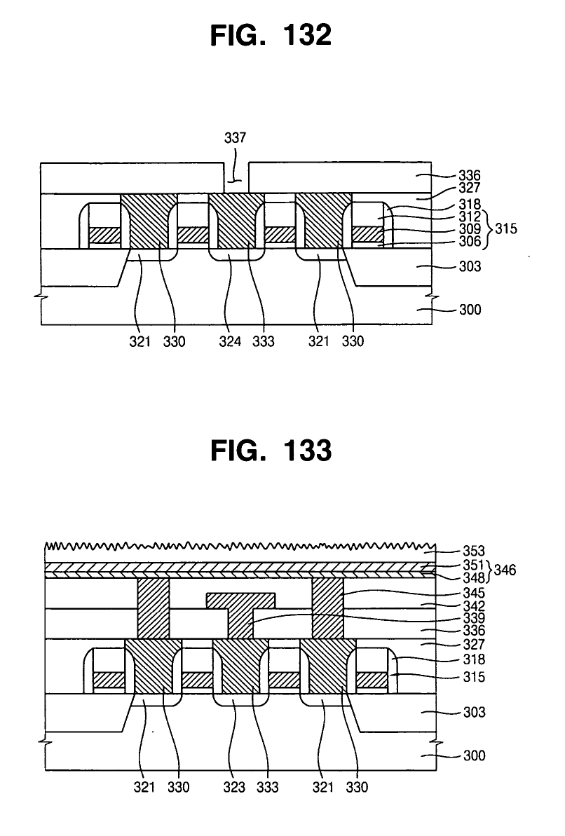

FIGS. 132 to 136 are cross-sectional views illustrating a semiconductor device including a thin ferroelectric layer in accordance with an example embodiment of the present invention.

Referring to FIG. 132, an isolation layer 303 is formed on a semiconductor substrate 300 to define an active region and a field region. The isolation layer 303 may be formed an isolation process such as a shallow trench isolation (STI) process.

A thin gate oxide layer is formed on the active region of the semiconductor substrate 300. The thin gate oxide layer may be formed on the substrate 300 by a thermal oxidation process or a CVD process.

A first conductive layer and a first mask layer are sequentially formed on the thin gate oxide layer. The first conductive layer may be formed using polysilicon doped with impurities. Alternatively, the first conductive layer may have a polycide structure that includes doped polysilicon and metal silicide. The first mask layer may be formed using a material that has an etching selectivity relative to that of a first insulating interlayer 327. For example, the first mask layer is formed using a nitride such as silicon nitride when the first insulating interlayer 327 is formed using an oxide.

After a first photoresist pattern (not shown) is formed on the first mask layer, the first mask layer, the first conductive layer and the thin gate oxide layer are etched using the first photoresist pattern as an etching mask. Hence, gate structures 315 are formed on the semiconductor substrate 300. The gate structures 315 include gate oxide layer patterns 306, gate conductive patterns 309 and gate mask patterns 312.

In one example embodiment of the present invention, after the first photoresist pattern is formed on the first mask layer, the first mask layer is etched to thereby form the gate mask pattern 312 on the first conductive layer. The first photoresist pattern is removed by an ashing process and/or a stripping process, and then the first conductive layer and the thin gate oxide layer are sequentially etched using the gate mask pattern 312 as an etching mask to thereby form the gate conductive pattern 309 and the gate oxide layer pattern 306.

After a first insulation layer is formed on the substrate 300 to cover the gate structures 315, the first insulation layer is anisotropically etched to form gate spacers 318 on sidewalls of the gate structures 315. The first insulation layer may be formed using a nitride such as silicon nitride.

Impurities are implanted into portions of the semiconductor substrate 300 exposed by the gate structures 315 using the gate structures 315 and the gate spacers 318 as ion implantation masks. Therefore, a first contact region 321 and a second contact region 324 are formed at the exposed portions of the semiconductor substrate 300. The first and the second contact regions 321 and 324 may correspond to source/drain regions, respectively. The first and the second contact regions 321 and 324 are divided into a capacitor contact region and a bit line contact region, respectively. A ferroelectric capacitor 384 (see FIG. 135) is electrically connected to the capacitor contact region, and a bit line 339 (see FIG. 133) is electrically connected to the bit line contact region. For example, the first contact region 321 corresponds to the capacitor contact region, and the second contact region 324 corresponds to the bit line contact region. When the first and the second contact regions 321 and 324 are formed, transistors including the gate structures 315 and the contact regions 321 and 324 are completed on the semiconductor substrate 300.

Referring now to FIG. 132, the first insulating interlayer 327 is formed on the semiconductor substrate 300 to cover the transistors including the gate structures 315. The first insulating interlayer 327 may be formed using an oxide such as BPSG, PSG, SOG, PE-TEOS, USG, HDP-CVD oxide, etc. The first insulating interlayer 327 may be formed on the semiconductor substrate 300 by a CVD process, PECVD process, an HDP-CVD process, an ALD process, etc.

An upper portion of the first insulating interlayer 327 is removed by a CMP process, an etch back process or a combination process of CMP and etch back, thereby planarizing the first insulating interlayer 327. The first insulating interlayer 327 may have an upper face slightly higher than that of the gate mask pattern 318. Alternatively, the first insulating interlayer 327 may be planarized until the gate mask pattern 318 is exposed so that the first insulating interlayer 327 may have an upper face substantially equal to that of the gate mask pattern 312.

After a second photoresist pattern (not shown) is formed on the first insulating interlayer 327, portions of the first insulating interlayer 327 are anisotropically etched to form first contact holes that expose the first and the second contact regions 321 and 324, respectively. When the first insulating interlayer 327 includes the oxide, the first insulating interlayer 327 may be partially etched using an etching gas that has an etching selectivity relative to the gate mask pattern 312 and the gate spacer 318. Therefore, the first contact holes are self-aligned relative to the gate spacer 318 and the gate mask pattern 312. Some first contact holes may expose the first contact regions 321, and another first contact hole may expose the second contact region 324.

After removing the second photoresist pattern by an ashing process and/or a stripping process, a second conductive layer is formed on the first insulating interlayer 327 to fill up the first contact holes. The second conductive layer may be formed using doped polysilicon, a metal or a conductive metal nitride. For example, the second conductive layer is formed using tungsten, aluminum, titanium, copper, tungsten nitride, titanium nitride, aluminum nitride, titanium aluminum nitride, etc.

The second conductive layer are partially removed by a CMP process, an etch back process or a combination process of CMP and etch back until the first insulating interlayer 327 is exposed. Therefore, a first pad 330 and a second pad 333 are formed in the first contact holes. Since the first contact holes are formed through the self-alignment process, the first and the second pads 330 and 333 also may correspond to self-aligned contact (SAC) pads, respectively. The first pad 330 makes contact with the first contact region 321, and the second pad 333 makes contact with the second contact region 324. For example, the first pad 330 is positioned on the capacitor contact region, and the second pad 333 is formed on the bit line contact region.

In one example embodiment of the present invention, when the first insulation interlayer 327 is planarized until the gate mask pattern 312 is exposed, the second conductive layer is partially removed until the gate mask pattern 312 is exposed to thereby form the first and the second pads 330 and 333. Hence, the first and the second pads 330 and 333 may have a height substantially identical to that of the gate mask pattern 312.

A second insulating interlayer 336 is formed on the first insulating interlayer 327, the first pad 330 and the second pad 333. The second insulating interlayer 336 electrically insulates the first pad 330 from the bit line 339. The second insulating interlayer 336 may be formed using an oxide such as BPSG, PSG, SOG, PE-TEOS, USG, HDP-CVD oxide, etc. The second insulating interlayer 336 may be formed by a CVD process, a PECVD process, an HDP-CVD process, an ALD process, etc. In one example embodiment of the present invention, the second insulating interlayer 336 may be formed using the oxide substantially identical to that of the first insulating interlayer 327. In another example embodiment of the present invention, the second insulating interlayer 336 may be formed using the oxide substantially different from that of the first insulating interlayer 327.

An upper portion of the second insulating interlayer 336 may be planarized by a CMP process, an etch back process or a combination process of CMP and etch back.

After a third photoresist pattern (not shown) is formed on the second insulating interlayer 336, the second insulating interlayer 336 is partially etched using the third photoresist pattern as an etching mask. Thus, a second contact hole 337 is formed through the second insulating interlayer 336. The second contact hole 337 exposes the second pad 333 buried in the first insulating interlayer 327.

Referring to FIG. 133, after the third photoresist pattern is removed by an ashing process and/or a stripping process, a third conductive layer is formed on the second insulating interlayer 336 to fill up the second contact hole 337. The third conductive layer may be formed using doped polysilicon or a metal such as tungsten, aluminum, titanium, copper, etc.

After a fourth photoresist pattern is formed on the third conductive layer, the third conductive layer is etched using the fourth photoresist pattern as an etching mask, thereby forming the bit line 339 filling the second contact hole 337 on the second insulating interlayer 336. The bit line 339 may include a first film of metal/metal nitride and a second film of metal. For example, the first film includes titanium/titanium nitride, and the second film includes tungsten.

A third insulating interlayer 342 is formed on the second insulating interlayer 336 to cover the bit line 339. The third insulating interlayer 342 may be formed by a CVD process, a PECVD process, an HDP-CVD process or an ALD process. The third insulating interlayer 342 may be formed using an oxide such as BPSG, PSG, SOG, PE-TEOS, USG, HDP-CVD oxide, etc. As described above, the third insulating interlayer 342 may be formed using the oxide substantially identical to that of the first insulating interlayer 327 and/or the second insulating interlayer 336. Alternatively, the third insulating interlayer 342 may be formed using the oxide substantially different from that of the first insulating interlayer 327 and/or the second insulating interlayer 336. For example, the third insulating interlayer 342 is formed using HDP-CVD oxide because HDP-CVD oxide may be deposited at a relatively low temperature and also a gap or a hole may be completely filled with HDP-CVD oxide without a void or a seam therein.

In one embodiment of the present invention, an additional insulation layer may be formed on the bit line 339 and the second insulating interlayer 336 in order to prevent a void or a seam from generating at a portion of the third insulating interlayer 342 between adjacent bit lines 339. The additional insulation layer may be formed using a nitride such as silicon nitride. Then, the third insulating interlayer 342 may be formed on the additional insulation layer.

The third insulating interlayer 342 may be planarized by a CMP process, an etch back process or a combination process of CMP and etch back.

After a fifth photoresist pattern (not shown) is formed on the third insulating interlayer 342, the third insulating interlayer 342 and the second insulating interlayer 336 are partially etched using the fifth photoresist pattern as an etching mask. Thus, third contact holes 343 exposing the first pads 330 are formed through the third insulating interlayer 342 and the second insulating interlayer 336.

In one example embodiment of the present invention, a cleaning process may be performed to remove a native oxide film or particles from the first pads 330 after the third contact holes 343 are formed.

After a fourth conductive layer is formed on the third insulating interlayer 342 to fill up the third contact holes 343, the fourth conductive layer is partially removed by a CMP process, an etch back process or a combination process of CMP and etch back until the third insulating interlayer 342 is exposed. Thus, third pads 345 are formed in the third contact holes 343, respectively. Each of the third pads 345 may be formed using doped polysilicon or a metal such as tungsten, aluminum, copper, titanium, etc. The third pad 345 electrically connects the first pad 330 to a lower electrode 369 of the ferroelectric capacitor 384 (see FIG. 135). That is, the lower electrode 369 is electrically contacted to the first contact region 321 through the third pad 345 and the first pad 330.

A lower electrode layer 346 is formed on the third pads 345 and the third insulating interlayer 342. The lower electrode layer 346 includes a first lower electrode film 348 and a second lower electrode film 351 sequentially formed on the third pads 345 and the third insulating interlayer 342. The first lower electrode film 348 may have a thickness of about 50 Å to about 300 Å, and the second lower electrode film 351 may have a thickness of about 300 Å to about 1,200 Å. The first lower electrode film 348 may be formed using a conductive metal nitride by a CVD process, a sputtering process or an ALD process. The second lower electrode film 351 may be formed using a first metal by a sputtering process, a CVD process, a PLD process or an ALD process. The second lower electrode film 351 may be formed on the first lower electrode film 348 at a temperature of about 20° C. o about 350° C. and a pressure of about 3 mTorr to about 10 mTorr while applying a power of about 300 W to about 1,000 W under an inactive gas atmosphere.

A preliminary ferroelectric layer 353 is formed on the second lower electrode film 351 to have a thickness of about 200 Å to about 1,500 Å. The preliminary ferroelectric layer 353 may be formed by an MOCVD process, a sol-gel process or an ALD process. The preliminary ferroelectric layer 353 may be formed using a ferroelectric material, a ferroelectric material doped with a metal, a metal oxide, etc.

In one example embodiment of the present invention, a third lower electrode film (not shown) may be formed between the second lower electrode layer 351 and the preliminary ferroelectric layer 353. The third lower electrode film may have a thickness of about 10 Å to about 500 Å. The third lower electrode film may be formed using a metal oxide doped with a metal. For example, the third lower electrode film is formed using SRO, STO, LNO or CRO doped with copper, lead or bismuth. The third lower electrode film may be formed on the second lower electrode film 351 at a temperature of about 20° C. to about 600° C. and a pressure of about 3 mTorr to about 10 mTorr while applying a power of about 300 W to about 1,000 W under an inactive gas atmosphere.

As described above, the preliminary ferroelectric layer 353 is polished by a surface polishing process such as a CMP process. In the CMP process, a pressure of a carrier pressing the semiconductor substrate 330 onto a polishing pad (that is, a downward pressure) may be in a range of about 0.5 psi to about 3.0 psi. Additionally, a rotation speed of the polishing pad may be in a range of about 2 rpm to about 25 rpm. The surface of the preliminary ferroelectric layer 353 may be polished using a slurry that includes an abrasive containing acidic silica, basic silica, ceria, alumina, titania, etc.

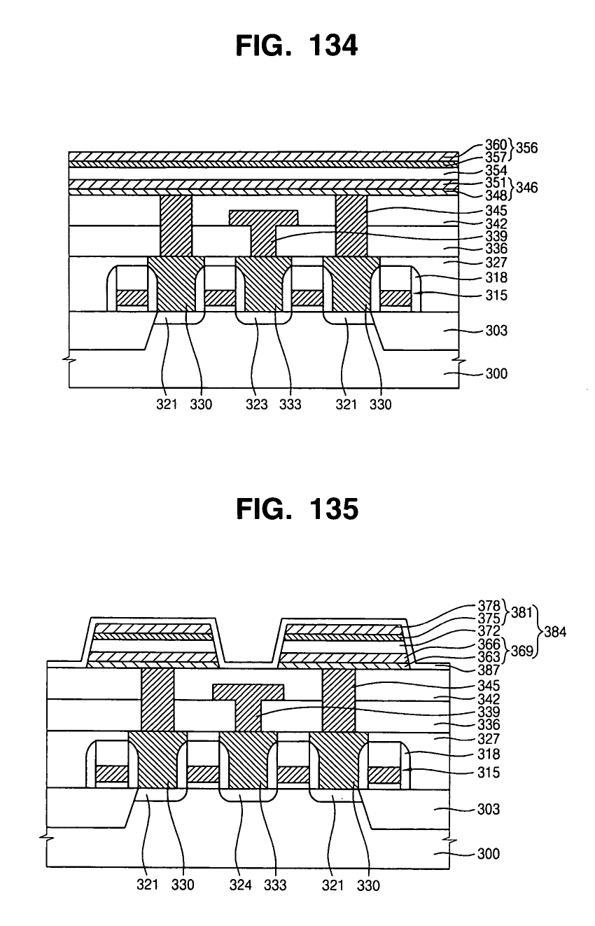

Referring to FIG. 134, a thin ferroelectric layer 354 is formed on the second lower electrode film 351. After polishing the preliminary ferroelectric layer 353, the thin ferroelectric layer 354 may have a thickness of about 200 Å to about 1,000 Å.

The thin ferroelectric layer 354 is cleaned to remove slurry residues and polishing residues from a surface of the thin ferroelectric layer 354. The thin ferroelectric layer 354 may be cleaned for about 30 seconds to about 90 seconds. The thin ferroelectric layer 354 may be cleaned using a cleaning solution that includes an SMX solution, an SMF solution, an SC1 solution, an ammonia solution or nitric solution. Alternatively the thin ferroelectric layer 354 may be cleaned using deionized water. When the preliminary ferroelectric layer 353 is polished, the surface of the thin ferroelectric layer 354 may be damaged. In the cleaning process, the damage to the surface of the thin ferroelectric layer 354 may be cured because the surface of the thin ferroelectric layer 354 may be slightly etched.

The thin ferroelectric layer 354 is thermally treated to completely cure the damage to the surface of the thin ferroelectric layer 354. This curing process may be performed at a temperature of about 500° C. to about 600° C. for about 30 to about 90 seconds. The surface of the thin ferroelectric layer 354 may be cured by an RTP under an inactive gas atmosphere such as a nitrogen gas, a helium gas, an argon gas, a xenon gas, etc.

An upper electrode layer 356 is formed on the thin ferroelectric layer 354. The upper electrode layer 356 includes a first upper electrode film 357 and a second upper electrode film 360 sequentially formed on the thin ferroelectric layer 354. The first upper electrode film 357 may have a thickness of about 10 Å to about 300 Å. The first upper electrode film 357 may be formed using a metal oxide doped with a metal by a sputtering process, a CVD process, a PLD process, an ALD process, etc. For example, the first upper electrode film 357 is formed using SRO, STO, LNO or CRO doped with copper, lead or bismuth. The first upper electrode film 357 may be formed at a temperature of about 20° C. to about 350° C. and a pressure of about 3 mTorr to about 10 mTorr while applying a power of about 300 W to about 1,000 W under an inactive gas atmosphere.

The second upper electrode film 360 may have a thickness of about 300 Å to about 1,000 Å. The second upper electrode film 360 may be formed using iridium, platinum, palladium, ruthenium, gold, etc. The second upper electrode film 360 may be formed by a sputtering process, a CVD process, an ALD process or a PLD process. The second upper electrode film 360 may be formed at a temperature of about 20° C. to about 350° C. and a pressure of about 3 to about 10 mTorr while applying a power of about 300 W to about 1,000 W under an inactive gas atmosphere.

After forming the upper electrode layer 356, the semiconductor substrate 300 having the thin ferroelectric layer 354 and the upper electrode layer 356 is thermally treated under an oxygen atmosphere, a nitrogen atmosphere or a mixture atmosphere including oxygen or nitrogen. The thin ferroelectric layer 354 and the upper electrode layer 356 may be thermally treated by an RTP at a temperature of about 500° C. to about 650° C. for about 30 seconds to about 3 minutes.

Referring to FIG. 135, a sixth photoresist pattern (not shown) is formed on the upper electrode layer 356. Using the sixth photoresist pattern as an etching mask, the second upper electrode film 360, the first upper electrode film 357, the thin ferroelectric layer 354, the second lower electrode film 351 and the first lower electrode film 348 are sequentially etched. Therefore, the ferroelectric capacitor 384 including the lower electrode 369, a thin ferroelectric layer pattern 372 and an upper electrode 381 is formed over the semiconductor substrate 300. The lower electrode 369 includes a first lower electrode film pattern 363 and a second lower electrode film pattern 366 successively formed on the third pads 345 and the third insulating interlayer 342. The upper electrode 381 includes a first upper electrode film pattern 375 and a second upper electrode film pattern 378 sequentially formed on the thin ferroelectric layer pattern 372. The ferroelectric capacitor 384 may have a sidewall substantially inclined by an angle of about 50° to about 90° relative to a horizontal direction.

A barrier layer 387 is formed on the third insulating interlayer 342 to cover the ferroelectric capacitor 384. The barrier layer 387 may be formed using a metal oxide or a metal nitride. For example, the barrier layer 387 is formed using aluminum oxide, titanium nitride or silicon nitride. The barrier layer 387 may be formed by a CVD process, a sputtering process, a PLD process, an ALD process, etc. The barrier layer 387 may prevent hydrogen atoms from diffusing into the thin ferroelectric layer pattern 372 so that the barrier layer 387 may improve electrical characteristics of the thin ferroelectric layer pattern 372. However, the barrier layer 387 may be omitted as occasion demands.

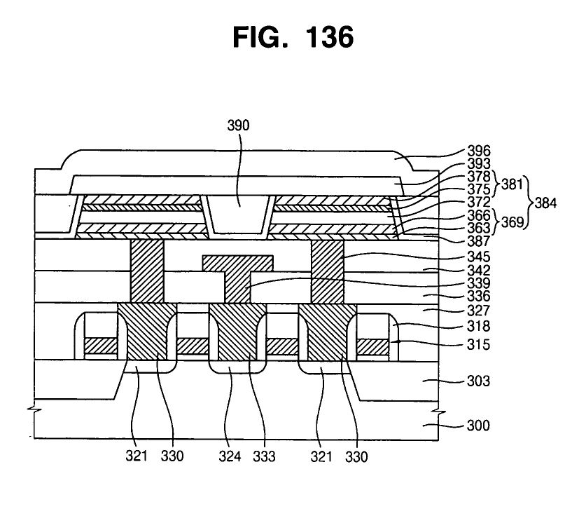

Referring to FIG. 136, a fourth insulating interlayer 390 is formed on the barrier layer 387. The fourth insulating interlayer 390 may be formed using an oxide such as BPSG, PSG, SOG, PE-TEOS, USG, HDP-CVD oxide, etc. The fourth insulating interlayer 390 may be formed on the barrier layer 387 by a CVD process, a PECVD process, an HDP-CVD process, an ALD process, etc.

The fourth insulating interlayer 390 and the barrier layer 387 are partially removed by a CMP process, an etch back process or a combination process of CMP and etch back until the upper electrode 381 is exposed.

A fifth conductive layer is formed on the exposed upper electrode 381 and the fourth insulating interlayer 390 by a CVD process, a sputtering process, a PLD process or an ALD process. The fifth conductive layer may be formed using a metal, a conductive metal oxide or a conductive metal nitride. For example, the fifth conductive layer is formed using titanium aluminum nitride, aluminum, titanium, titanium nitride, iridium, iridium oxide, platinum, ruthenium, ruthenium oxide, etc.

After a seventh photoresist pattern (not shown) is formed on the fifth conductive layer, the fifth conductive layer is etched using the seventh photoresist pattern as an etching mask, thereby forming a plate line 393 that makes contact with the upper electrode 381. The plate line 393 commonly contacts adjacent upper electrodes 381 of adjacent ferroelectric capacitors 384.

A fifth insulating interlayer 396 is formed on the plate line 393 and the fourth insulating interlayer 390. The fifth insulating interlayer 396 may be formed using an oxide such as BPSG, PSG, SOG, PE-TEOS, USG, HDP-CVD oxide, etc. The fifth insulating interlayer 396 may be formed by a CVD process, a PECVD process, an HDP-CVD process, an ALD process, etc.

A sixth conductive layer is formed on the fifth insulating interlayer 396 using a metal or a conductive metal nitride. For example, the sixth conductive layer is formed using aluminum, titanium, titanium nitride, titanium aluminum nitride, etc. The sixth conductive layer may be formed by a sputtering process, an ALD process, a PLD process, a CVD process, etc.

After an eighth photoresist pattern (not shown) is formed on the sixth conductive layer, the sixth conductive layer is etched using the eighth photoresist pattern as an etching mask, thereby forming an upper wiring (not shown) on the fifth insulating interlayer 396. As a result, the semiconductor device including the ferroelectric capacitor 384 is formed on the semiconductor substrate 300.

According to the present invention, a preliminary ferroelectric layer may be polished by a CMP process under properly adjusted process conditions so that a thin ferroelectric layer may have a very level surface and a uniform thin thickness. Thus, the thin ferroelectric layer may have greatly improved ferroelectric and electrical characteristics such as more enhanced polarization or data retention, less leakage current density, etc. Additionally, slurry residues and polishing residues remaining on a surface of the thin ferroelectric layer may be effectively removed using an advantageous cleaning solution. Furthermore, the damage to the thin ferroelectric layer generated in the CMP process may be completely cured by cleaning the thin ferroelectric layer and by thermally treating the thin ferroelectric layer. As a result, a ferroelectric capacitor or a semiconductor device including the thin ferroelectric layer may have greatly improved electrical characteristics. In the meantime, since an upper electrode layer is formed on the thin ferroelectric layer having the greatly level surface, the upper electrode layer may not be detached from the thin ferroelectric layer due to an enhanced adhesive strength between the upper electrode layer and the thin ferroelectric layer. Thus, the ferroelectric capacitor and the semiconductor device may have improved reliabilities. Further, the semiconductor device including the thin ferroelectric layer may be efficiently operated at a relatively low voltage of below about 1.5 V.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A method of forming a ferroelectric layer, comprising:
forming a ferroelectric layer on a substrate;
polishing a surface of the ferroelectric layer; and
curing the polished surface of the ferroelectric layer.

2. The method of claim 1, wherein forming the ferroelectric layer comprises depositing the ferroelectric layer on the substrate using a deposition process selected from a group consisting of chemical vapor deposition, sol-gel deposition and atomic layer deposition.

3. The method of claim 1, wherein the ferroelectric layer comprises any one selected from a group consisting of PZT, SBT, BLT, PLZT, and BST.

4. The method of claim 1, wherein forming the ferroelectric layer comprises forming a ferroelectric layer having a first RMS surface roughness and a first peak-to-valley surface roughness; wherein polishing the surface of the ferroelectric layer comprises polishing the surface of the ferroelectric layer for sufficient duration to achieve a second RMS surface roughness and a second peak-to-valley surface roughness; wherein a ratio of the first RMS surface roughness to the second RMS surface roughness is in a range from about 1:0.025 to about 1:0.25; and wherein a ratio of the first peak-to-valley surface roughness to the second peak-to-valley surface roughness is in a range from about 1:0.03 to about 1:0.3.

5. The method of claim 1, wherein forming the ferroelectric layer comprises forming the ferroelectric layer having a first RMS surface roughness in a range from about 40 \acute{Å} to about 80\acute{Å} and a first peak-to-valley surface roughness in a range from about 200 \acute{Å} to about 600 \acute{Å}; wherein polishing the surface of the ferroelectric layer comprises polishing the surface of the ferroelectric layer for sufficient duration to achieve a second RMS surface roughness in a range from about 2 \acute{Å} to about 10 \acute{Å} and a second peak-to-valley surface roughness in a range from about 20 \acute{Å} to about 60 \acute{Å}.

6. The method of claim 1, wherein forming the ferroelectric layer comprises forming the ferroelectric layer having a thickness in a range from about 500 \acute{Å} to about 1,500 \acute{Å}; and wherein polishing the surface of the ferroelectric layer comprises polishing the surface of the ferroelectric layer for sufficient duration to achieve a polished ferroelectric layer having a thickness in a range from about 200 \acute{Å} to about 1,000 \acute{Å}.

7. The method of claim 1, wherein polishing the surface of the ferroelectric layer comprises chemically-mechanically polishing the surface of the ferroelectric layer by rotating a polishing pad on the surface at a rotation speed in a range from about 5 rpm to about 25 rpm.

8. The method of claim 7, wherein polishing the surface of the ferroelectric layer comprises pressing the polishing pad onto the surface of the ferroelectric layer at a pressure in a range from about 0.5 psi to about 3 psi.

9. The method of claim 1, wherein polishing the surface of the ferroelectric layer comprises chemically-mechanically polishing the surface of the ferroelectric layer using a slurry selected from a group consisting of acidic silica, basic silica, ceria, alumina and titania.

10. The method of claim 1, wherein polishing the surface of the ferroelectric layer comprises chemically-mechanically polishing the surface of the ferroelectric layer using a slurry selected from a group consisting of acidic silica having a pH in a range from about 2 to about 3 and basic silica having a pH in a range from about 10 to about 12.

11. The method of claim 1, wherein curing the polished surface of the ferroelectric layer comprises exposing the polished surface to a rapid thermal anneal.

12. The method of claim 11, wherein exposing the polished surface to a rapid thermal anneal is performed in an inert atmosphere comprising a gas selected from a group consisting of nitrogen, helium, argon and neon.

13. The method of claim 11, wherein the rapid thermal anneal is performed at a temperature in a range from about 500° C. to about 600° C. for a duration in a range between 30 seconds and 90 seconds.

14. The method of claim 1, wherein curing the polished surface of the ferroelectric layer comprises thermally treating the polished surface at a temperature in a range from about 500° C. to about 650° C. for a duration in a range between 30 seconds and 120 seconds.

15. The method of claim 1, wherein forming the ferroelectric layer is preceded by a step of forming a first capacitor electrode on the substrate; wherein forming the ferroelectric layer comprises forming a ferroelectric layer on the first capacitor electrode; and wherein curing the polished surface of the ferroelectric layer is followed by a step of forming a second capacitor electrode on the ferroelectric layer.

16. A method of forming a ferroelectric layer, comprising:
forming a ferroelectric layer on a substrate; and
chemically-mechanically polishing a surface of the ferroelectric layer by rotating a polishing pad on the surface at a rotation speed in a range from about 5 rpm to about 25 rpm.

17. The method of claim 16, wherein polishing the surface of the ferroelectric layer comprises pressing the polishing pad onto the surface of the ferroelectric layer at a pressure in a range from about 0.5 psi to about 3 psi.

18. The method of claim 17, wherein polishing the surface of the ferroelectric layer is followed by exposing the polished surface to a rapid thermal anneal.

19. The method of claim 18, wherein exposing the polished surface to a rapid thermal anneal is performed in an inert atmosphere comprising a gas selected from a group consisting of nitrogen, helium, argon and neon.

20. The method of claim 18, wherein the rapid thermal anneal is performed at a temperature in a range from about 500° C. to about 600° C. for a duration in a range between 30 seconds and 90 seconds.

21.-88. (canceled)
